(19) United States
(12) Patent Application Publication
(10) Pub. No.: US 2025/0212474 A1
(43) Pub. Date: Jun. 26, 2025

(54) Magnesium Group IV Oxides

(71) Applicant: Silanna UV Technologies Pte Ltd, Singapore (SG)

(72) Inventor: Petar Atanackovic, Henley Beach South (AU)

(73) Assignee: Silanna UV Technologies Pte Ltd, Singapore (SG)

(21) Appl. No.: 19/076,574

(22) Filed: Mar. 11, 2025

Related U.S. Application Data
(63) Continuation-in-part of application No. 18/497,137, filed on Oct. 30, 2023, now Pat. No. 12,266,697.
Application No. 18/497,137 is a continuation of application No. 17/651,711, filed on Feb. 18, 2022, now Pat. No. 11,855,152.
Application No. 17/651,711 is a continuation of application No. PCT/IB2021/060414, filed on Nov. 10, 2021.

(51) Int. Cl. H10D 62/80; C30B 29/32; H01L 21/02; H01L 21/225; H10F 77/12; H10H 20/811; H10H 20/822; H10H 20/823

(52) U.S. Cl. CPC H10D 62/80; C30B 29/32; H01L 21/02565; H01L 21/02576; H01L 21/02579; H01L 21/02631; H01L 21/2252; H10F 77/12; H10H 20/811; H10H 20/822; H10H 20/823

(57) ABSTRACT

Various forms of Mgₐ(Siₓ(Ge_{y}Sn_{1-y})₁₋ₓ)O_{b} are disclosed. In some aspects, an epitaxial layer comprises single crystal Mgₐ(Siₓ(Ge_{y}Sn_{1-y})₁₋ₓ)O_{b}, wherein 1.5≤a≤2.5, 3≤b≤5, 0≤x≤1, and 0≤y≤1; wherein the single crystal Mgₐ(Siₓ(Ge_{y}Sn_{1-y})₁₋ₓ)O_{b} has a crystal symmetry compatible with a substrate or an underlying layer on which the single crystal Mgₐ(Siₓ(Ge_{y}Sn_{1-y})₁₋ₓ)O_{b} is grown. In some aspects, a semiconductor structure includes an epitaxial layer comprising single crystal Mgₐ(Siₓ(Ge_{y}Sn_{1-y})₁₋ₓ)O_{b}, wherein 1.5≤a≤2.5, 3≤b≤5, 0≤x≤1, and 0≤y≤1; The semiconductor structure also includes a substrate or an underlying layer on which the single crystal Mgₐ(Siₓ(Ge_{y}Sn_{1-y})₁₋ₓ)O_{b} is grown; wherein the single crystal Mgₐ(Siₓ(Ge_{y}Sn_{1-y})₁₋ₓ)O_{b} has a crystal symmetry compatible with the substrate or the underlying layer.

### RELATED APPLICATIONS

This application is a continuation-in-part of U.S. patent application Ser. No. 18/497,137, entitled “Ultrawide Bandgap Semiconductor Devices Including Magnesium Germanium Oxides,” filed on Oct. 30, 2023; which is a continuation of U.S. patent application Ser. No. 17/651,711, entitled “Ultrawide Bandgap Semiconductor Devices Including Magnesium Germanium Oxides,” filed on Feb. 18, 2022; which is a continuation of International Patent Application No. PCT/IB2021/060414, filed on Nov. 10, 2021, and entitled “Ultrawide Bandgap Semiconductor Devices Including Magnesium Germanium Oxides”; all of which are hereby incorporated by reference for all purposes.

This application is related to U.S. patent application Ser. No. 17/651,712, entitled “Ultrawide Bandgap Semiconductor Devices Including Magnesium Germanium Oxides,” filed on Feb. 18, 2022, and issued as U.S. Pat. No. 11,456,361; to U.S. patent application Ser. No. 17/651,713, entitled “Ultrawide Bandgap Semiconductor Devices Including Magnesium Germanium Oxides,” filed on Feb. 18, 2022, and issued as U.S. Pat. No. 11,462,400; to U.S. patent application Ser. No. 16/990,349, filed on Aug. 11, 2020, entitled “Metal Oxide Semiconductor-Based Light Emitting Device,” and issued as U.S. Pat. No. 11,342,484; to International Application No. PCT/IB2021/060413, entitled “Epitaxial Oxide Materials, Structures and Devices,” filed on Nov. 10, 2021; and to International Application No. PCT/IB2021/060466, entitled “Epitaxial Oxide Materials, Structures and Devices,” filed on Nov. 11, 2021; all of which are hereby incorporated by reference for all purposes.

### BACKGROUND

Electronic and optoelectronic devices rely on semiconductor materials to provide properties that enable the devices to function in various ways for different applications. Optoelectronic devices include light emitting diodes (LEDs) that emit light at infrared, visible or ultraviolet wavelengths depending on the bandgaps of the materials used in the LEDs. For example, ultraviolet (UV) emitting LEDs utilize wide bandgap (WBG) semiconductors such as gallium nitride (GaN) and aluminum nitride (AlN). Photodetectors are another type of optoelectronic device, which sense the presence of light. For example, UV detection of light is utilized for diverse applications in communication systems, data storage, biosensing and fluorescence measurements. Lasers and solar blind detectors are other types of optoelectronic devices.

Digital power management systems use electronic devices for direct current (DC) and alternating current (AC) power conversion, such as DC-DC and AC-DC conversion. These power inverters and power conversion devices are fundamentally constructed using high breakdown voltage and fast switching time power transistors. The properties of the semiconductor materials used in the electronic devices affect performance characteristics such as electrical breakdown voltage tolerance, on-state electrical losses, transistor switching speed and overall switching efficiency. High radiofrequency switching transistors are used in telecommunication and radar systems and require in addition the use of low insertion loss materials and high signal gain.

Ongoing development of semiconductor materials is extremely important for continuing improvements and advances in electronic and optoelectronic devices.

### SUMMARY

In some aspects, an epitaxial layer comprises single crystal Mgₐ(Siₓ(Ge_{y}Sn_{1-y})₁₋ₓ)O_{b}, wherein 1.5≤a≤2.5, 3≤b≤5, 0≤x≤1, and 0≤y≤1; wherein the single crystal Mgₐ(Siₓ(Ge_{y}Sn_{1-y})₁₋ₓ)O_{b} has a crystal symmetry compatible with a substrate or an underlying layer on which the single crystal Mgₐ(Siₓ(Ge_{y}Sn_{1-y})₁₋ₓ)O_{b} is grown.

In some aspects, a semiconductor structure includes an epitaxial layer comprising single crystal Mgₐ(Siₓ(Ge_{y}Sn_{1-y})₁₋ₓ)O_{b}, wherein 1.5≤a≤2.5, 3≤b≤5, 0≤x≤1, and 0≤y≤1. The semiconductor structure also includes a substrate or an underlying layer on which the single crystal Mgₐ(Siₓ(Ge_{y}Sn_{1-y})₁₋ₓ)O_{b} is grown; wherein the single crystal Mgₐ(Siₓ(Ge_{y}Sn_{1-y})₁₋ₓ)O_{b} has a crystal symmetry compatible with the substrate or the underlying layer.

### BRIEF DESCRIPTION OF THE DRAWINGS

FIG. 1A is a perspective view of a cubic crystal symmetry MgO structure showing the atomic positions of magnesium and oxygen atoms of a unit cell, in accordance with some aspects.

FIG. 1B is a plan view along an axis of the cubic MgO illustrated in FIG. 1A.

FIG. 2A is a perspective view of a single crystal unit cell comprising trigonal germanium oxide GeO₂, in accordance with some aspects.

FIG. 2B is a plan view of the single crystal unit cell of trigonal germanium oxide GeO₂ illustrated in FIG. 2A.

FIG. 3A is a perspective view of a single crystal unit cell comprising tetragonal germanium oxide GeO₂, in accordance with some aspects.

FIG. 3B is a plan view of the single crystal unit cell of tetragonal germanium oxide GeO₂ illustrated in FIG. 3A.

FIG. 4 is a table of single crystal compositions that may be formed from various proportions of Mg, Ge and O, in accordance with some aspects.

FIG. 5 is a table showing examples of possible single crystal compositions that may be formed from Mg, Ge and O, exhibiting low formation energy and therefore stable structures, in accordance with some aspects.

FIG. 6 is a plot showing calculated formation energies of different single crystal compositions formed from Mg, Ge and O (i.e., MgₓGe_{y}O_{z}), in accordance with some aspects.

FIG. 7A is a figurative view of the fundamental unit cell defining the single crystal composition of type Mg₂GeO₄ (Pnma), in accordance with some aspects.

FIG. 7B is a figurative view of the fundamental unit cell defining the single crystal composition of the type MgGeO₃ (C2/c), in accordance with some aspects.

FIG. 7C is a figurative view of the fundamental unit cell defining the single crystal composition of the type Mg₂GeO₄(Fd3m), in accordance with some aspects.

FIG. 8A is an electron energy-momentum (E-k) diagram for Mg₂GeO₄ (Fd3m) showing the calculated valence and conduction band structure at critical points within the Brillouin-zone of the crystal disclosed in FIG. 7C, in accordance with some aspects.

FIG. 8B is an E-k diagram showing the detailed valence band structure of the E-k diagram for Mg₂GeO₄(Fd3m) illustrated in FIG. 8A, in accordance with some aspects.

FIG. 9A is an E-k diagram for Mg₂GeO₄ (Pnma) showing the calculated valence and conduction band structure at critical points within the Brillouin-zone of the crystal disclosed in FIG. 7A, in accordance with some aspects.

FIG. 9B is an E-k diagram showing the detailed valence band structure of the E-k diagram for Mg₂GeO₄ (Pnma) illustrated in FIG. 9A, in accordance with some aspects.

FIG. 10A is an E-k diagram for MgGeO₃ (C2/c) showing the calculated valence and conduction band structure at critical points within the Brillouin-zone of the crystal disclosed in FIG. 7B, in accordance with some aspects.

FIG. 10B is an E-k diagram showing the detailed valence band structure of the E-k diagram for MgGeO₃ (C2/c) illustrated in FIG. 10A, in accordance with some aspects.

FIG. 11 discloses a local bonding configuration within a Fd3m cubic crystal of the form AB₂O₄ where A and B cations are bonded to an oxygen (O) atom, in accordance with some aspects.

FIG. 12 is a table showing examples of compatible substrates compositions and orientations upon which the single crystal compositions Mg₂GeO₄ (Pnma), MgGeO₃ (C2/c), and Mg₂GeO₄ (Fd3m) may be epitaxially formed, in accordance with some aspects.

FIG. 13A is a schematic diagram showing two distinct free-standing crystal structures corresponding to a film and a substrate, both having a cubic or tetrahedral symmetry, where the film has a larger parallel (i.e., in-plane) lattice constant than the substrate (a_{f}^{∥}>a_{sub}^{∥}), in accordance with some aspects.

FIG. 13B is a schematic diagram showing the effect of epitaxially forming a layer having cubic symmetry on a substrate also having cubic symmetry as shown in FIG. 13A, where the free-standing in-plane lattice constant of the original film is greater than the in-plane lattice constant of the substrate, in accordance with some aspects.

FIG. 14A is a schematic diagram showing two distinct free-standing crystal structures corresponding to a film and a substrate, both having a cubic or tetrahedral symmetry, where the film has a smaller in-plane lattice constant than the substrate (a_{f}^{∥}>a_{sub}^{∥}), in accordance with some aspects.

FIG. 14B is a schematic diagram showing the effect of epitaxially forming a layer having cubic symmetry on a substrate also having cubic symmetry as shown in FIG. 14A, where the free-standing in-plane lattice constant of the original film is less than the in-plane lattice constant of the substrate, in accordance with some aspects.

FIG. 15A depicts a unit cell of cubic Fd3m Mg₂GeO₄ crystal elastically deformed equally along the in-plane a-b axes, matched to twice the lattice constant of a free-standing cubic MgO crystal, in accordance with some aspects.

FIG. 15B is a figurative diagram of the lattice mismatched formation of an epitaxial layer of Mg₂GeO₄ (Fd3m) formed on a substrate comprising cubic magnesium-oxide MgO (001), showing that the in-plane lattice constant of the film is approximately matched to an integer multiple of the smaller MgO unit cell, in accordance with some aspects.

FIG. 16 discloses the electronic energy band structure E-k diagram for an epitaxial layer of cubic space group Fd3m Mg₂GeO₄ formed on a substrate or rigid layer of cubic Fd3m space group magnesium aluminate MgAl₂O₄, in accordance with some aspects.

FIG. 17 discloses the electronic energy band structure E-k diagram for an epitaxial layer of cubic space group Fd3m Mg₂GeO₄ formed on a substrate or rigid layer of cubic Fd3m space group magnesium oxide MgO, in accordance with some aspects.

FIG. 18A is a table showing normalized x, y, and z positions of cation sites for a Mg₂GeO₄ (Fd3m) unit cell, in accordance with some aspects.

FIG. 18B is a table showing normalized x, y, and z positions of anion sites for a Mg₂GeO₄ (Fd3m) unit cell, in accordance with some aspects.

FIG. 19 is a table summarizing the semiconductor properties of single site trivalent gallium impurity atom substitution in Mg₂GeO₄ (Fd3m) lattice, showing that single site substitutions of the Ge sites with Ga results in p-type conductivity and preserves the direct bandgap character, in accordance with some aspects.

FIG. 20 is a crystal structure diagram of a Ga-doped Mg₂GeO₄ (Fd3m), showing in this example the Ge₂₃ site substituted with Ga, in accordance with some aspects.

FIG. 21A is an E-k diagram for the doped Mg₂GeO₄ (Fd3m) illustrated in FIG. 20, showing the valence and conduction band structure, in accordance with some aspects.

FIG. 21B is an E-k diagram showing a detailed view of the valence band structure illustrated in FIG. 21A, in accordance with some aspects.

FIG. 22 is a table showing semiconductor properties of Ga-doped Mg₂GeO₄ (Fd3m) arising from various single site substitutions of distinct Mg sites with Ga, in accordance with some aspects.

FIG. 23 is a crystal structure diagram and associated E-k diagram of a doped Mg₂GeO₄ (Fd3m), showing in this example the Mg₂ site substituted with Ga, in accordance with some aspects.

FIG. 24 is a crystal structure diagram and associated E-k diagram of a doped Mg₂GeO₄ (Fd3m), showing in this example the Mg₂ site substituted with Ga, in accordance with some aspects.

FIG. 25 is an E-k diagram for a doped Mg₂GeO₄ (Fd3m) arising from the octahedral Mg₁ site being substituted with trivalent Al, in accordance with some aspects.

FIG. 26 is an E-k diagram for a doped Mg₂GeO₄ (Fd3m) arising from the tetrahedral Ge₁₇ site being substituted with trivalent Al, in accordance with some aspects.

FIG. 27 is a unit cell crystal structure diagram of cubic lithium-oxide Li₂O (Fm3m), showing the monovalent Li⁺ atoms tetrahedrally bonded to oxygen, in accordance with some aspects.

FIG. 28 is a unit cell crystal structure diagram of doped Mg₂GeO₄ (Fd3m), showing in this example the tetrahedral site of Ge₁₇ intentionally substituted with Li, in accordance with some aspects.

FIG. 29A is an E-k diagram for the Li-doped Mg₂GeO₄ (Fd3m) illustrated in FIG. 28, in accordance with some aspects.

FIG. 29B is an E-k diagram showing the detailed valence band structure of the E-k diagram illustrated in FIG. 29A, in accordance with some aspects.

FIG. 30 shows an E-k diagram corresponding to Li-doped Mg₂GeO₄ (Fd3m) where the Mg₁ site is substituted with Li, in accordance with some aspects.

FIG. 31 is a unit cell crystal structure diagram of cubic nickel-oxide NiO (space group Fd3m) showing the octahedral bonding of Ni with oxygen atoms, in accordance with some aspects.

FIG. 32 is a unit cell crystal structure diagram of Ni-doped Mg₂GeO₄ (Fd3m), showing in this example the octahedral Mg₁ site substituted with Ni, in accordance with some aspects.

FIG. 33A is an E-k diagram for the Ni-doped Mg₂GeO₄ (Fd3m) illustrated in FIG. 32, in accordance with some aspects.

FIG. 33B is the resulting density-of-states diagram for the Ni-doped Mg₂GeO₄ (Fd3m) illustrated in FIG. 32, in accordance with some aspects.

FIG. 34 is a unit cell crystal structure diagram of a nitrogen (N) atom substituted at one of the possible 32 oxygen sites within Mg₂GeO₄ (Fd3m), in accordance with some aspects.

FIG. 35A is an E-k diagram for the N-doped Mg₂GeO₄ (Fd3m) illustrated in FIG. 34, in accordance with some aspects.

FIG. 35B shows a detailed view of the valence band structure illustrated in FIG. 35A, in accordance with some aspects.

FIG. 36A shows the stoichiometric unit cell crystal structure of cubic Mg₂GeO₄ (Fd3m), identifying the nominal structural positions of selected Mg and Ge atomic sites, in accordance with some aspects.

FIG. 36B shows an example of an anti-site cross-substitution process where the exchange process comprises a nominal Mg₁₂ site that is exchanged for a Ge atom and a nominal Ge₂₀ site that is exchanged for a Mg atom, in accordance with some aspects.

FIG. 37A is the resultant E-k diagram for the anti-site exchange within Mg₂GeO₄ (Fd3m) illustrated in FIG. 36B, in accordance with some aspects.

FIG. 37B is an electronic density of states diagram for the Mg↔Ge anti-site exchange illustrated in FIG. 36B, in accordance with some aspects.

FIG. 37C shows a distorted crystal unit cell resulting from geometric optimization via the process of energy minimization for the single Mg↔Ge anti-site atom exchange as illustrated in FIG. 36B, in accordance with some aspects.

FIG. 37D is a schematic diagram of the cubic bonding environment of a Ge atom within a nominal Fd3m crystal, and the resulting distorted crystal field when the Ge atom is substituted into an octahedral bonding site, in accordance with some aspects.

FIG. 37E are tables of the cation and anion positions for a distorted crystal structure in the case of a single anti-site substitution, in accordance with some aspects.

FIG. 37F is an E-k band structure diagram of a geometry-optimized single anti-site substitution, in accordance with some aspects.

FIG. 38 is a unit cell crystal structure diagram of the cation lattice positions for the case of a space group Fd3m, transformed from a normal configuration to a germanium-rich configuration, in accordance with some aspects.

FIG. 39A is a table of possible compositions of MgₓGe_{y}O_{z}, with respective crystalline space groups and the relative number of cations and anions within the crystal unit cell, in accordance with some aspects.

FIG. 39B is a table of the formation energy and lowest energy bandgap for the example MgₓGe_{y}O_{z} compounds referred to in FIG. 39A, in accordance with some aspects.

FIG. 39C is a table indicating the atomic positions within a Fd3m crystal formed with a Ge-excess by substituting a Mg-site with Ge, in accordance with some aspects.

FIG. 40 is an E-k diagram of a Ge-doped Mg₂GeO₄ (Fd3m) where there is an excess of Ge, in accordance with some aspects.

FIG. 41 is an E-k diagram of a Mg-doped Mg₂GeO₄ (Fd3m) where there is an excess of Mg, in accordance with some aspects.

FIG. 42A is a diagram of possible conductivity types (n-type or p-type) using the doping strategies disclosed herein, for the case of Mg₂GeO₄ (Fd3m), in accordance with various aspects.

FIG. 42B is a diagram showing relative formation energies for selected substitutional impurity doping of the Mg-site or Ge-site in Mg₂GeO₄ (Fd3m), in accordance with some aspects.

FIG. 43A is thermodynamic oxidation Ellingham diagram for the formation of binary oxides 2Mg+O₂→2MgO and Ge+O₂→GeO₂ and ternary oxide 2MgO+Ge+O₂→Mg₂GeO₄, in accordance with some aspects.

FIGS. 43B, 43C and 43D schematically show surface kinetics of film formation at an epitaxial surface using elemental fluxes of constituent specie, in accordance with some aspects.

FIG. 43E is a summary ternary phase diagram for the Mg—Ge—O system as calculated using density functional theory (DFT), showing the stable compositions of MgO, GeO₂, Mg₂GeO₄ and MgGeO₃ in accordance with some aspects.

FIG. 44A is a representative growth phase diagram for epitaxial co-deposition of Mg_{1-y}Ge_{y}O_{1+y} compound using elemental Ge, Mg and active-O fluxes as a function of surface growth temperature, in accordance with some aspects.

FIG. 44B is a growth phase diagram similar to that illustrated in FIG. 44A and depicting an experimentally determined growth window for high quality single crystal Mg₂GeO₄ with Fd3m crystal structure deposited on MgO substrate, in accordance with some aspects.

FIG. 45 is a growth phase diagram for Mg_{1-y}Ge_{y}O_{1+y} for the case of k=Φ_{Ge}^{inc}/Φ_{Mg}^{inc}=7.5 and the resulting variation in growth rate of the film, in accordance with some aspects.

FIG. 46A is a sectional view of an epitaxially formed layered semiconductor structure comprising a substrate, a substantially single crystal epilayer comprising Mg₂GeO₄ (Fd3m) and an optional cap formed of MgO, in accordance with some aspects.

FIG. 46B is a table of crystal structure properties of example epitaxial films and substrates that are compatible with Mg₂GeO₄, in accordance with some aspects.

FIG. 46C is a cubic crystal structure diagram of a substrate made from MgO or LiF, having a symmetric lattice constant, a, in accordance with some aspects.

FIG. 46D is a cubic crystal structure diagram of a substrate or epilayer having symmetric lattice constant approximately twice as large as that illustrated in FIG. 46C, in accordance with some aspects.

FIG. 46E is a schematic diagram depicting coherent epitaxial layer formation along a growth direction of two distinct cubic crystal structures having a large difference in lattice constants, in accordance with some aspects.

FIG. 47 is an experimentally determined triple axis X-ray diffraction (XRD) diagram of a layered semiconductor structure as illustrated in FIG. 46A where a Mg₂GeO₄ (Fd3m) layer was formed with k=7.5, in accordance with some aspects.

FIG. 48 is an experimentally determined triple axis XRD diagram of a layered semiconductor structure as illustrated in FIG. 46A where a Mg₂GeO₄ (Fd3m) layer was formed with k=3, in accordance with some aspects.

FIG. 49 is an experimentally determined triple axis XRD diagram of a layered semiconductor structure as illustrated in FIG. 46A where a Mg₂GeO₄ (Fd3m) layer was formed with k=1.5, in accordance with some aspects.

FIG. 50 is an experimentally determined triple axis XRD diagram of a semiconductor structure where a Mg₂GeO₄ (Fd3m) layer was attempted to be formed with k=˜1.0, in accordance with some aspects.

FIG. 51 is a sectional view of an epitaxially formed layered semiconductor structure comprising a substrate, an optional buffer layer, and a superlattice or multilayered periodic structure, in accordance with some aspects.

FIG. 52A is an experimentally determined XRD diagram of a layered semiconductor structure as illustrated in FIG. 51 for a superlattice where one layer was MgO and another layer was Mg₂GeO₄ (Fd3m), deposited on a MgO buffer layer and a MgO(100) substrate, in accordance with some aspects.

FIG. 52B is an experimentally determined XRD diagram of a layered semiconductor structure as illustrated in FIG. 51 for a superlattice where one layer was Mg₂GeO₄ (Fd3m) and another layer was MgGa₂O₄ (Fd3m), deposited upon a MgO buffer layer and a MgO(100) substrate, in accordance with some aspects.

FIG. 52C is an experimentally determined XRD diagram of a layered semiconductor structure as illustrated in FIG. 51 for a superlattice where one layer was Mg₂GeO₄ (Fd3m) and another layer was MgO (Fm3m), the superlattice being deposited upon a MgO buffer layer and a MgO(100) substrate, in accordance with some aspects.

FIG. 52D is an experimentally determined XRD diagram of a layered semiconductor structure as illustrated in FIG. 51 for a superlattice where one layer was Mg₂GeO₄ (Fd3m) and another layer was MgO (Fm3m), deposited upon a MgO buffer layer and a MgO(100) substrate, in accordance with some aspects.

FIG. 52E is an experimentally determined XRD diagram of a layered semiconductor structure as illustrated in FIG. 51 for a superlattice where one layer was Mg₂GeO₄ (Fd3m) and another layer was stabilized cubic gamma-Ga₂O₃, the superlattice being deposited upon a MgO buffer layer and a MgO(100) substrate, in accordance with some aspects.

FIG. 52F is an experimentally determined XRD diagram of a layered semiconductor structure as illustrated in FIG. 51 for a superlattice where one layer was Mg₂GeO₄ (Fd3m) and another layer was stabilized cubic gamma-Ga₂O₃, the superlattice being deposited upon a MgO buffer layer and a MgO(100) substrate, in accordance with some aspects.

FIG. 52G shows the complex epilayer structure of dissimilar cubic oxide layers integrated into a superlattice or multi-heterojunction structure, in accordance with some aspects.

FIG. 52H shows the experimental XRD data of a Fd3m crystal structure GeMg₂O₄ deposited as a high quality bulk layer on a Fm3m MgO(100) substrate and further comprising a MgO cap, in accordance with some aspects.

FIG. 52I shows the experimental XRD data of a Fd3m crystal structure GeMg₂O₄ when incorporated as a SL structure comprising 20× period SL[GeMg₂O₄/MgO] on a Fm3m MgO(100) substrate, in accordance with some aspects.

FIG. 53 is a summary table of the superlattice properties for example structures comprising MgGeO epilayers, in accordance with some aspects.

FIG. 54A shows an epitaxial multiple layer structure for forming an electronic or optoelectronic device, comprising a substrate, optional buffer layer, a first conductivity type layer, a second conductivity type region, a third conductivity type region and an electrical contact layer, in accordance with some aspects.

FIG. 54B is a figurative diagram showing possible electrical conductivity types for MgₐGe_{b}O_{c} using co-doping or crystal growth modification during epitaxial layer formation, in accordance with some aspects.

FIG. 55A shows a multilayer structure used to form an electronic device having distinct regions comprising at least one layer of MgₐGe_{b}O_{c}, in accordance with some aspects.

FIG. 55B is a figurative diagram showing example materials that may be combined with MgₐGe_{b}O_{c} to form a heterostructure, in accordance with some aspects.

FIG. 55C is a plot of the bandgap energy as a function of lattice constant for various materials that may be used in semiconductor structures, in accordance with some aspects.

FIG. 56A shows a band structure diagram for a homojunction device comprising a p-i-n structure, in accordance with some aspects.

FIG. 56B shows a band structure diagram for a homojunction device comprising an n-i-n structure, in accordance with some aspects.

FIG. 56C shows a band structure diagram for a heterojunction device comprising a p-i-n structure, in accordance with some aspects.

FIG. 56D shows a band structure diagram for a double heterojunction device, in accordance with some aspects.

FIG. 56E shows a band structure diagram for a metal-insulator-semiconductor (MIS) structure, in accordance with some aspects.

FIG. 56F shows a band structure diagram for a multiple heterojunction device comprising a p-i-n structure and a quantum well, in accordance with some aspects.

FIG. 56G shows a band structure diagram for a p-i-n structure with a superlattice in the i-region, in accordance with some aspects.

FIGS. 56H and 561 show band structure diagrams for a p-i-n structure with a superlattice in the p-, i-, and n-regions, in accordance with some aspects.

FIG. 57 is a figurative sectional view of an in-plane conduction device comprising an insulating substrate and a semiconductor layer region formed on the substrate with the electrical contacts positioned on the top semiconductor layer of the device, in accordance with some aspects.

FIG. 58 is figurative sectional view of a vertical conduction device comprising a conducting substrate and a semiconductor layer region formed on the substrate with the electrical contacts positioned on the top and bottom of the device, in accordance with some aspects.

FIG. 59 is a figurative sectional view of a vertical conduction device for light emission having the electrical contact configuration illustrated in FIG. 58, configured as a plane parallel waveguide for the emitted light, in accordance with some aspects.

FIG. 60 is a figurative sectional view of a vertical conduction device for light emission having the electrical contact configuration illustrated in FIG. 58, configured as a vertical light emission device, in accordance with some aspects.

FIG. 61 is a figurative sectional view of an in-plane conduction device for photo-detection, having the electrical contact configuration illustrated in FIG. 57, and configured to receive light passing through the semiconductor layer region and/or the substrate, in accordance with some aspects.

FIG. 62 is a figurative sectional view of an in-plane conduction device for light emission, having the electrical contact configuration illustrated in FIG. 57, and configured to emit light either vertically or in-plane, in accordance with some aspects.

FIG. 63 is a figurative sectional view of an in-plane surface metal-semi-conductor-metal (MSM) conduction device comprising a substrate and a semiconductor layer region comprising multiple semiconductor layers, with a top layer comprising a pair of planar interdigitated electrical contacts, in accordance with some aspects.

FIG. 64A is a top view of an in-plane dual metal MSM conduction device comprising a first electrical contact formed of a first metallic substance interdigitated with a second electrical contact formed of a second metallic substance, in accordance with some aspects.

FIG. 64B is a figurative sectional view of the in-plane dual metal MSM conduction device illustrated FIG. 64A formed of a substrate and a semiconductor layer region showing the unit cell arrangement, in accordance with some aspects.

FIG. 65 is a figurative sectional view of a multilayered semiconductor device having a first electrical contact formed on a mesa surface and a second electrical contact spaced both horizontally and vertically from the first electrical contact, in accordance with some aspects.

FIG. 66 is figurative sectional view of an in-plane MSM conduction device comprising multiple unit cells of the mesa structure illustrated in FIG. 65 disposed laterally to form the device, in accordance with some aspects.

FIG. 67 is a figurative sectional view of a multi-electrical terminal device having multiple mesa structures, in accordance with some aspects.

FIGS. 68A-68B and FIG. 69 are generalized views of an example epitaxial oxide field effect transistor (FET) device, in accordance with some aspects.

FIG. 70 is a top view of a planar FET comprising multiple interconnected unit cells of the planar FET illustrated in FIG. 68A or 68B, in accordance with some aspects.

FIG. 71 is a process flow diagram for forming a conduction device comprising a regrown conformal semiconductor layer region on an exposed etched mesa sidewall, in accordance with some aspects.

FIGS. 72A-72C are crystal structure diagrams of Fd3m AB₂O₄, in accordance with some aspects.

FIG. 73A is a graph showing direct bandgaps versus cubic oxide lattice constants for Mg₂SiO₄, Mg₂GeO₄, Mg₂SnO₄, in accordance with some aspects.

FIG. 73B is the same graph as in FIG. 73A with the addition of bandgaps for MgO and MgAl₂O₄, in accordance with some aspects.

FIGS. 74A-74B, 75A-75B, and 76A-76B are bandgap diagrams for the cubic Fd3m materials of FIGS. 73A-73B, in accordance with some aspects.

FIG. 77A is a graph showing direct bandgaps versus cubic oxide lattice constants for Mg, (Siₓ(Ge_{y}Sn_{1-y})₁₋ₓ)O_{b} with varying values of x and y, in accordance with some aspects.

FIG. 77B is a graph showing direct bandgaps versus cubic oxide lattice constants for varying values of x and y for Mg—Si—Ge—O, in accordance with some aspects.

FIG. 78 is a graph that includes bandgap energies for ternary spinels of magnesium group IV oxides, in accordance with some aspects.

FIG. 79 is a graph of bandgap energy as a function of growth direction for an example graded alloy structure constructed using layers of Mg₂SiO₄ and Mg₂GeO₄, in accordance with some aspects.

FIG. 80 is a graph of bandgap energy as a function of growth direction for an example graded alloy structure constructed using layers of Mg₂GeO₄ and Mg₂SnO₄, in accordance with some aspects.

FIG. 81A shows a band structure diagram for a homojunction device comprising a p-i-n structure, in accordance with some aspects.

FIG. 81B shows a band structure diagram for a heterojunction device comprising a p-i-n structure, in accordance with some aspects.

FIG. 81C shows a band structure diagram for a multiple heterojunction device comprising a p-i-n structure and a quantum well, in accordance with some aspects.

### DETAILED DESCRIPTION

Magnesium-group IV oxide epitaxial layers—such as epitaxial layers made of a material having magnesium and one or more of silicon, germanium, and tin—are disclosed. Semiconductor structures and devices that include magnesium-containing oxide epitaxial layers are also described, where substrate materials and the magnesium-containing oxide layers are carefully designed and utilized in specific combinations to enable formation of high-quality crystal structures. Aspects of the semiconductor structures include a substantially single crystal substrate having a pre-determined crystal symmetry compatible with the particular form of magnesium-group IV oxide in the epitaxial layer. The semiconductor structures involve new forms of magnesium-group IV oxide, with substantially single crystal structures formed. The semiconductor structures comprise at least one region of magnesium-group IV oxide having a predetermined single crystal symmetry type. Aspects for conductivity doping of the magnesium-group IV oxide materials are disclosed, as well as methods for forming the semiconductor structures. Aspects of the magnesium-group IV oxide materials exhibit ultrawide bandgaps, such as a bandgap of 7.75 eV for Mg₂SiO₄, 5.8 eV for Mg₂GeO₄ and 4.5 eV for Mg₂SnO₄. Some aspects have a direct bandgap, such as the cubic form of magnesium germanium oxide having a direct bandgap of 5.8 eV. The disclosed materials, structures and methods enable high-quality and efficient semiconductor devices including optoelectronic devices operating in the deep ultraviolet range, and electronic devices for radiofrequency (RF) communication, digital computing and power switching.

In this disclosure, magnesium germanium oxide (MgₓGe_{y}O_{z}) comprises the elements of germanium (Ge), magnesium (Mg) and oxygen (O), where x, y, and z are mole fractions for x having any values in the range 0≤x≤1.5, y having any values in the range 1.0≤y≤2.5 and z having any values in the range 2≤z≤5. Aspects are also expressed in this disclosure as MgₐGe_{b}O_{c} (with a, b, c corresponding to x, y, z of MgₓGe_{y}O_{z}), or MgₓGe₁₋ₓO₂₋ₓ with x having any values in the range 0≤x≤1, or as Mg_{1-y}Ge_{y}O_{1+y} with 0≤y≤1. It shall be understood that instances in this disclosure that list one expression for magnesium germanium oxides (e.g., MgₓGe_{y}O_{z}) may be equally replaced with another expression (e.g., MgₓGe₁₋ₓO₂₋ₓ) as described in this paragraph.

In this disclosure, magnesium-group IV oxides may be represented as Mgₐ(Siₓ(Ge_{y}Sn_{y})₁₋ₓ)O_{b}, where 1.5≤a≤2.5, 3≤b≤5, 0≤x≤1, and 0≤y≤1. Some examples include ternary oxide materials, wherein i) x=1, or ii) y=0 and x=0, or iii) y=1 and x=0. For example, when x=1, the material is a ternary magnesium-silicon-oxide: Mgₐ(Si)O_{b}. When x=0 and y=0, the material is a ternary magnesium-tin-oxide: Mgₐ(Sn)O_{b}. When x=0 and y=1, the material is a ternary magnesium-germanium-oxide: Mgₐ(Ge)O_{b}. Some examples include quaternary oxide materials, wherein i) x=0 and 0≤y≤1, or ii) 0<x<1 and y=0 or 1. For example, when x=0 and 0≤y≤1, the material is a quaternary magnesium-germanium-tin oxide: Mgₐ(Ge_{y}Sn_{1-y})O_{b}. When 0≤x≤1 and y=0, the material is a quaternary magnesium-silicon-tin oxide: Mgₐ(Siₓ(Sn)₁₋ₓ)O_{b}. When 0≤x≤1 and y=1, the material is a quaternary magnesium-silicon-germanium oxide: Mgₐ(Siₓ(Ge)₁₋ₓ)O_{b}.

In the electronic and optoelectronic industries, semiconductors with new material and functional properties are required for an increasing number of modern applications. Although silicon is the workhorse of the digital computing and the power switching industries, there is a need to increase performance of power switches in digital power management systems in order for new application areas to progress commercially. In particular, there is a need for development of wide bandgap (WBG) semiconducting materials. Additionally, optoelectronic devices such as light emitting diodes (LEDs) require a unique set of materials-specific criteria to enable efficient light emission at infrared, visible and ultraviolet wavelengths. UVLEDs use WBG semiconductors such as GaN and AlN. It is well known by workers in the field that efficient optical emission from semiconductor materials requires the fundamental property of possessing a direct-bandgap energy-momentum configuration.

The advantageous direct bandgap is, however, possible for only a small subset of crystal structure types and atoms comprising single crystal compositions of semiconductors. There are technical and fundamental physics challenges preventing conventional UVLEDs (e.g., AlN-based UVLEDs) from achieving far ultraviolet wavelengths shorter than approximately 260 nm, such as shorter than approximately 220 nanometers (nm). It is desirable to provide UVLEDs that can produce wavelengths farther below 250 nm and to increase the optical output power of UVLEDs for applications such as the inactivation of viral and germicidal contamination of surfaces, liquids, and air.

Short UV wavelength sensors are another type of device that can benefit from further development of WBG semiconducting materials, as short UV wavelength sensors are typically limited by the available semiconductor bandgap energy and technology available.

Another desirable example of WBG semiconductor materials application is directed toward digital power management systems, such as DC-DC and AC-DC conversion. Power switches for such systems are conventionally implemented using semiconductors of the form: Si (E_{g}=1.1 eV), GaN (E_{g}=3.4 eV) and silicon-carbide (SiC, E_{g}=3.1 eV), where E_{g} is the energy gap between the conduction band minimum and valence band maximum. While GaN and SiC are classified as WBG, there is a pressing need to further increase the available bandgap energy to further improve the electrical breakdown voltage tolerance, reduce on-state electrical losses, increase transistor switching speed and thus increase overall switching efficiency.

Clearly, conventional WBG materials are technologically limiting for many applications, including extremely short UVLEDs and lasers, high efficiency power switching systems and solar blind detectors. There is a pressing need to establish new materials to overcome these shortcomings and limitations. The wide bandgaps of epitaxial oxide materials provide them with high dielectric breakdown voltages, and therefore can be used in electronic devices that require large voltage biases and sustain high electric fields (e.g., high voltage switches, and impact ionization devices). The bandgaps of epitaxial oxide materials are also well suited for use in optoelectronic devices that emit or detect light in the UV range, where materials with bandgaps from about 4.5 eV to about 8 eV can be used to emit or detect UV light with wavelengths from about 150 nm to 280 nm. Other ultrawide bandgap oxide materials disclosed can be used for extreme UV applications <150 nm. Semiconductor heterostructures can also be formed with wide bandgap materials as the emitter or absorber layers, and materials that have wider bandgaps than the emitter or absorber layers can be used in other layers of the structure to be transparent to the wavelength being emitted or absorbed.

The magnesium-group IV oxide materials disclosed herein may be utilized in various electronic and optoelectronic devices, such as, but not limited to, light emitting devices (e.g., UVLEDs), light sensors (e.g., short UV wavelength sensors), and power switches as described above. Other applications included functionalized oxide surfaces to form bio-electronic interfaces for biosensing. In some aspects, the magnesium-group IV oxide materials may be used in one or more layers of the active regions (e.g., n-type active region or layer(s), i-type active region or layer(s) and/or p-type active region or layer(s)) of a semiconductor device, as shall be described herein. An i-type region shall also be referred to as an intrinsic region or not intentionally doped region.

An “epitaxial oxide” material described herein is a material comprising oxygen and other elements (e.g., metals such as gallium or non-metals such as germanium and silicon) having an ordered crystalline structure configured to be formed on a single crystal substrate, or on one or more layers formed on the single crystal substrate. Epitaxial oxide materials have defined crystal symmetries and crystal orientations with respect to the substrate. Epitaxial oxide materials can form layers that are coherent with the single crystal substrate and/or with the one or more layers formed on the single crystal substrate. Epitaxial oxide materials can be in layers of a semiconductor structure that are strained, wherein the crystal of the epitaxial oxide material is deformed compared to a relaxed state. Epitaxial oxide materials can also be in layers of a semiconductor structure that are unstrained or relaxed.

In this disclosure, the crystal symmetry of the substrate and the epitaxial oxide material can be compatible if they have compatible crystal symmetry, and the in-plane (i.e., parallel with the surface of the substrate) lattice parameters and atomic positions at the surface of the substrate provide a suitable template for the growth of the subsequent epitaxial oxide materials. For example, a substrate and an epitaxial oxide material can be compatible if the in-plane lattice constant mismatch between the substrate and the epitaxial oxide material are less than 0.5%, 1%, 1.5%, 2%, 5% or 10%. For example, in some aspects the crystal structure of the substrate material has a lattice mismatch of less than or equal to 10% with the epitaxial layer. In some cases, the crystal symmetry of the substrate and the epitaxial oxide material can be compatible if they have a different type of crystal symmetry but the in-plane (i.e., parallel with the surface of the substrate) lattice parameters and atomic positions at the surface of the substrate provide a suitable template for the growth of the subsequent epitaxial oxide materials. In some cases, multiple (e.g., 2, 4 or other integer) unit cells of a substrate surface atomic arrangement can provide a suitable surface for the growth of an epitaxial oxide material with a larger unit cell than that of the substrate. In another case, the epitaxial oxide layer can have a smaller lattice constant (e.g., approximately half) than the substrate. In some cases, the unit cells of the epitaxial oxide layer may be rotated (e.g., by 45 degrees) compared to the unit cells of the substrate.

The epitaxial oxide materials described herein can be formed using an epitaxial growth technique such as molecular beam epitaxy (MBE), metal organic chemical vapor deposition (MOCVD), atomic layer deposition (ALD), and other physical vapor deposition (PVD) and chemical vapor deposition (CVD) techniques.

### Crystal Structure

The discovery of the ability to create epitaxial single crystal semiconductor structures of particular forms of Mgₐ(Siₓ(Ge_{y}Sn_{1-y})₁₋ₓ)O_{b} are disclosed herein (where 1.5≤a≤2.5, 3≤b≤5, 0≤x≤1, and 0≤y≤1), using substrates that are carefully selected based on crystal symmetry compatibility with the epitaxial oxide films being formed. Insights involving crystal structures will now be described to provide context for the formation of such epitaxial magnesium-group IV films and the tuning for example properties. Examples include MgₓGe_{y}O_{z}, Mgₐ(Ge)O_{b}, Mgₐ(Si)O_{b}, Mgₐ(Sn)O_{b}, Mgₐ(Ge_{y}Sn_{1-y})O_{b}, Mgₐ(Siₓ(Sn)₁₋ₓ)O_{b}, and Mgₐ(Siₓ(Ge)₁₋ₓ)O_{b}.

Density functional theory (DFT) enables prediction and calculation of the crystal oxide band structure on the basis of quantum mechanics without requiring phenomenological parameters. DFT calculations applied to understanding the electronic properties of solid-state oxide crystals is based fundamentally on treating the nuclei of the atoms comprising the crystal as fixed via the Born-Oppenheimer approximation, thereby generating a static external potential in which the many-body electron fields are embedded. The crystal structure symmetry of the atomic positions and species imposes a fundamental structure effective potential for the interacting electrons. The effective potential for the many-body electron interactions in three-dimensional spatial coordinates can be implemented by the utility of functionals of the electron density. This effective potential includes exchange and correlation interactions, representing interacting and non-interacting electrons. For application to solid-state semiconductors and oxides there exists a range of improved exchange functionals (XCF) that improve the accuracy of the DFT results. Within the DFT framework the many-electron Schradinger equation is divided into two groups: (i) valence electrons; and (ii) inner core electrons. Inner shells electrons are strongly bound and partially screen the nucleus, forming with the nucleus an inert core. Crystal atomic bonds are primarily due to the valence electrons. Therefore, inner electrons can be ignored in a large number of cases, thereby reducing the atoms comprising the crystal to an ionic core that interacts with the valence electrons. This effective interaction is called a pseudopotential and approximates the potential felt by the valence electrons. One notable exception of the effect of inner core electrons is in the case of Lanthanide oxides, wherein partially filled Lanthanide atomic 4f-orbitals are surrounded by closed electron orbitals. The present DFT band structures disclosed herein account for this effect. There exist many improvements for XCF to attain higher accuracy of band structures applied to oxides. For example, improvements over historical XCFs of the known local density approximation (LDA), generalized gradient approximation (GGA) hybrid exchange (e.g., HSE (Heyd-Scuseria-Ernzerhof), PBE (Perdew-Burke-Ernzerhof) and BLYP (Becke, Lee, Yang, Parr)) include the use of the Tran-Blaha modified Becke-Johnson (TBmBJ) exchange functional, and further modifications, such as the KTBmBJ, JTBSm, and GLLBsc forms. It was found in accordance with the present disclosure that in particular for the present materials disclosed, the TBmBJ exchange potential can predict the electron energy-momentum (E-k) band structure, bandgaps, lattice constants, and some mechanical properties of epitaxial oxide materials. A further benefit of the TBmBJ is the lower computational cost compared to HSE when applied to a large number of atoms in large supercells which are used to simulate smaller perturbations to an idealized crystal structure, such as impurity incorporation. It is expected that further improvements over TBmBJ applied specifically to the present oxide systems can also be achieved. DFT calculations are used extensively in the present disclosure to provide ab-initio insights into the electronic and physical properties of the epitaxial oxide materials described herein, such as the bandgap and whether the bandgap is direct or indirect in character. The electronic and physical properties of the epitaxial oxide materials can be used to design semiconductor structures and devices utilizing the epitaxial oxide materials. In some cases, experimental data has also been used to verify the properties of the epitaxial oxide materials and structures described herein.

Calculated E-k band diagrams of epitaxial oxide materials derived using DFT calculations are described herein. There are several features of the E-k diagrams that can be used to provide insight into the electronic and physical properties of the epitaxial oxide materials. For example, the energies and k-vectors of valence band and conduction band extrema indicate the approximate energy width of the bandgap and whether the bandgap has a direct or an indirect character. The curvature of the branches of the valence band and conduction band near the extrema are related to the hole and electron effective masses, which relates to the carrier mobilities in the material. DFT calculations using the TBmBJ exchange functional more accurately shows the magnitude of the bandgap of the material compared to previous exchange functionals, as verified by experimental data. The calculated band diagrams of epitaxial materials in this disclosure may differ from the actual band diagrams of the epitaxial materials in some ways. However, certain features, such as the valence band and conduction band extrema, and the curvature of the branches of the valence band and conduction band near the extrema, may closely correspond to the actual band diagrams of the epitaxial materials. Therefore, even if some details of the band diagrams are inaccurate, the calculated band diagrams of epitaxial materials in this disclosure provide useful insights into the electronic and physical properties of the epitaxial oxide materials, and can be used to design semiconductor structures and devices utilizing the epitaxial oxide materials.

### Magnesium-Germanium Oxides

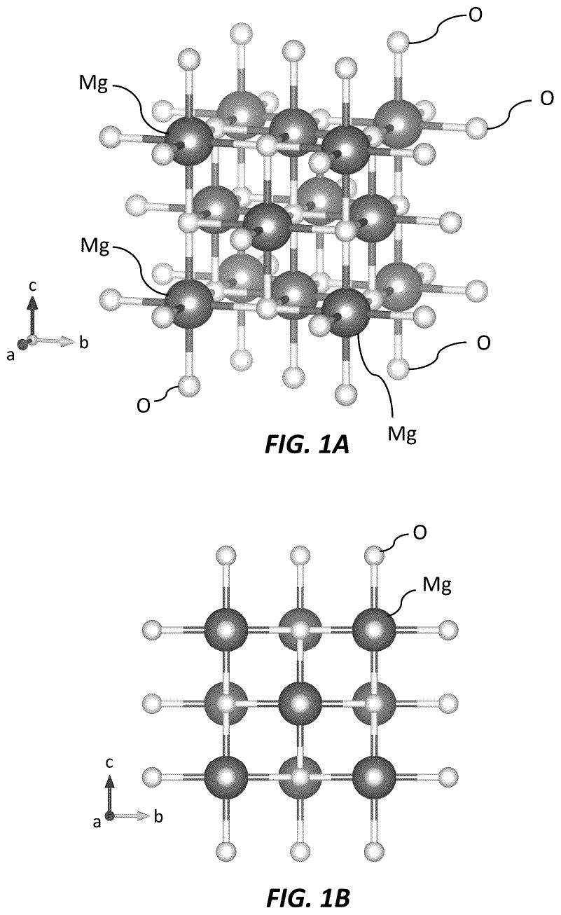

FIGS. 1A and 1B show perspective and plan views, respectively, of a cubic crystal symmetry MgO structure. The figures show the atomic positions of magnesium atoms (“Mg”) and oxygen atoms (“O”) of a single unit cell that is characterized by lattice constant a₀. Cubic crystal MgO is the most stable form of this composition which seldom forms any other polytypes where the unit cell is classified in the cubic Fm3m space group. In this crystal structure the Mg atoms are octahedrally bound to the oxygen atoms. Cubic crystal MgO is known and may be formed readily as a bulk substrate or film. However, aspects of the present disclosure provide unique insights in using materials such as MgO to serve as low crystal lattice mismatch substrates for growing certain forms of epitaxial MgₓGe_{y}O_{z} as a single crystal structure.

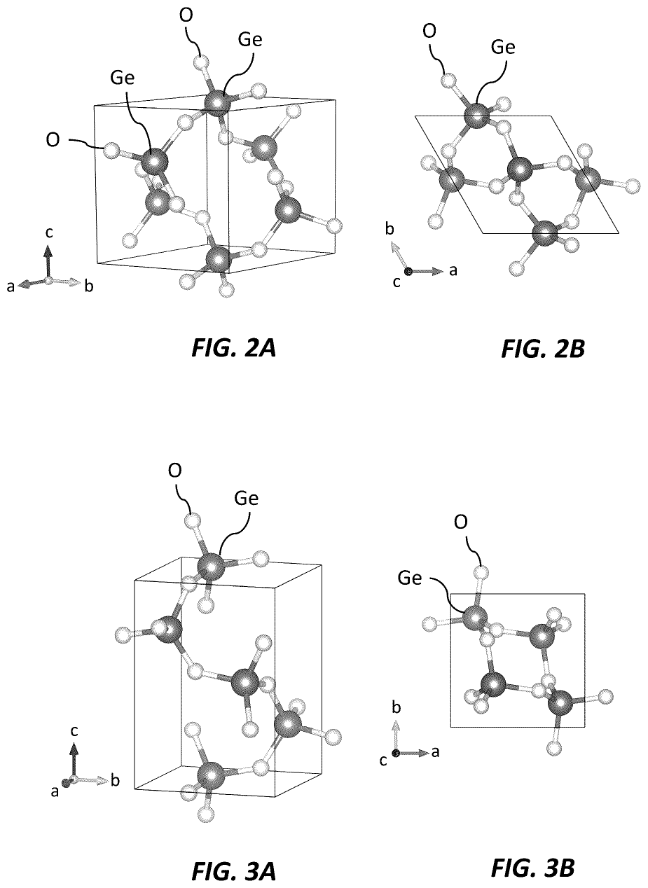

FIGS. 2A and 2B show perspective and plan views, respectively, of one example of a low formation energy crystal structure for GeO₂, in accordance with some aspects. A low formation energy corresponds to the composition being a stable structure. The structure of FIGS. 2A and 2B is trigonal GeO₂ characterized by lattice constants a, b and c where a≠b≠c. As can be seen, the Ge atoms (“Ge”) are tetrahedrally bonded to the oxygen atoms (“O”).

FIGS. 3A and 3B, show perspective and plan views, respectively, of a second example of a low formation energy crystal structure for GeO₂, in accordance with some aspects. The structures are tetragonal GeO₂ characterized by lattice constants a₀ and c₀ where a₀≠c₀. Once again, the Ge atoms are tetrahedrally bonded to the O atoms. The low energy forms of FIGS. 2A-2B and 3A-3B provide stable structures. There are also other types of GeO₂ crystal structures, but these are less stable than those depicted in FIGS. 2A-2B and 3A-3B.

In practice, the formation of large single crystals of GeO₂ is challenging to form and at best polycrystalline or amorphous films are formed. It was found in accordance with the present disclosure after investigation of exhaustive growth parameters that crystalline GeO₂ can be stabilized by the addition of other elements, such as Mg and Zn, and even Al and Ga.

The present disclosure uniquely utilizes these relatively stable forms of octahedral Mg—O bonds and tetrahedral Ge—O bonds to enable growth of MgₓGe_{y}O_{z} layers in forming single crystal structures, using carefully selected substrates. Aspects also enable doping of the MgₓGe_{y}O_{z} materials in various manners, using properties of the octahedral and tetrahedral bonding sites.

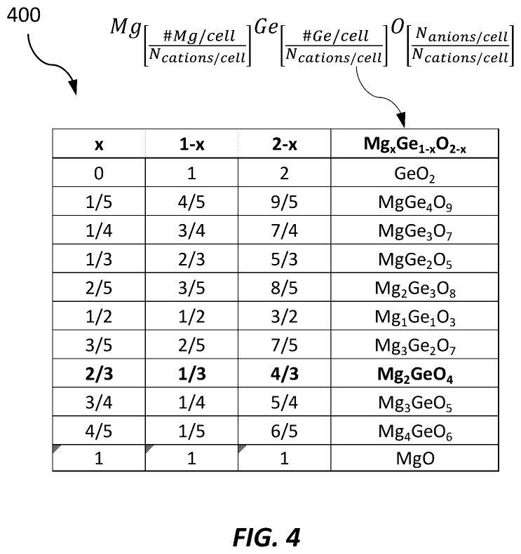

Many possible structures of MgₓGe_{y}O_{z} were investigated in relation to the present disclosure. FIG. 4 shows an example table 400 of potential single crystal compositions that may be formed from Mg, Ge and O, listed in an order transitioning from GeO₂ at the top of the table to MgO at the bottom. In this table, a unit cell is classified according to MgₓGe₁₋ₓO₂₋ₓ with x ranging from 0 to 1 wherein x=0 represents the binary GeO₂ and x=1 the binary MgO. As will be seen, the most stable composition corresponds to x=2/3 with resulting composition Mg₂GeO₄. The specific unit cell of the crystal structure comprises a range of unique spatial positions of the Mg and Ge cations as well as the oxygen anions. The space and point group of the specific crystal are determined the atomic arrangement within the unit cell. The general formula in FIG. 4 is used to describe the various configurations possible.

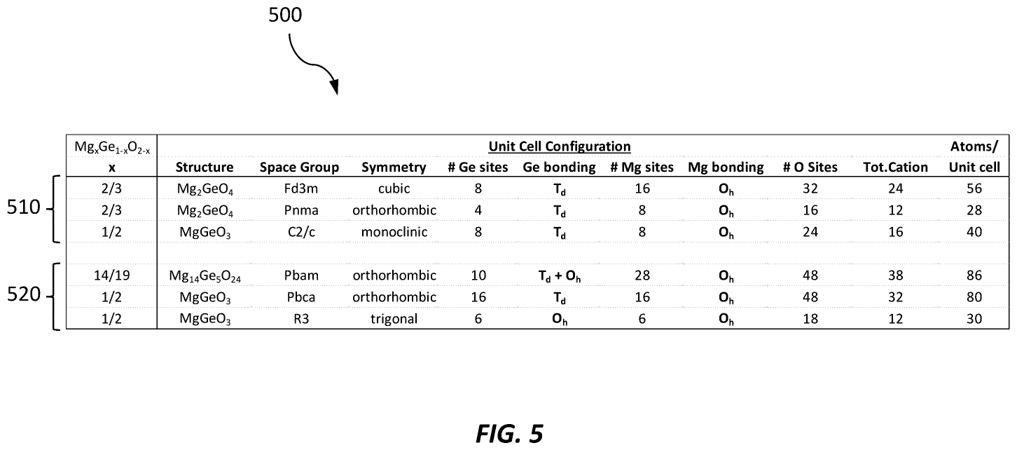

From the possible compositions of Mg, Ge and O such as those shown in FIG. 4, a selection of possible single crystal compositions formed from Mg, Ge and O was modeled, taking into consideration the stability of the compositions. Example single crystal compositions are shown in table 500 of FIG. 5, with the structures of group 510 being the most stable of the structures investigated and those of group 520 being the next most stable. Table 500 shows the relevant space group and symmetry classifications for each composition (or structure). Table 500 also shows the type of bonding for both Ge and Mg, where T_{d} indicates tetrahedral bonding to O atoms, and Oₕ indicates octahedral bonding to O atoms. For Mg₁₋₄Ge₅O₂₄ the Ge bonding to O atoms is a combination of T_{d} and Oₕ bonding. The most stable MgₓGe₁₋ₓO₂₋ₓ structures exhibit crystal symmetry group of the type: x=2/3 Cubic (Fd3m), x=2/3 Orthorhombic (Pnma) and x=1/2 Monoclinic (C2/c), which were of particular interest.

Density function theory (DFT) calculations using the Tran-Blaha modified Becke-Johnson (TBmBJ) exchange potential can predict the electron energy-momentum (E-k) diagrams, bandgaps, lattice constants, and some mechanical properties of epitaxial oxide materials.

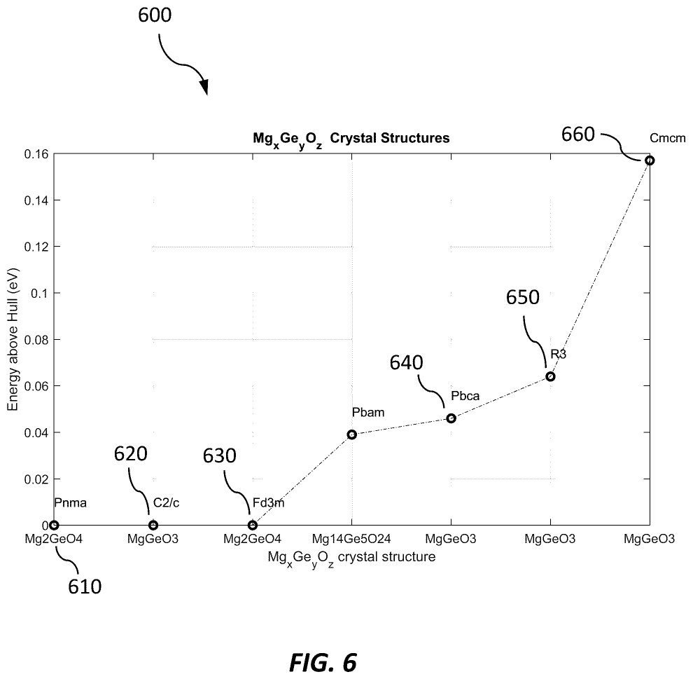

FIG. 6 illustrates characteristics of the structures of table 500 in graphical form. Plot 600 shows the calculated relative energy above Hull (in electron volts, eV) of different single crystal compositions and space groups formed from Mg, Ge, and O (i.e., MgₓGe_{y}O_{z}). Thermodynamically stable compounds exhibit an energy above the convex hull, E_{bull}=0.0 eV/atom, and higher values indicate increasing metastability. A value for the energy above Hull of zero represents the most stable crystal form, progressing to less stable forms as the energy above Hull increases (i.e., increasing formation energies). The most stable compositions (i.e., low formation energy) are depicted starting on the left side of the plot 600, with the compositions being less stable (i.e., higher formation energies) progressing toward the right along the plot 600. As can be seen, the single crystal compositions Mg₂GeO₄ having Pnma space group (orthorhombic symmetry) at point 610 on plot 600, MgGeO₃ having C2/c space group (monoclinic symmetry) at point 620, and Mg₂GeO₄ having Fd3m space group (cubic symmetry) at point 630 are equivalent in terms of stability, having thermodynamically stable structures with low formation energy. Plot 600 also illustrates that changing the crystal structure can result in different stability even with the same stoichiometry of MgₓGe_{y}O_{z}. For example, MgGeO₃ having a crystal structure of having R3 space group (point 650) is less stable than MgGeO₃ having Pbca space group (point 640), and MgGeO₃ having Cmcm space group (point 660) is even less stable.

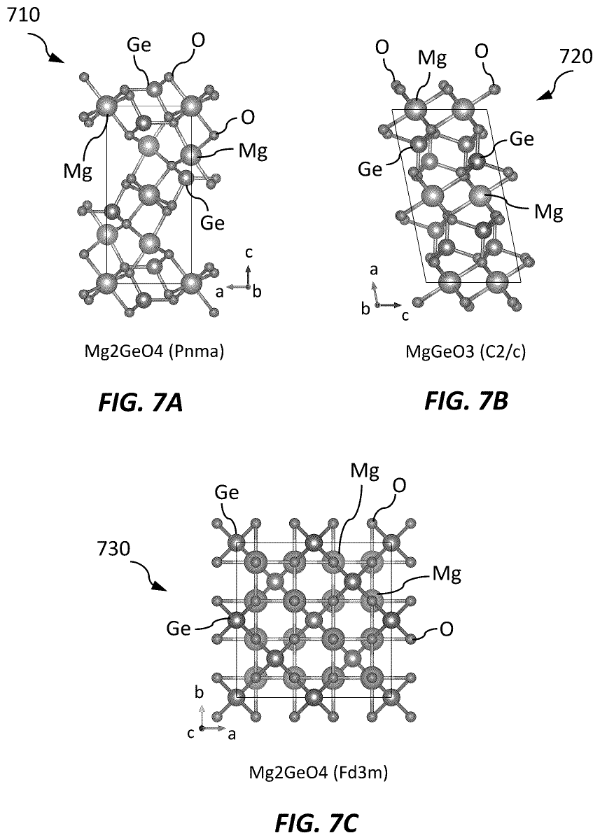

FIGS. 7A, 7B and 7C are crystal lattice diagrams for examples of MgₓGe_{y}O_{z} that may be formed in single crystal semiconductor structures, in accordance with some aspects. Each figure shows a fundamental unit cell for single crystal compositions formed from Mg, Ge, and oxygen (O). FIG. 7A is a unit cell 710 for Mg₂GeO₄ (Pnma space group), having a bandgap E_{g} of 6.4066 eV and a formation energy of −163.1986 eV per atom. FIG. 7B is a unit cell 720 for MgGeO₃ (C2/c space group), having a bandgap E_{g} of 5.1694 eV and having a formation energy of −117.6576 eV per atom. FIG. 7C is a unit cell 730 for Mg₂GeO₄(Fd3m space group) having a bandgap E_{g} of 5.8056 eV and formation energy of −81.9710 eV per atom. Of the three forms depicted, Mg₂GeO₄ (Fd3m) has the combination of: a bandgap potentially in the UVC band (i.e., approximately 200-280 nm) and exhibiting a direct bandgap, the best formation energy, and being of cubic crystal symmetry which would be expected to be more readily grown by epitaxial methods.

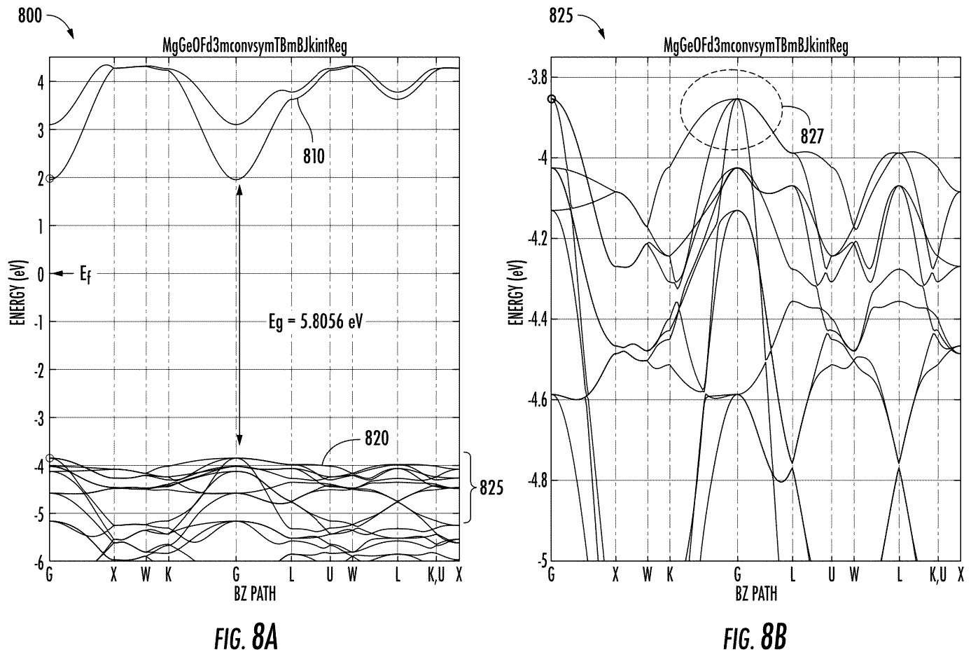

Bandgap characteristics of the forms of MgₓGe_{y}O_{z} in FIGS. 7A, 7B and 7C were calculated and are shown in FIGS. 9A-9B, 10A-10B, and 8A-8B, respectively. FIGS. 8A and 8B show bandgap modeling of the Mg₂GeO₄(Fd3m) structure of FIG. 7C. FIG. 8A is an E-k diagram 800 for Mg₂GeO₄(Fd3m), showing the calculated valence band 820 and conduction band 810 structure. The diagram 800 shows energy (eV) on the y-axis versus Brillouin-zone (BZ) path along the x-axis. The direct bandgap between the conduction band 810 and the valence band 820 is shown at the Brillouin-zone center, where the bandgap energy Eg is 5.8056 eV. FIG. 8A illustrates that Mg₂GeO₄(Fd3m) is a direct bandgap semiconductor material, where the maximum of the valence band 820 and the minimum of the conduction band 810 occur at the zone center where k=0. FIG. 8B is an enlarged view 825 of the valence band structure. As can be seen in FIG. 8B, the valence band structure in region 827 at the zone center has a relatively large curvature and is parabolic-like, indicating that there will be good mobility (e.g., greater than 1 cm²/Vs, or greater than 10 cm²/Vs, or greater than 100 cm²/Vs) for holes. As also can be seen from FIG. 8A, the Fermi energy (E_{f}=0) is located approximately mid-gap between the valence and conduction bands indicating that Mg₂GeO₄ (Fd3m) will be a semiconductor having high resistivity (e.g., an intrinsic or low doped semiconductor).

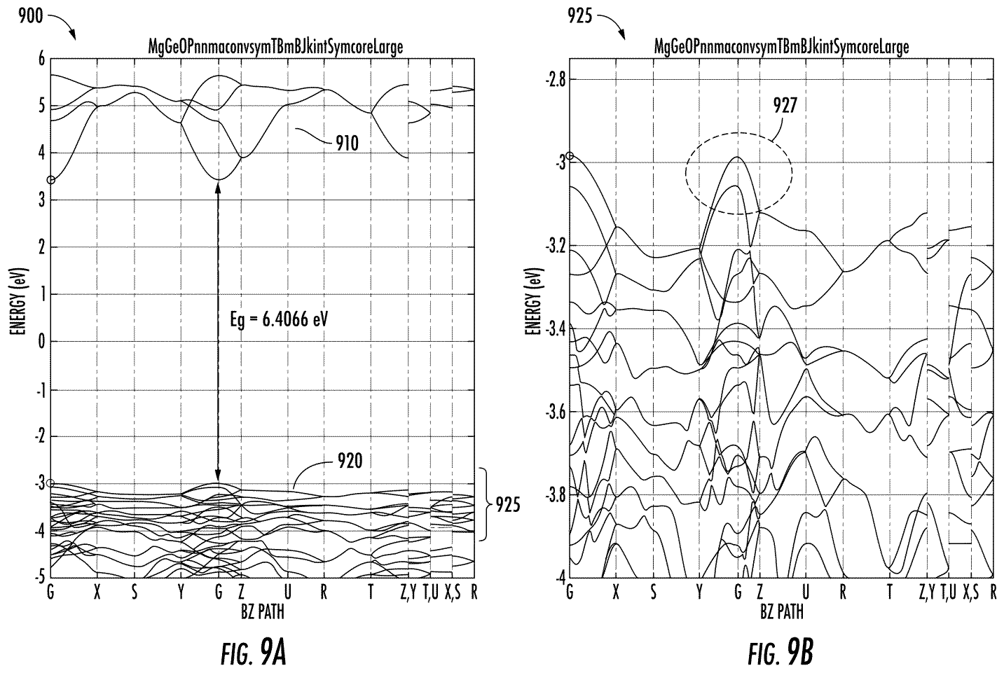

FIG. 9A shows an E-k diagram 900 for Mg₂GeO₄ (Pnma) (see FIG. 7A), with the calculated valence band 920 and conduction band 910 structure. FIG. 9B is an enlarged view 925 of the valence band structure. The direct bandgap is shown at the Brillouin-zone center, having a bandgap energy E_{g} of 6.4066 eV. As can be seen, Mg₂GeO₄ (Pnma) is a direct bandgap semiconductor material, where the maximum of the valence band and the minimum of the conduction band occur at the zone center where k=0. FIG. 9B illustrates that the valence band structure in region 927 at the zone center has high curvature, which indicates that there will be good mobility for holes. As also can be seen from FIG. 9A, the Fermi energy (E_{f}) is located approximately mid-gap between the valence and conduction bands indicating that Mg₂GeO₄ (Pnma) will be a semiconductor having high resistivity (e.g., an intrinsic or low doped semiconductor).

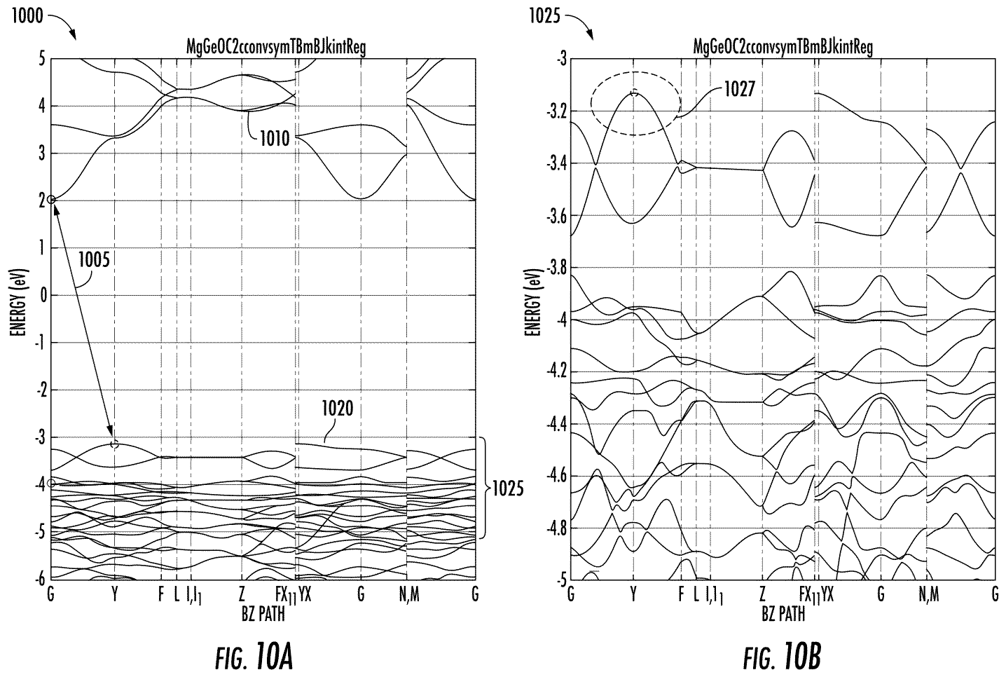

FIG. 10A shows an E-k diagram 1000 for MgGeO₃ (C2/c) (see FIG. 7B), with the calculated valence band 1020 and conduction band 1010 structure. FIG. 10B is an enlarged view 1025 of the valence band structure. As can be seen, MgGeO₃ (C2/c) is an indirect bandgap semiconductor material as the maximum of the valence band and the minimum of the conduction band occur at different k values and as such would be expected to be a poor optical emitter. That is, in some aspects the MgₓGe₁₋ₓO₂₋ₓ is MgGeO₃ with a C2/c space group and is an indirect bandgap material. The indirect bandgap is observed for different k-vectors between the conduction band minimum and valence band maximum, with one example being indicated by arrow 1005. As can be seen in FIG. 10B, the valence band structure in region 1027 at the zone center has a curvature, indicating that there will be good mobility for electron holes. As also can be seen from FIG. 10A, the Fermi energy (E_{f}) is located approximately mid-gap between the valence and conduction bands indicating that MgGeO₃ (C2/c) will be a semiconductor having high resistivity (e.g., an intrinsic or low doped semiconductor).

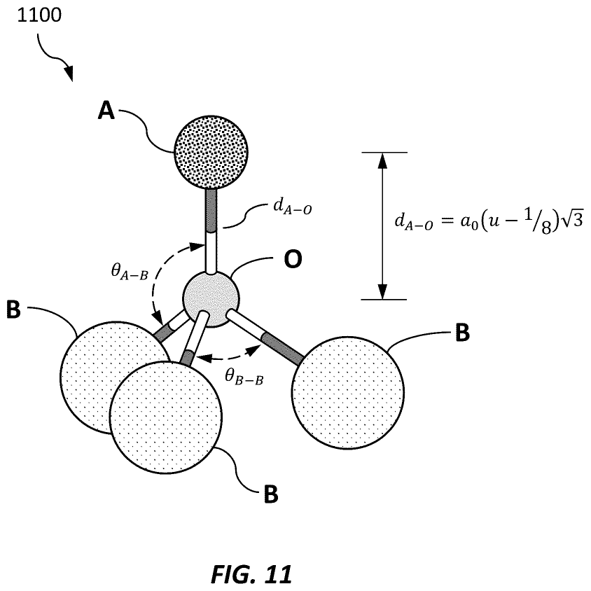

Referring now to FIG. 11, a local tetrahedron bonding configuration 1100 within a Fd3m cubic crystal of the form AB₂O₄ is shown, where the A and B cations are tetrahedrally and octahedrally bonded to an oxygen (O) atom, respectively. The critical bond length d_{A-O} between the A and O atoms is annotated in FIG. 11. Equation 1 is presented in accordance with the present disclosure to study the stability and cation interchangeability of possible configurations of MgₓGe_{y}O_{z} structures. For the case of an ideal Fd3m unit cell, cations in tetrahedral coordination occupy special position 8a (point symmetry 43m at Wyckoff position

$$( \frac{1}{8} , \frac{1}{8} , \frac{1}{8} ) ,$$

while the octahedrally coordinated cations reside on special position 16d (point symmetry 3m at

$$( \frac{1}{2} , \frac{1}{2} , \frac{1}{2} ) ) .$$

The anions are at equipoint position 32e, which requires one positional parameter u. For u=0.25, an ideal cubic closed packing of anions is realized and therefore variations in u reflect the adjustment of the structure to accommodate cations of different size in octahedral and tetrahedral positions. For example, decreasing values of u below 0.25 moves the anions along [111] direction toward the nearest tetrahedral cation, thereby decreasing the size of the tetrahedron at the extent of the size of the octahedron.

The bond length between the tetrahedral Ge cation and O anion d_{A-O} is given by:

$${d}_{A - O} = {a}_{o} ( u - \frac{1}{8} ) \sqrt{3} \qquad ( Equation 1 )$$

where a₀ is the cubic unit cell lattice constant. For the case of bulk freestanding Fd3m Mg₂GeO₄ crystal structure it is found that a₀=8.3499 Å, d_{A-O}=1.8054 Å and thus u=0.2498 Å.

For example, if the B atom has a valence coordination number of +2, such as magnesium (i.e., cation site B=Mg), and the A atom has a valence coordination number of +4, such as germanium (i.e., cation site A=Ge), then the cubic composition AB₂O₄=GeMg₂O₄ (i.e., Mg₂GeO₄) is formed. A consideration in studying growth of MgₓGe_{y}O_{z} structures in accordance with the present disclosure is whether Mg₂GeO₄ will adopt a normal spinel structure, or alternatively will adopt the less stable spinel structure with some interchange between cations on tetrahedral and octahedral sites. That is, a normal spinel structure would be expected to self-assemble exclusively with Mg cations located at octahedral sites and Ge cations located at tetrahedral sites within the crystal and in general enable co-deposition which is desirable for epitaxial growth.

Deformation of the Fd3m unit cell can also alter the oxygen u parameter for example, via biaxial strain during pseudomorphic epitaxial deposition on a lattice mismatched surface. Tetragonal distortion will clearly influence the structural and electronic properties of Mg₂GeO₄.

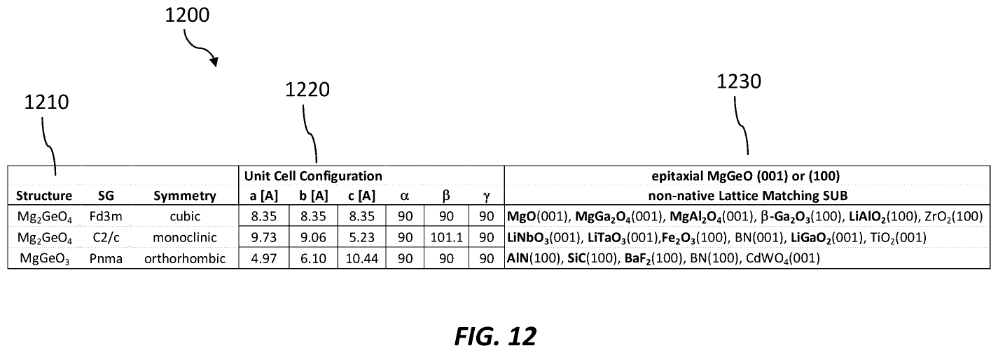

Using these crystal structure considerations, various forms of MgₓGe_{y}O_{z} were investigated. In FIG. 12, table 1200 depicts examples of compatible substrates compositions and orientations upon which single crystal compositions 1210 of Mg₂GeO₄ (Pnma), MgGeO₃ (C2/c), Mg₂GeO₄ (Fd3m) of (001) or (100) orientation may be epitaxially formed. At present in the industry there are no examples of bulk large area single crystal native Mg₂GeO₄ substrates and therefore heteroepitaxial methods are required. The space group “SG” and crystal symmetry type are listed for each composition. Possible substrates 1230 for the compositions 1210 are disclosed, noting that the seeding substrate may not be ideally lattice matched (i.e., is non-native lattice matching) to the MgGeO composition that is to be epitaxially formed. The crystal structures of the respective unit cells of MgₓGe_{y}O_{z} are also disclosed as shown by the unit cell configuration parameters 1220, including the lattice constants a, b, c and angles α, β, γ. The magnitude of lattice mismatch between the MgₓGe_{y}O_{z} film and substrate are preferably selected to enable the growth of single crystal epitaxial films with low defect density.

In some aspects, the crystal symmetry of the substrate material may be cubic or tetrahedral. In some aspects, the substrate material comprises MgO(001), MgGa₂O₄(001), MgAl₂O₄(001), or LiF(100). In some aspects, the substrate material comprises β-Ga₂O₃(100), LiAlO₂(100), ZrO₂(100), LiNbO₃ (001), LiTaO₃ (001), Fe₂O₃(100), BN(001), LiGaO₂(001), TiO₂(001), AlN(100), SiC(100), BaF₂(100), BN(100), or CdWO₄(001).

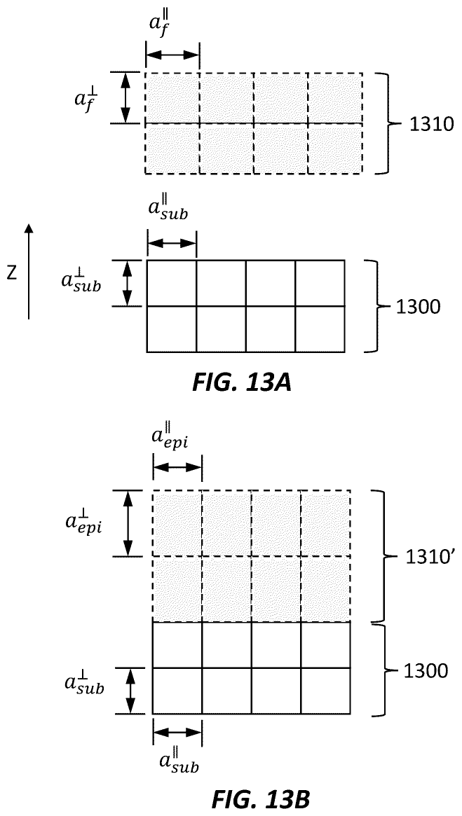

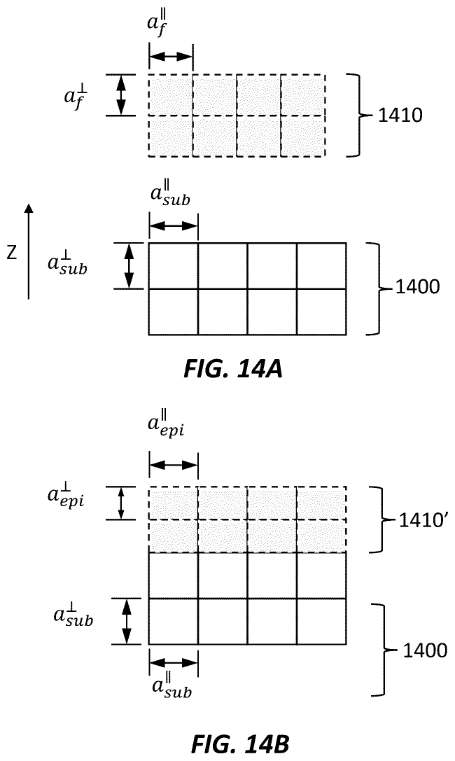

Schematics of single crystal structures of MgₓGe_{y}O_{z} films (i.e., epitaxial layers) on substrates are depicted in FIGS. 13A-13B and 14A-14B, where the substrate materials are chosen (i.e., pre-determined) for their compatibility with the type of MgₓGe_{y}O_{z} being grown.

FIG. 13A is a schematic diagram showing two distinct free-standing crystal structures corresponding to a film 1310 and a substrate 1300 both having a cubic or tetrahedral symmetry. The growth direction Z is shown. The film 1310 has a larger in-plane lattice constant (also referred to as a parallel lattice constant) than the substrate; that is, a_{f}^{∥}>a_{sub}^{∥}. It is noted that free-standing cubic crystals exhibit equal in-plane and perpendicular lattice constants aᵢ^{∥}= [symbol] , where i={sub, film}. That is, prior to the formation of any epitaxial layer (i.e., if the film material is in a free-standing state, not grown on the substrate), the parallel and perpendicular lattice constants of the film will be equal to each other (a_{f}^{∥}= [symbol] ) due the cubic or tetrahedral (a_{f}^{∥}≠ [symbol] ) symmetry of the film material. Similarly, the parallel and perpendicular lattice constants of the substrate (a_{sub}^{∥}= [symbol] ) will be equal due to the cubic or tetrahedral symmetry of the substrate.

FIG. 13B is a schematic diagram showing the film 1310 of FIG. 13A epitaxially grown on the substrate 1300. FIG. 13B illustrates the effect of epitaxially forming a layer having cubic symmetry on a substrate that also has cubic symmetry, where the free-standing in-plane lattice constant of the film is greater than the in-plane lattice constant of the substrate. Upon forming the epitaxial layer 1310′, the film material will elastically deform and will be in a strained state as compared to its free-standing (or relaxed) state (film 1310) so that the parallel or in-plane lattice constant of the epitaxial layer (aₑₚᵢ^{∥}) will match the parallel or in-plane lattice constant of the substrate 1300 (i.e., aₑₚᵢ^{∥}=a_{sub}^{∥}, with aₑₚᵢ^{∥}<a_{f}^{∥}). The resulting epitaxial layer 1310′ is formed in compression. Due to the Poisson effect, this deformation will result in the perpendicular lattice constant aₑₚᵢ^{⊥} of the resulting epitaxial layer 1310′ to be increased, being greater than the perpendicular lattice constant of the original film material (i.e., [symbol] > [symbol] ) according to the Poisson's ratio for the material.

Accordingly, a high-quality epitaxial layer may be formed via elastic deformation of the film unit cell during growth to accommodate the in-plane lattice mismatch. This is defined herein as pseudomorphic epitaxy. FIGS. 13A-13B illustrate that designing semiconductor structures in which both the epitaxial layers and substrates have cubic and tetrahedral symmetry can be used advantageously in accordance with aspects of the present disclosure. In some aspects, the substrate and film have cubic or tetrahedral crystal symmetries such that the in-plane lattice constants are equal (a_{f}^{∥}= [symbol] and a_{sub}^{∥}= [symbol] ) and the in-plane lattice constants of the film are greater than those of the substrate (a_{f}^{∥}>a_{sub}^{∥}) In such cases, the perpendicular lattice constant of the epitaxial film will be increased when grown on the substrate, resulting in the film generally accumulating in-plane compressive stress. Furthermore, compression was observed in some cases to facilitate growth of the epitaxial layers.

FIGS. 14A-14B are similar to FIGS. 13A-13B, but with the epitaxial layer being strained in tension. FIG. 14A is a schematic diagram showing two distinct free-standing crystal structures corresponding to a film 1410 and a substrate 1400, both having a cubic or tetrahedral symmetry. The film 1410 has a smaller in-plane (i.e., parallel) lattice constant than the substrate 1400; that is, a_{f}^{∥}<a_{sub}^{∥}. Prior to the formation of any epitaxial layer, the parallel and perpendicular lattice constants of the film will be equal (a_{f}^{∥}= [symbol] ), and similarly, the parallel and perpendicular lattice constants of the substrate will be equal (a_{sub}^{∥}= [symbol] ) due to the cubic or tetrahedral symmetry of the materials.

FIG. 14B is a schematic diagram showing the effect of epitaxially forming a layer having a cubic (or tetrahedral) symmetry on a substrate that also has a cubic (or tetrahedral) symmetry, where the free-standing in-plane lattice constant of the original film 1410 is less than the in-plane lattice constant of the substrate 1400 (i.e., a_{f}^{∥}<a_{sub}^{∥} such as shown in FIG. 14A). Upon forming the epitaxial layer 1410′, the film material will elastically deform so that the in-plane lattice constant aₑₚᵢ^{∥} will match the in-plane lattice constant of the substrate (i.e., aₑₚᵢ^{∥}=a_{sub}^{∥}, with aₑₚᵢ^{∥}>a_{f}^{∥}). Due to the Poisson effect, this deformation will cause the perpendicular lattice constant of the resulting epitaxial layer to be reduced to less than the perpendicular lattice constant of the original film material (i.e., [symbol] < [symbol] ). The elastic tetragonal distortion of the film unit cell due to matching the in-plane lattice constant with that of the substrate results in a reduction of the film perpendicular lattice constant (i.e., [symbol] < [symbol] ). The resulting epitaxial layer is formed in tension, where the layer in general accumulates in-plane tensile stress.

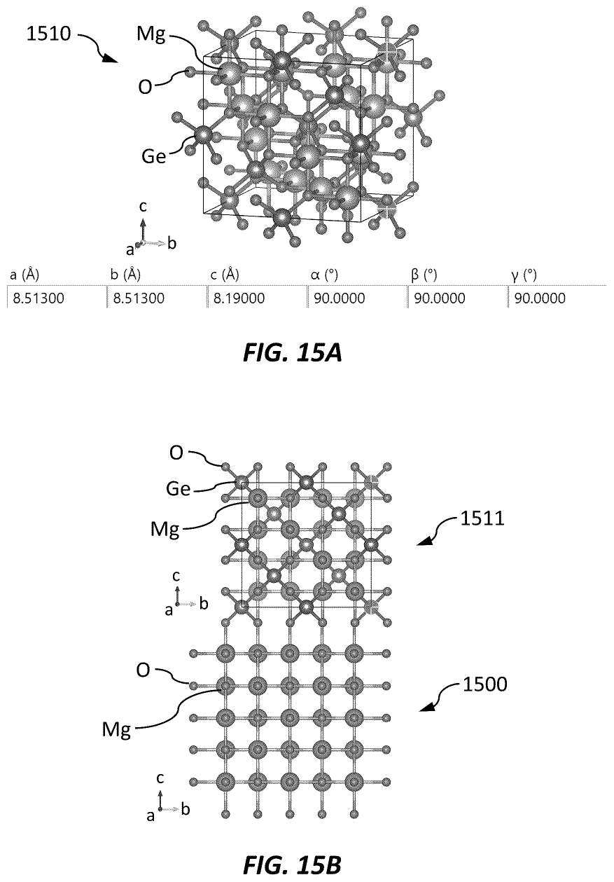

FIGS. 15A-15B show crystal structure diagrams of cubic Fd3m Mg₂GeO₄ crystal 1510, alone and formed on a substrate 1500. In FIG. 15A, a unit cell of cubic Fd3m Mg₂GeO₄ crystal 1510 is elastically deformed equally along the in-plane a- and b-axes, matched to twice the lattice constant of a free-standing cubic MgO crystal. That is, the Mg₂GeO₄ crystal 1510 has tensile biaxial strain matched to MgO (001). The crystal symmetry of the cubic Fd3m space group from this tensile elastic deformation is tetragonally deformed into a new I4amd space group. The lattice constants a, b, and c in Angstroms (Å) are disclosed in FIG. 15A, along with the angles α, β, γ.

FIG. 15B is a figurative diagram of lattice mismatched formation of the epitaxial layer 1511 of Mg₂GeO₄ (Fd3m) crystal formed on a substrate 1500 of cubic MgO (001) showing that the in-plane lattice constant of the film is approximately matched to an integer multiple of the smaller MgO unit cell. In this example, the epitaxial layer 1511 will have tetragonal symmetry with space group I4amd. In this example, formation of the epitaxial layer results in 2 times unit cell matching where 2×a_{MgO}>a_{Mg2GeO4} resulting in the Mg₂GeO₄ (Fd3m) epitaxial layer 1511 being formed in a state of tension on the MgO substrate 1500.

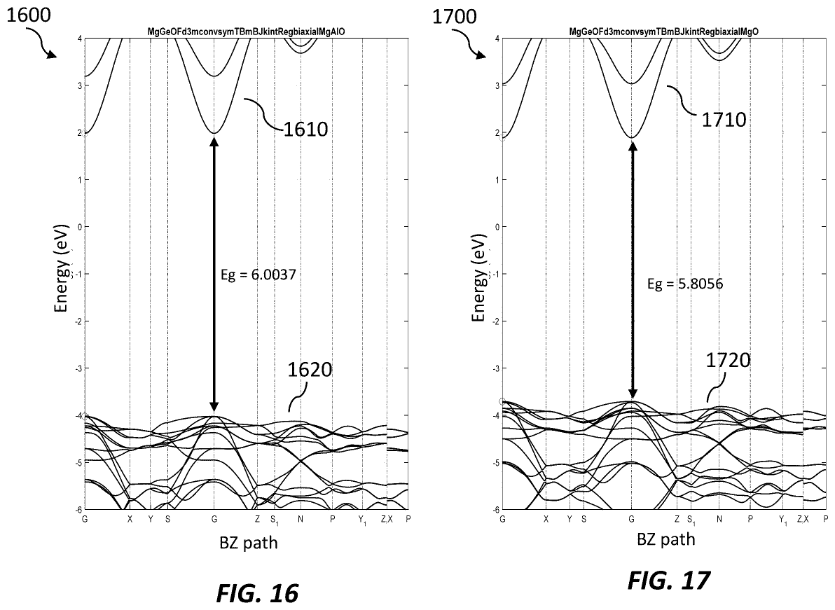

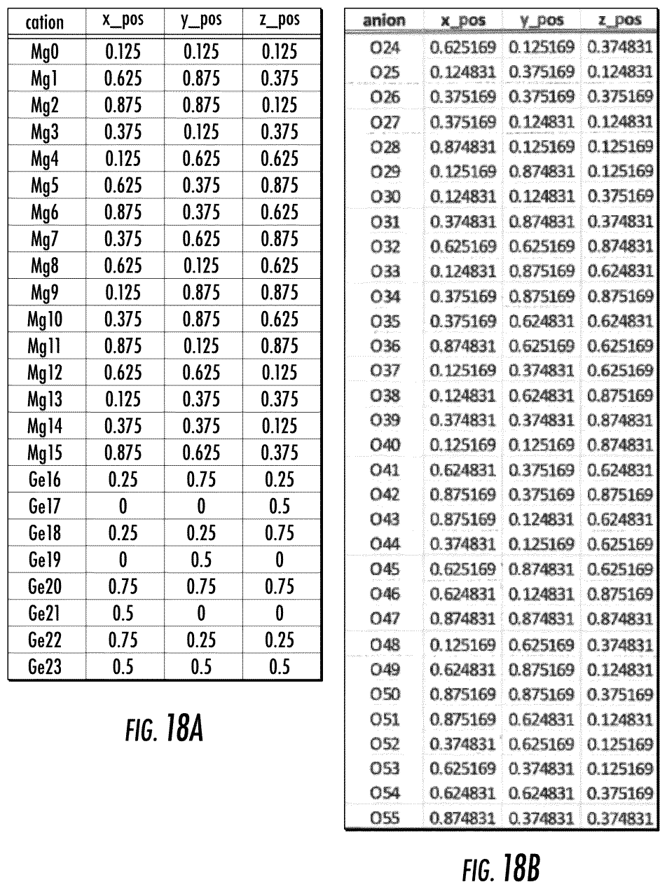

FIGS. 16 and 17 show the effect of strain on bandgap, for an epitaxial layer of cubic Mg₂GeO₄ (Fd3m) on different cubic substrate materials. FIG. 16 is an electronic band structure E-k diagram 1600 for an epitaxial layer of cubic space group Fd3m Mg₂GeO₄ formed on a substrate or rigid layer of cubic Fd3m space group magnesium aluminate MgAl₂O₄. In this example, the lattice constant mismatch of Mg₂GeO₄ and MgAl₂O₄ is ˜+2.2% resulting in a compressive in-plane stress and the Mg₂GeO₄ is formed in a state of compression. The epitaxial layer of cubic space group Fd3m Mg₂GeO₄ still has a direct bandgap, and the minimum of the conduction band 1610 and the maximum of the valence band 1620 occurs at the Brillouin-zone center where k=0 as was the case for the unstrained Mg₂GeO₄ Fd3m of FIG. 8A. However, the bandgap E_{g} of the compressively deformed or strained Mg₂GeO₄ layer at the zone center in diagram 1600 has increased to 6.004 eV, in contrast to an E_{g} of 5.8056 eV in FIG. 8A.

FIG. 17 is an electronic band structure E-k diagram 1700 for an epitaxial layer of cubic space group Fd3m Mg₂GeO₄ formed on a substrate or rigid layer of cubic Fd3m space group magnesium oxide MgO. In this example, the lattice constant mismatch of Mg₂GeO₄ and MgO is ˜−1.9% resulting in a tensile in-plane stress, i.e., the Mg₂GeO₄ is formed in tension. The strained Mg₂GeO₄ bandgap E_{g} between conduction band 1710 and valence band 1720 at the Brillouin-zone center is observed to decrease to 5.806 eV compared to FIG. 16.

As can be understood by this disclosure, compatible (i.e., having low lattice mismatch) combinations of MgₓGe_{y}O_{z} crystal structures and substrate materials are disclosed that enable epitaxial layers of MgₓGe_{y}O_{z} to be formed as an epitaxial single crystal structure with the substrates. In aspects, the epitaxial oxide materials and the substrate materials are selected such that epitaxial layers of a semiconductor structure have in-plane (i.e., parallel with the surface of the substrate) lattice constants (or crystal plane spacings) that are within 0.5%, 1%, 1.5%, 2%, 5% or 10% of an in-plane lattice constant (or crystal plane spacing) of the substrate.

### Magnesium-Germanium-Silicon-Tin Oxides

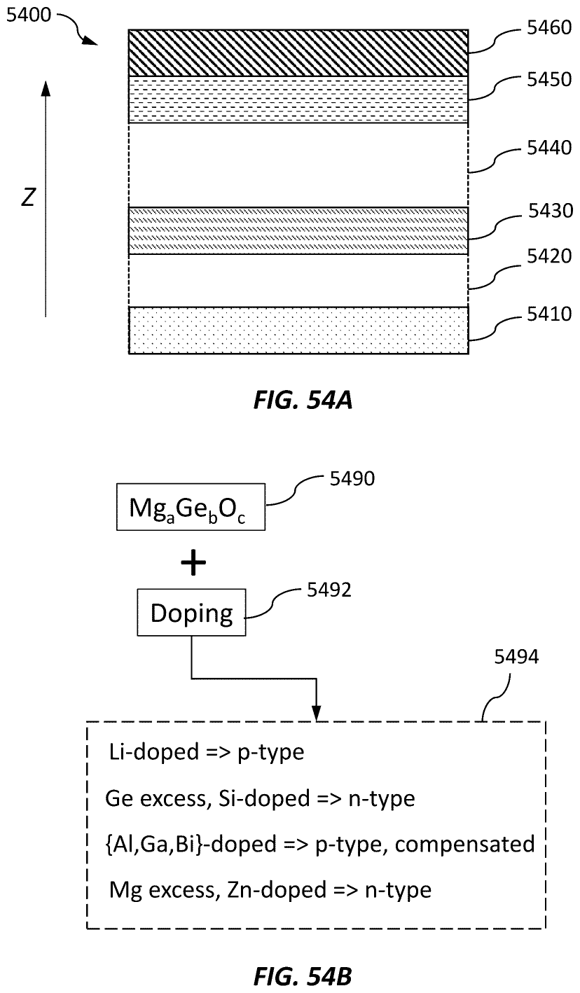

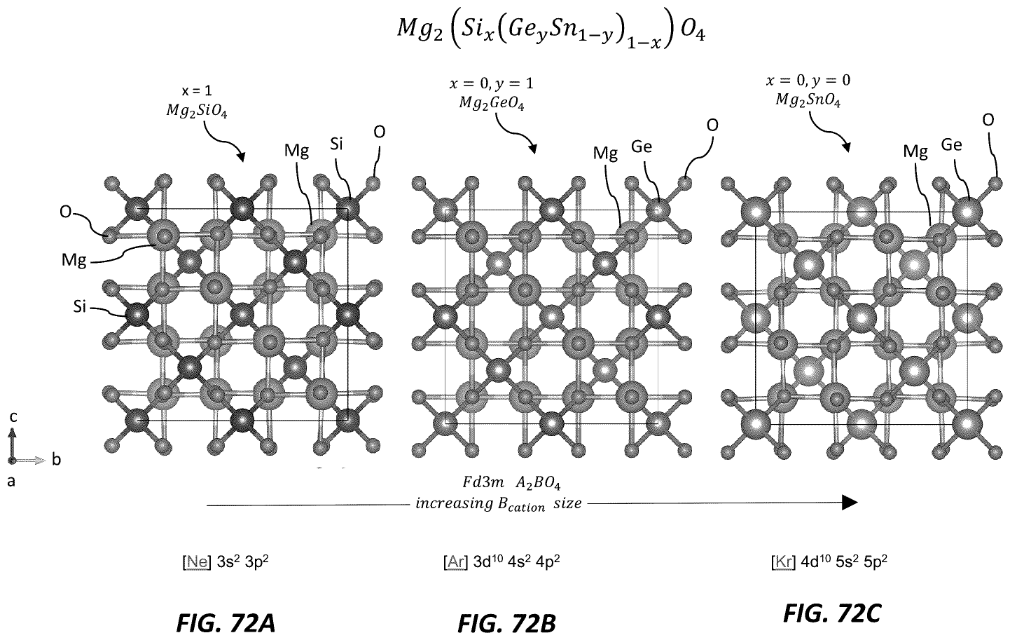

Various forms of Mgₐ(Siₓ(Ge_{y}Sn_{1-y})₁₋ₓ)O_{b} materials are disclosed that are beneficial to various applications, such as semiconductor devices. Examples include epitaxial layers of single crystal Mgₐ(Siₓ(Ge_{y}Sn_{1-y})₁₋ₓ)O_{b}, wherein 1.5≤a≤2.5, 3≤b≤5, 0≤x≤1, and 0≤y≤1, where the single crystal Mgₐ(Siₓ(Ge_{y}Sn_{1-y})₁₋ₓ)O_{b} has a crystal symmetry compatible with a substrate or an underlying layer on which the single crystal Mgₐ(Siₓ(Ge_{y}Sn_{1-y})₁₋ₓ)O_{b} is grown. In some examples, a=2 and b=4 as described in FIGS. 72A-72C. The Mgₐ(Siₓ(Ge_{y}Sn_{1-y})₁₋ₓ)O_{b} materials described herein may be used in one or more layers of semiconductor structures and semiconductor devices, such as in FIGS. 54A-71.

FIGS. 72A-72C show front views of crystal structure diagrams of Mgₐ(Siₓ(Ge_{y}Sn_{1-y})₁₋ₓ)O_{b} in examples where x or y is 0 or 1. In particular, FIGS. 72A-72C depict Fd3m crystal structure forms of A₂BO₄ where A is Mg and B is Si, Ge or Sn. The figures show atomic positions of magnesium atoms (“Mg”), oxygen atoms (“0”), silicon atoms (“Si”), germanium atoms (“Ge”), and tin (“Sn”) atoms. FIG. 72A shows an Fd3m form of Mg₂SiO₄, where a=2, b=4, x=1. FIG. 72B shows an Fd3m form of Mg₂GeO₄, where a=2, b=4, x=0, y=1. FIG. 72C shows an Fd3m form of Mg₂SnO₄, where a=2, b=4, x=0, y=0. FIGS. 72A, 72B and 72C are shown in order of increasing B cation size, with Mg₂SiO₄ having the smallest cation (Si), Mg₂GeO₄ having a larger size cation (Ge) than Si, and Mg₂SnO₄ having the largest cation (Sn) size compared to Si and Ge. Also annotated are the atomic orbitals for Si, Ge, and Sn, with the Si in Mg₂SiO₄ (FIG. 72A) being [Ne]3s² 3p², the Ge in Mg₂GeO₄ (FIG. 72B) being [Ar]3d¹⁰ 4s² 4p², and the Sn in Mg₂SnO₄ (FIG. 72C) being [Kr]4d¹⁰ 5s² 5p².

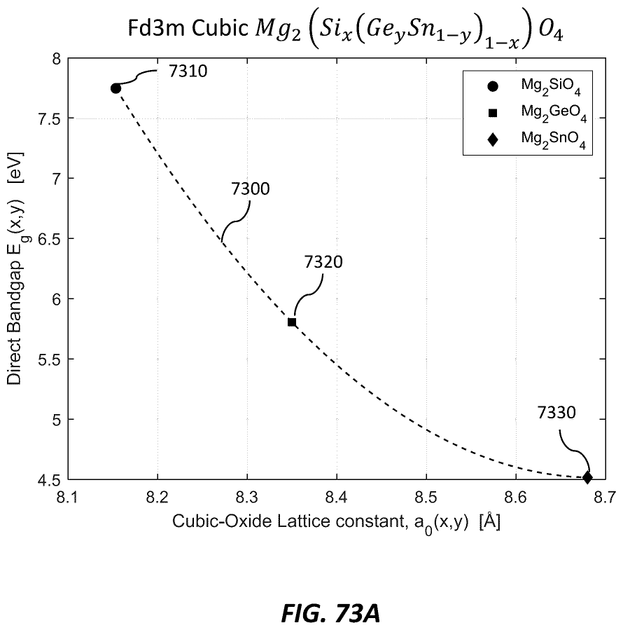

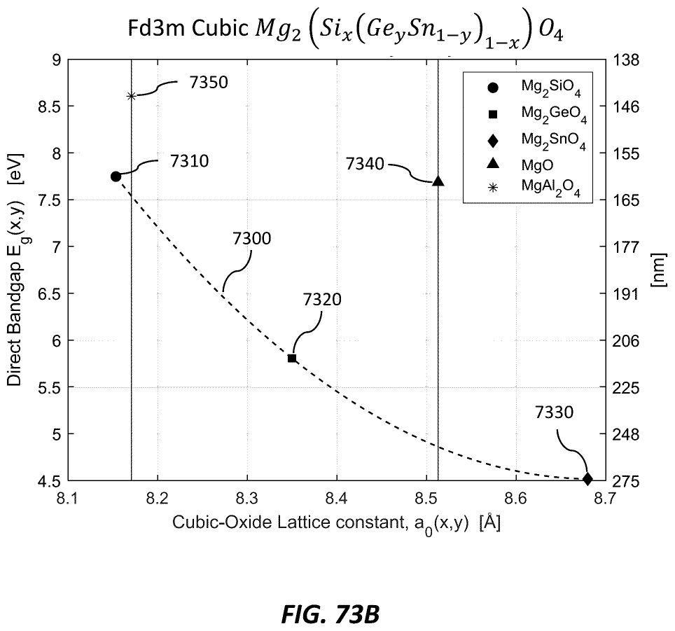

FIG. 73A is a graph showing direct bandgaps for the cubic oxide lattice constants for Mg₂SiO₄, Mg₂GeO₄, Mg₂SnO₄. Direct bandgap materials are beneficial in operating very efficiently in semiconductor devices since the peaks of the valence and conduction bands (top of valence band and bottom of conduction band) are aligned at the same value of momentum, whereas in indirect bandgap materials the peaks are offset. The values for the materials are also shown to have wide bandgaps, ranging from approximately 7.75 eV for Mg₂SiO₄ (point 7310) to approximately 5.8 eV for Mg₂GeO₄ (point 7320) to 4.5 eV for Mg₂SnO₄ (point 7330). Other direct bandgap values may be achieved with quaternary compounds along curve 7300 representing Mg₂(Siₓ(Ge_{y}Sn_{1-y})₁₋ₓ)O₄ where 0≤x≤1 and 0≤y≤1. For example, compounds of Mg₂(Siₓ(Ge_{y})₁₋ₓ)O₄ with 0≤x≤1 and y=1 between points 7310 and 7320 may have direct bandgaps from 5.8 eV to 7.75 eV. In other examples, compounds of Mg₂(Ge_{y}Sn_{1-y})O₄ with x=0 and 0≤y≤1 between points 7320 and 7330 may have direct bandgaps from 4.5 eV to 5.8 eV.

FIG. 73B is the same graph as FIG. 73A but with points for MgO (point 7340) and MgAl₂O₄ (point 7350) shown in comparison to Mg₂SiO₄, Mg₂GeO₄, Mg₂SnO₄. As can be seen, the magnesium-group IV Fd3m cubic materials shown in this figure beneficially provide alternative bandgap values in a similar range of lattice constants as MgO (point 7340) and MgAl₂O₄. This graph also shows that Mg₂(Siₓ(Ge_{y}Sn_{1-y})₁₋ₓ)O₄ materials where 0≤x≤1 and 0≤y≤1 can be epitaxially grown on MgO or MgAl₂O₄ substrates since their in-plane lattice constants are similar. Some compositions of Mg₂(Siₓ(Ge_{y}Sn_{1-y})₁₋ₓ)O₄ can be lattice-matched to MgO or MgAl₂O₄ substrates, where the in-plane lattice constants of the substrate and the epitaxial layer are substantially the same. Other compositions of Mg₂(Siₓ(Ge_{y}Sn_{1-y})₁₋ₓ)O₄ can have different lattice constants than the substrates upon which they are grown and therefore be lattice mismatched and have some degree of strain. The strain can be uniaxial, biaxial, or triaxial. In some cases, the epitaxial layers described herein are grown with thicknesses less than their critical thicknesses, and therefore include some degree of strain rather than being relaxed. For example, epitaxial films with compositions of Mg₂(Siₓ(Ge_{y}Sn_{1-y})₁₋ₓ)O₄ can be coherently formed on MgO or MgAl₂O₄ substrates, with in-plane lattice constant mismatches from about −6% to about +4%. In general, epitaxial films with compositions of Mg₂(Siₓ(Ge_{y}Sn_{1-y})₁₋ₓ)O₄ can be coherently formed on single crystal substrates, with in-plane lattice constant mismatches from −10% to about +10%, or from about −5% to about +5%, or from about −2% to about +2%. Epitaxial films with compositions that have larger lattice constant mismatches with the substrate will correspondingly have smaller critical thicknesses allowable before the film will tend to relax.

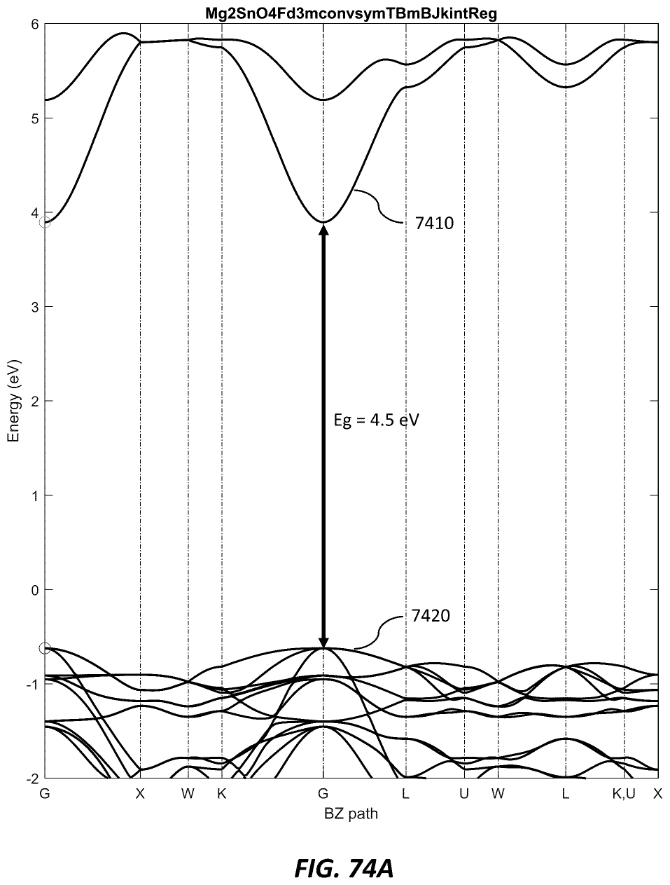

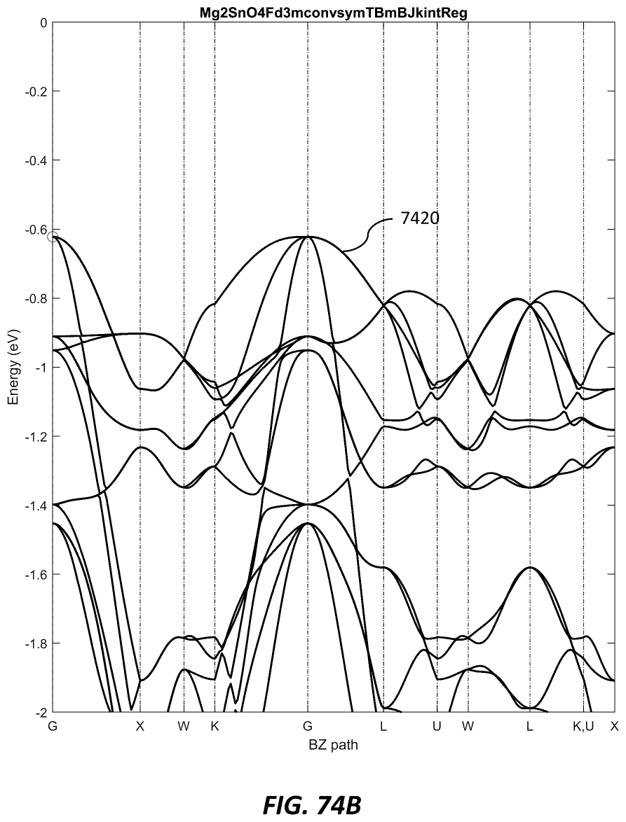

FIGS. 74A-74B, 75A-75B, and 76A-76B are bandgap diagrams for the cubic Fd3m materials of FIGS. 73A-73B, showing conduction and valence bands as generated by DFT calculations that include the TBmBJ exchange functional as discussed above in this disclosure.

FIG. 74A is a bandgap diagram for the Mg₂SnO₄ Fd3m crystal structure, showing that the material is a direct bandgap semiconductor with a bandgap energy (Eg) of approximately 4.88 eV, annotated by the distance between conduction band 7410 and valence band 7420. FIG. 74B is an enlarged view of the top valence band 7420 of FIG. 74A.

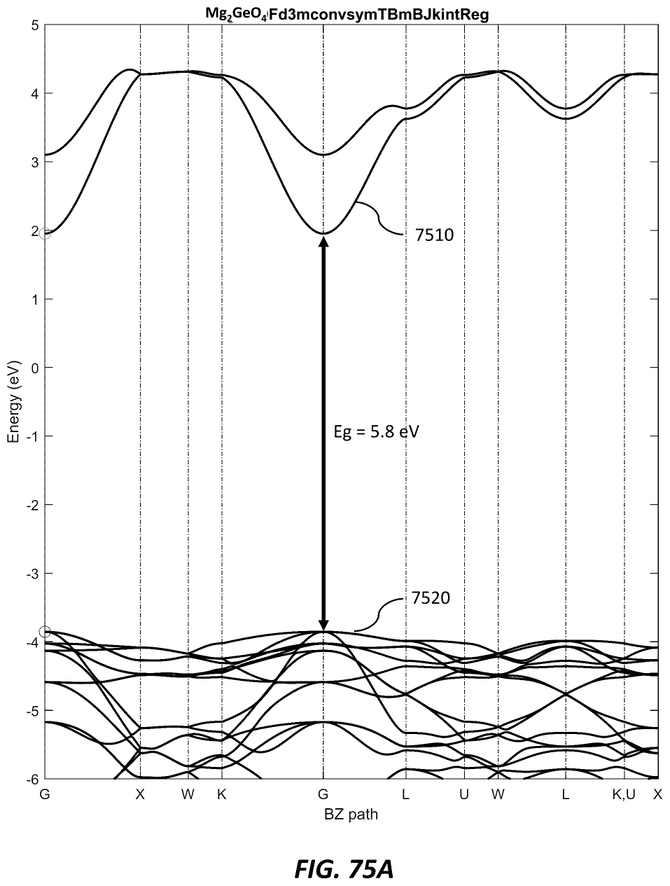

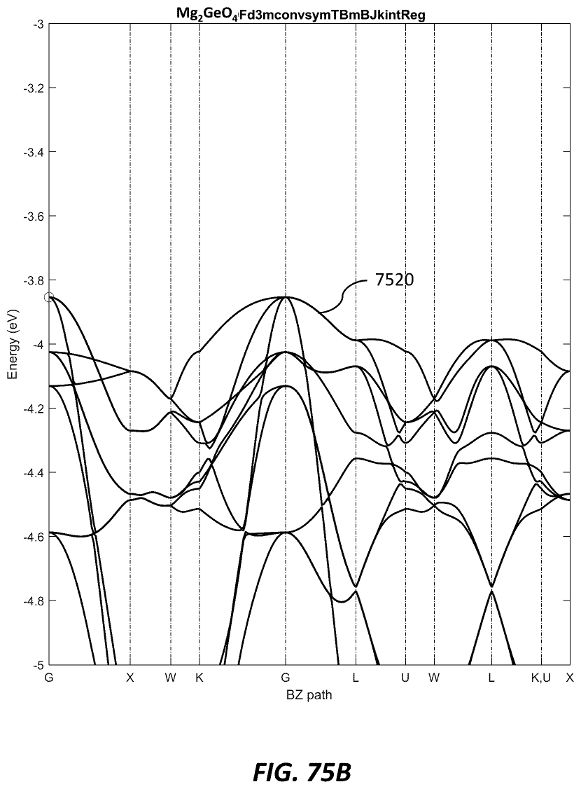

FIG. 75A is a bandgap diagram for Mg₂GeO₄ Fd3m crystal structure, showing that the material is a direct bandgap semiconductor with a bandgap energy (Eg) of approximately 5.8 eV, annotated by the distance between conduction band 7510 and valence band 7520. FIG. 75B is an enlarged view of the top valence band 7520 of FIG. 75A.

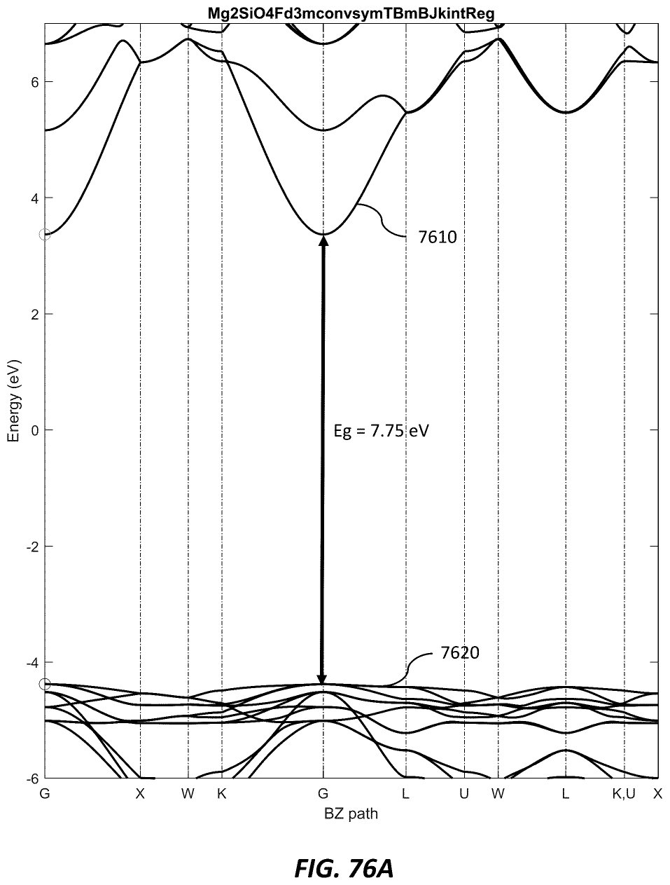

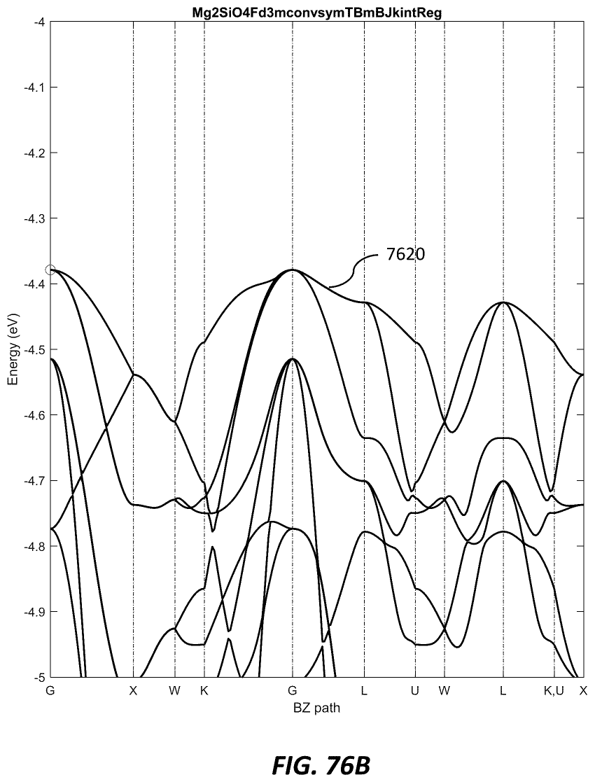

FIG. 76A is a bandgap diagram for Mg₂SiO₄ Fd3m crystal structure, showing that the material is a direct bandgap semiconductor with a bandgap energy (Eg) of approximately 7.75 eV, annotated by the distance between conduction band 7610 and valence band 7620. FIG. 76B is an enlarged view of the top valence band 7620 of FIG. 76A.

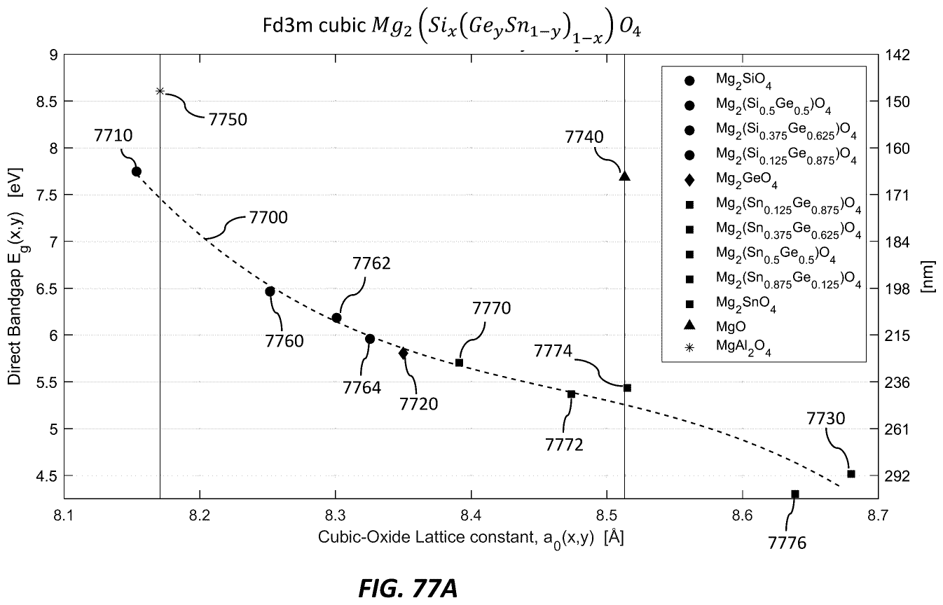

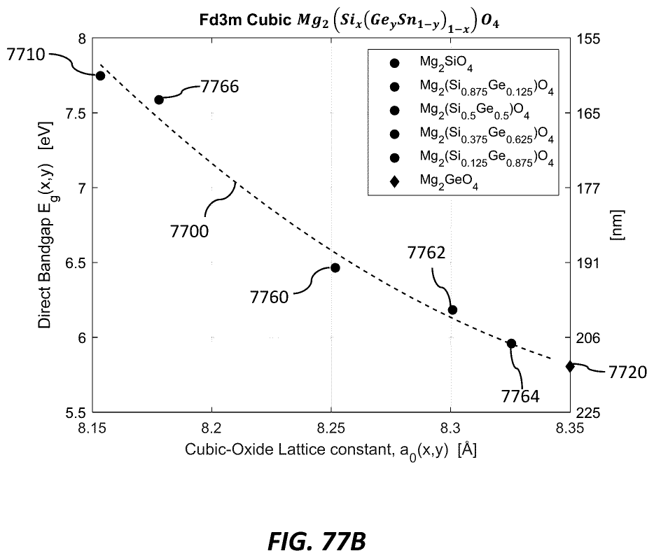

FIG. 77A is a graph showing direct bandgaps versus cubic oxide lattice constants for Mgₐ(Siₓ(Ge_{y}Sn_{1-y})₁₋ₓ)O_{b} with varying values of x and y along curve 7700. Similar to FIG. 73B, FIG. 77A shows values for Mg₂SiO₄ (point 7710), Mg₂GeO₄ (point 7720), Mg₂SnO₄ (point 7730), MgO (point 7740) and MgAl₂O₄ (point 7750). Also shown in FIG. 77A are bandgap and lattice constant values for Mg₂(Si_{0.5}Sn_{0.5})O₄ (point 7760), Mg₂(Si_{0.375}Sn_{0.625})O₄ (point 7762), Mg₂(Si_{0.125}Sn_{0.875})O₄ (point 7764), Mg₂(Sn_{0.125}Ge_{0.875})O₄ (point 7770), Mg₂(Sn_{0.375}Ge_{0.625})O₄ (point 7772), Mg₂(Sn_{0.5}Ge_{0.5})O₄ (point 7774), and Mg₂(Sn_{0.875}Ge_{0.125})O₄ (point 7776). This graph illustrates the bandgaps and lattice constants that can be engineered for cubic Fd3m forms of by Mg₂(Siₓ(Ge_{y}Sn_{1-y})₁₋ₓ)O₄ varying the amount of Si, Ge and Sn grown in the crystal structure.

FIG. 77B is a close-up view of FIG. 77A, showing direct bandgaps versus cubic oxide lattice constants for varying values of x and y for Mg—Si—Ge—O. FIG. 77B includes Mg₂SiO₄ (point 7710), Mg₂(Si_{0.875}Sn₀₁₁₂₅)O₄ (point 7766), Mg₂(Si_{0.5}Sn_{0.5})O₄ (point 7760), Mg₂(Si_{0.375}Sn_{0.625})O₄ (point 7762), Mg₂(Si_{0.125}Sn_{0.875})O₄ (point 7764), and Mg₂GeO₄ (point 7720).

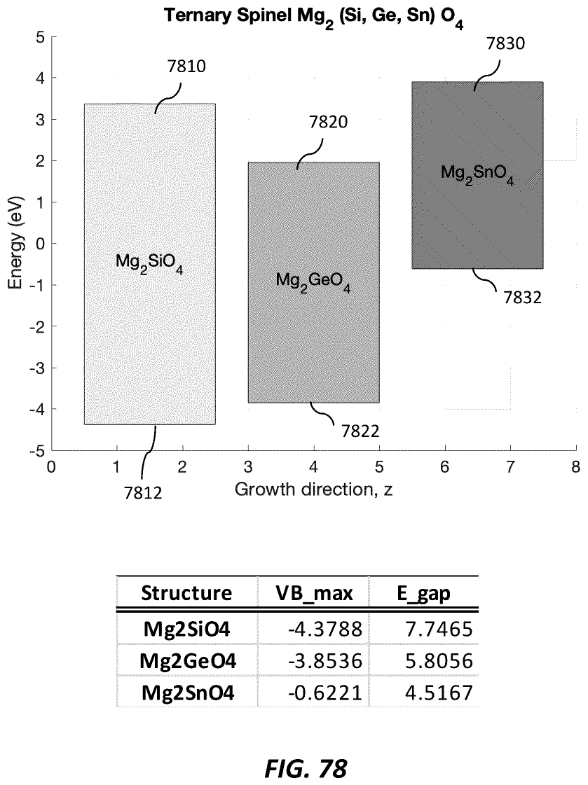

FIG. 78 is a graph of bandgap energy (units eV) as a function of growth direction “z” for ternary spinels Mg₂(Si, Ge, Sn)O₄, which beneficially are all direct bandgap materials as described above. The bandgap plot 7810 for Mg₂SiO₄ shows that Mg₂SiO₄ has a valence band maximum 7812 of −4.3788 eV (value at the bottom edge of the bandgap plot 7810) and a bandgap energy of 7.7465 eV (height of the bandgap plot 7810; see also FIG. 76A). The bandgap plot 7820 for Mg₂GeO₄ shows that Mg₂GeO₄ has a valence band maximum 7822 of −3.8536 eV (value at the bottom edge of the bandgap plot 7820) and a bandgap energy of 5.8056 eV (height of the bandgap plot 7820; see also FIG. 75A). The bandgap plot 7830 for Mg₂SnO₄ shows that Mg₂SnO₄ has a valence band maximum 7832 of −0.6221 eV (value at the bottom edge of the bandgap plot 7830) and a bandgap energy of 4.5167 eV (height of the bandgap plot 7830; see also FIG. 74A). All three of these ternary spinels are ultrawide bandgap materials, which can provide advantageous properties for semiconductor heterostructures such as in optoelectronic devices operating in the deep ultraviolet range, electronic devices for radiofrequency (RF) communication, digital computing and power switching. Graphing these bandgaps side by side in FIG. 78 illustrates how the properties of the Mg₂(Siₓ(Ge_{y}Sn_{1-y})₁₋ₓ)O₄ materials disclosed herein may be used in semiconductor devices, as shall be further described below.

In FIG. 78, the Fermi level is at approximately 0 eV in energy and is relatively close to the valence band maximum 7832 which indicates that the material Mg₂SnO₄ is suitable as a p-type material. Additionally, there is a relatively large valence band offset between the Mg₂SnO₄ material and the Mg₂SiO₄ and Mg₂GeO₄ materials. In practice, Mgₐ(Sn)O_{b} can be grown, where 1.5≤a≤2.5 and 3≤b≤5, with stoichiometries such that the material has an Mg/O ratio (i.e., a/b) greater than 0.5 (i.e., be grown Zn-rich) and the materials can have a p-type conductivity. In some cases, Mgₐ(Siₓ(Ge_{y}Sn_{1-y})₁₋ₓ)O_{b}, wherein 1.5≤a≤2.5, 3≤b≤5, 0≤x≤1, and 0≤y≤1 can be grown wherein the ratio of Sn/(Ge+Si) is greater than about 0.5, or is greater than about 0.6, or is greater than about 0.7, or is greater than about 0.8, or is greater than about 0.9, and wherein the ratio of Mg/O is greater than about 0.5 (i.e., be grown Zn-rich) and the materials can have a p-type conductivity. In some cases, Mgₐ(Siₓ(Ge_{y}Sn_{1-y})₁₋ₓ)O_{b}, wherein 1.5≤a≤2.5, 3≤b≤5, 0≤x≤1, and 0≤y≤1 can be grown wherein the group IV elements include more than about 50% Sn, or more than about 60% Sn, or more than about 70% Sn, or more than about 80% Sn, or more than about 90% Sn, and wherein the ratio of Mg/O is greater than about 0.5 (i.e., be grown Zn-rich) and the materials can have a p-type conductivity.

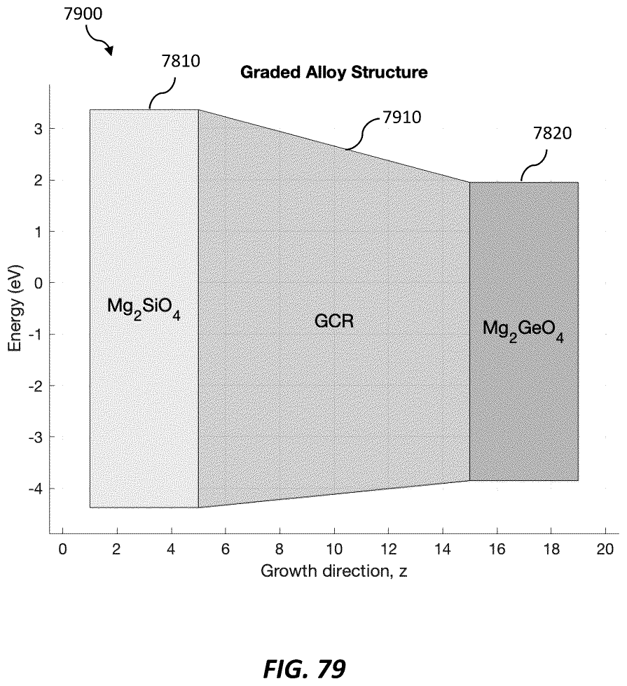

FIG. 79 is a graph of bandgap energy (units eV) as a function of growth direction “z” for an example graded alloy structure 7900 constructed using layers of Mg₂SiO₄ and Mg₂GeO₄, where the same bandgap plots 7810 and 7820 for Mg₂SiO₄ and Mg₂GeO₄, respectively, are shown. In this structure, a graded composition region 7910 (GCR) is constructed between the layers of Mg₂SiO₄ and Mg₂GeO₄. The GCR 7910 (i.e., a graded layer) has a blended composition, changing in composition from Mg₂SiO₄ to Mg₂GeO₄ in a continuous (linear) manner in this example. FIG. 79 illustrates an example heterostructure of Mg₂SiO₄ and Mg₂GeO₄ that may be used in semiconductor structures in accordance with the present disclosure, such as in FIGS. 54A-71. The Fermi level for these materials is close to the center of the bandgap (e.g., approximately at 0 eV), and therefore there is not much curvature in the conduction or valence band edges in the GRC between of Mg₂SiO₄ and Mg₂GeO₄ in this example.

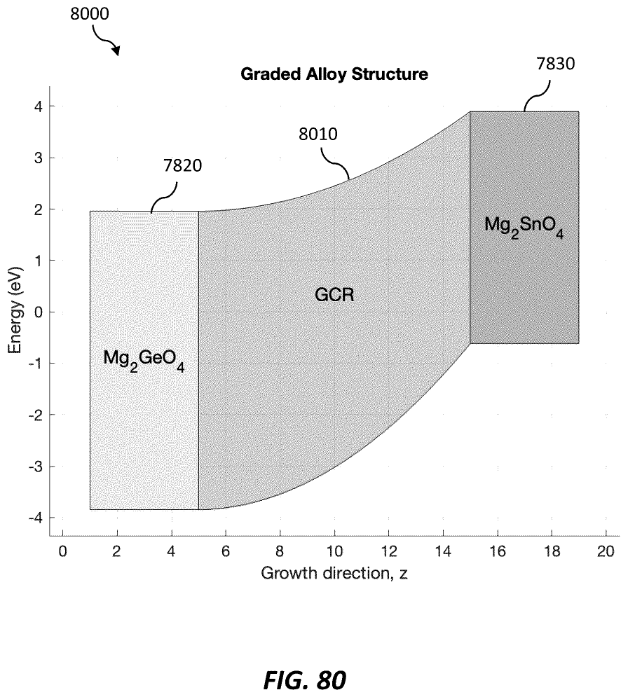

FIG. 80 is a graph of bandgap energy (units eV) as a function of growth direction “z” for an example graded alloy structure 8000 constructed using layers of Mg₂GeO₄ and Mg₂SnO₄, where the same bandgap plots 7820 and 7830 for Mg₂GeO₄ and Mg₂SnO₄, respectively, are shown. In this structure, a graded composition region 8010 is constructed between the layers of Mg₂GeO₄ and Mg₂SnO₄. The GCR 8010 (i.e., a graded layer) has a blended composition, changing in composition from Mg₂GeO₄ to Mg₂SnO₄ in the GCR in this example. The p-type properties in the Mg₂SnO₄ layer can cause an electric field to develop in the GCR in this case, which causes the curvature in the conduction and valence band edges in the GCR 8010. FIG. 80 illustrates an example heterostructure of Mg₂GeO₄ and Mg₂SnO₄ that may be used in semiconductor structures in accordance with the present disclosure, such as in FIGS. 54A-71 and 81A-81C. Another example of magnesium-group IV oxide materials that may be used as a heterostructure in semiconductor devices of the present disclosure include a layer comprising Mg₂SiO₄ and a layer comprising Mg₂SnO₄.

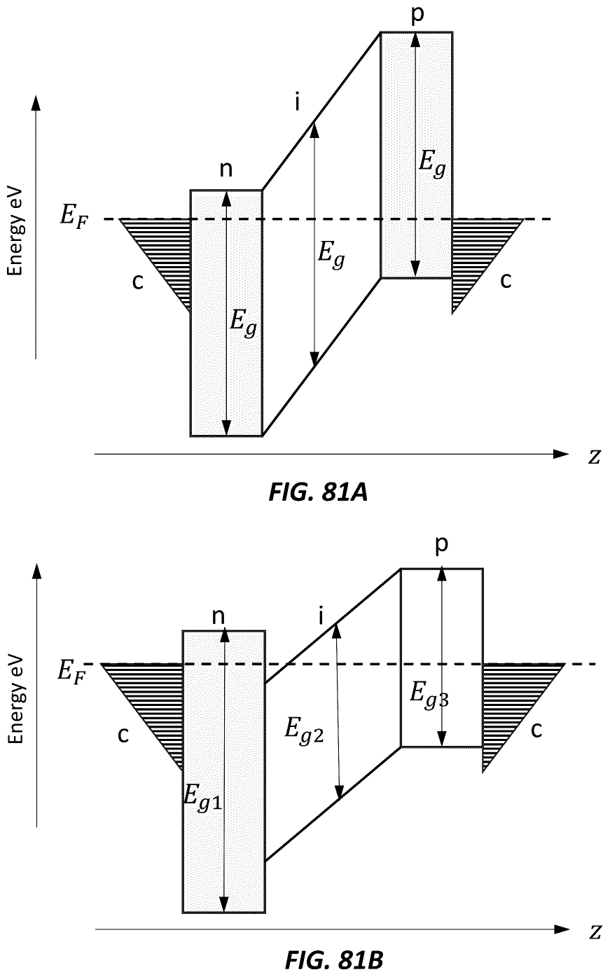

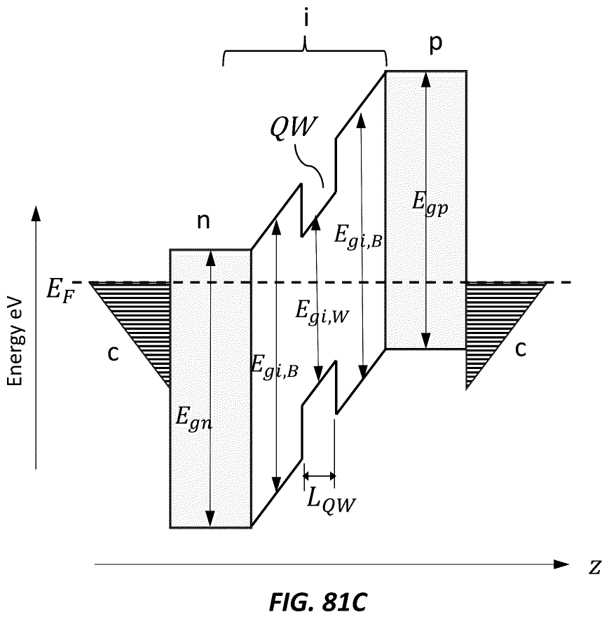

FIG. 81A is a band structure diagram of bandgap energy (eV) as a function of growth direction Z, representing a homojunction device comprising a p-i-n structure. The figure is a simplified schematic for illustrative purposes, where the actual magnitudes of the bandgaps, the Fermi level, and the layer thicknesses (z distances) will depend on the specific device and materials being constructed. The structure is formed along a growth direction Z, using spatial control of the doping regions. Moving from left to right along the growth direction, first an n-type region is formed, followed by an intrinsic “i” region, and then a p-type region. Metal contacts “c” are coupled to the p- and n-regions where other layers (not shown, e.g., transition or buffer layers) may be present between the contacts and the active p/n regions. In some cases, a substrate (not shown) can also be included, for example, between the n-type region and the metal contact. In various aspects, the doping transition between the n-, i-, and p-regions may be abrupt or graded over a distance. There are no conduction or valence band offsets in this example, since the bandgap energies E_{g} for the n-, i-, and p-regions are equal. The p-i-n structure in this example forms a diode. An electric field between the p- and n-regions is applied across the central intrinsic region along the Z-axis, forming a depletion region in the i-region. In aspects, a device having the structure of FIG. 81A may comprise Mgₐ(Siₓ(Ge_{y}Sn_{1-y})₁₋ₓ)O_{b} wherein 1.5≤a≤2.5, 3<b 5, 0≤x≤1, and 0≤y≤1, such as Mg₂GeO₄, Mg₂SiO₄ or Mg₂SnO₄, for one or more of the p-i-n layers.

In some examples, the i-region (i.e., i-layer or intrinsic layer) in FIGS. 81A-81C can be lightly n-type or lightly p-type. For instance, the doping concentration in the i-region may be less than or equal to 10¹⁵ cm⁻³. In some examples, the i-region may be a “not-intentionally doped” layer. In some examples, the i-region may be “intentionally doped” at a low doping level, e.g., less than 10¹⁵ cm⁻³.

FIG. 81B is a band structure diagram representing a heterojunction device, such as a diode, with a p-i-n structure. The figure is a simplified schematic for illustrative purposes, where the actual magnitudes of the bandgaps, the Fermi level, the conduction and valence band offsets, and the layer thicknesses (z distances) will depend on the specific device and materials being constructed. The structure is sequentially formed along the growth direction Z, using spatial control of the composition and doping of the distinct regions. In various aspects, the composition and doping can be abrupt or graded across a predetermined distance. The bandgap energies E_{g} of the p- and n-regions are not the same in this example, and the bandgap E_{g1} of the n-region is larger (wider bandgap) than that of the p-region (narrow bandgap E_{g3}). For example, the n-region may comprise Mg₂GeO₄ or Mg₂SiO₄, and the p-region may comprise Mg₂GeO₄ or Mg₂SnO₄, respectively. In aspects, a device having the structure of FIG. 81B may comprise Mgₐ(Siₓ(Ge_{y}Sn_{1-y})₁₋ₓ)O_{b} wherein 1.5≤a≤2.5, 3≤b≤5, 0≤x≤1, and 0≤y≤1, such as Mg₂GeO₄, Mg₂SiO₄ or Mg₂SnO₄ for one or more of the layers.

FIG. 81C is a band structure diagram representing a double heterojunction device, such as a diode, with a p-i-n structure and a single quantum well QW. The figure is a simplified schematic for illustrative purposes, where the actual magnitudes of the bandgaps, the Fermi level, and the layer thicknesses (z distances) will depend on the specific device and materials being constructed. In this example, the bandgaps of the n- and p-regions (E_{gn}, E_{gp} respectively) are the same as their adjacent barriers (bandgap E_{gi,B}). When placed in forward bias, electrons and holes are injected into the intrinsic region from their respective reservoir regions. The quantum well, with bandgap E_{gi,W}, is designed such that the thickness L_{QW} can tune the quantized energy levels in the conduction and valence bands confined between the barriers, with bandgaps E_{gi,B}. In other aspects, the structure can have more than one, or multiple quantum wells in the intrinsic region. The energy levels in the multiple quantum well structure influence various properties of the structure, such as the minimum effective bandgap. In some cases, such as in light emitting devices, having more than one quantum well improves optical emission, such as due to increased quantum well capture rates of carriers injected into the i-region from the p- and n-regions. In aspects, a device having the structure of FIG. 81C may comprise Mgₐ(Siₓ(Ge_{y}Sn_{1-y})₁₋ₓ)O_{b} wherein 1.5≤a≤2.5, 3≤b≤5, 0≤x≤1, and 0≤y≤1, such as Mg₂GeO₄, Mg₂SiO₄ or Mg₂SnO₄ for one or more of the layers.

In some examples, semiconductor structures of the present disclosure, such as represented by FIGS. 54A-71 and 81A-81C, may include superlattices with sub-layers of Mgₐ(Siₓ(Ge_{y}Sn_{1-y})₁₋ₓ)O_{b} wherein 1.5≤a≤2.5, 3≤b≤5, 0≤x≤1, and 0≤y≤1, such as Mg₂SiO₄, Mg₂GeO₄ and/or Mg₂SnO₄. For example, the n-, i-, and/or p-regions in the structures in FIGS. 81A-81C can contain one or more superlattices.

In other examples, magnesium-group IV oxide materials may be used in a heterostructure in semiconductor devices and include two layers made of different magnesium-group IV oxide materials. The heterostructures can be in any region of the devices or spanning across two regions of the devices. For example, the heterostructures can be in one or more of an active region, a transition layer (e.g., a buffer layer), an intermediate layer, a drift layer, and a channel region. The heterostructures can contain layers of different materials in contact with one another, such as a layer with a first composition Mgₐ₁(Siₓ₁(Ge_{y1}Sn_{1-y1})₁₋ₓ₁)O_{b1} where 1.5≤a1≤2.5, 3≤b1≤5, 0≤x1≤1, and 0≤y1≤1, in contact with a layer having a second composition Mgₐ₂(Siₓ₂(Ge_{y2}Sn_{1-y2})₁₋ₓ₂)O_{b2} where 1.5≤a2≤2.5, 3≤b2≤5, 0≤x2≤1, and 0≤y2≤1, where at least one condition selected from a1≠a2, b1≠b2, x1≠x2, and y1≠y2 is satisfied. In some examples of a heterostructure in semiconductor devices, the first and/or the second composition may be a ternary magnesium-group IV oxide material Mgₐ(Siₓ(Ge_{y}Sn_{1-y})₁₋ₓ)O_{b} where i) x=1, or ii) y=0 and x=0, or iii) y=1 and x=0. In some examples of a heterostructure in semiconductor devices, the first and/or the second composition may be a quaternary magnesium-group IV oxide materials Mgₐ(Siₓ(Ge_{y}Sn_{1-y})₁₋ₓ)O_{b} where i) x=0 and 0<y<1, or ii) 0<x<1 and y=0 or 1. In some examples of a heterostructure in semiconductor devices, the first and/or the second composition may be a quinary magnesium-group IV oxide materials Mgₐ(Siₓ(Ge_{y}Sn_{1-y})O_{b}, where 0<x<1 and 0<y<1. In some examples, the ternary, quaternary, and/or quinary magnesium-group IV oxide materials may be combined with each other as various layers in a semiconductor structure. Other examples of semiconductor structures include magnesium-group IV oxide materials Mgₐ(Siₓ(Ge_{y}Sn_{1-y})₁₋ₓ)O_{b} combined with a binary, ternary, quaternary, or quinary oxide material that may or may not include a group IV element. For example, one of the materials in the heterostructure may be any of the Materials 1-7 described herein.

In some examples, the single crystal Mgₐ(Siₓ(Ge_{y}Sn_{1-y})₁₋ₓ)O_{b} and epitaxial layers that include the material have an electronic bandgap between 3 eV and 8 eV. In some examples, the single crystal Mgₐ(Siₓ(Ge_{y}Sn_{1-y})₁₋ₓ)O_{b} has a direct electronic bandgap. In some examples, the single crystal Mgₐ(Siₓ(Ge_{y}Sn_{1-y})₁₋ₓ)O_{b} has a cubic crystal space group symmetry. In some examples, the single crystal Mgₐ(Siₓ(Ge_{y}Sn_{1-y})₁₋ₓ)O_{b} is a ternary oxide material, wherein i) x=1, or ii) y=0 and x=0, or iii) y=1 and x=0. In some examples, the single crystal Mgₐ(Siₓ(Ge_{y}Sn_{1-y})₁₋ₓ)O_{b} is a quaternary oxide material, wherein i) x=0 and 0<y<1, or ii) 0<x<1 and y=0 or 1. In some examples, the single crystal Mgₐ(Siₓ(Ge_{y}Sn_{1-y})₁₋ₓ)O_{b} is a quinary oxide material, wherein 0<x<1 and 0<y<1.

### Doping

Aspects of the present disclosure provide for the doping of MgₓGe_{y}O_{z} and Mgₐ(Siₓ(Ge_{y}Sn_{1-y})₁₋ₓ)O_{b}, which enables the materials to be used as epitaxial layers in various types of electronic and optoelectronic devices, such as n-type or p-type layers. In various aspects, the MgₓGe_{y}O_{z} or Mg, (Siₓ(Ge_{y}Sn_{1-y})₁₋ₓ)O_{b} may be a direct bandgap material or an indirect bandgap material. In some aspects, the direct bandgap material Mg₂GeO₄ (Fd3m) is doped. In the crystal structure of Mg₂GeO₄ (Fd3m), Ge-sites have tetrahedral (T_{d}) bonding to oxygen and the Mg-sites have octahedral (Oₕ) bonding to oxygen. The following are some of the aspects in this disclosure:
Ga doping can potentially substitute for Ge_{Td} site with calculations showing that Ge_{Td} sites (e.g., all single Ge_{Td} sites) substituted with Ga_{Td} site result in a direct bandgap p-type material.
Ga doping can potentially substitute for Mg_{Oh} site with calculations showing that Mg_{Oh} sites (e.g., all single Mg_{Oh} sites) substituted with Ga_{Oh} site result in a direct bandgap n-type material.
Al doping can potentially substitute for Mg_{Oh} site with calculations showing that this results in a direct bandgap n-type material.
Al doping can potentially substitute for Ge_{Td} site with calculations showing that this results in a direct bandgap p-type material.
Li doping can potentially substitute for Ge_{Td} or Mg_{Oh} sites with calculations showing a direct bandgap p-type material.
Ni doping can potentially substitute for Mg_{Oh} sites with calculations showing the formation of defect bands and a reduced bandgap.
N doping can potentially substitute for 0 sites with calculations showing a direct bandgap p-type material.
Anti-site substitution can be implemented within a unit cell, with calculations showing a p-type material. Anti-site substitution may involve Mg and Ge atoms being switched out for each other, which results in Ge_{Td} atoms being placed at an octahedral bonding site (Ge_{Td}→Ge_{Oh}) and Mg_{Oh} atoms being placed at a tetrahedral bonding site (Mg_{Oh}→Mg_{Td}).
Doping can be achieved with either excess Mg or excess Ge.

Although aspects shall be described using Mg₂GeO₄ as an example, the aspects may apply to other forms of MgₓGe₁₋ₓO₂₋ₓ. Methods of doping an epitaxial layer of MgₓGe₁₋ₓO₂₋ₓ include co-depositing materials onto the substrate to form the epitaxial layer of MgₓGe₁₋ₓO₂₋ₓ, with x having a value of 0≤x<1. The materials comprise at least two elements selected from Mg, Ge and oxygen in accordance with the value of x; the Mg, Ge and oxygen being supplied by a Mg source, a Ge source, and an activated oxygen source, respectively. Methods may include depositing a buffer layer between the substrate and the epitaxial layer of MgₓGe₁₋ₓO₂₋ₓ. The co-depositing may be performed using a molecular beam epitaxy process.

Referring now to FIGS. 18A and 18B, tables are shown of the normalized x, y and z positions in Cartesian coordinates of cation (i.e., Mg and Ge) sites (FIG. 18A) and anion (i.e., O) sites (FIG. 18B) for the Mg₂GeO₄ (Fd3m) unit cell as will be referred to throughout the present disclosure. In this example, the cation unit cell comprises 16 distinct Mg sites (Mg₁, i=0-15) and 8 distinct Ge sites (Geⱼ, j=16-23). The anion unit cell comprises 32 distinct sites (Ok, k=24-55). FIGS. 18A-18B thus disclose the crystal structure of Mg₂GeO₄ (Fd3m), in accordance with aspects of the present disclosure.

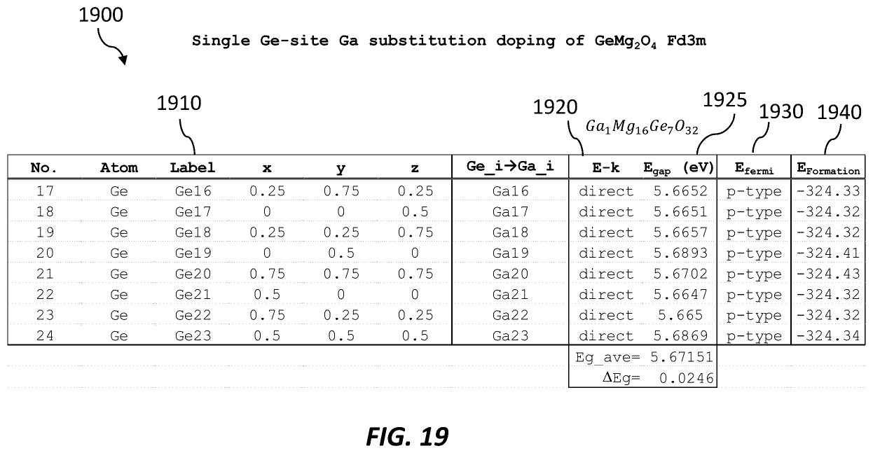

In some aspects, Ge_{Td} sites can be substituted with Ga atoms (resulting in Ga_{Td} sites) to create a direct bandgap p-type material, as shall be described in FIGS. 19-21B. FIG. 19 is a table 1900 summarizing the semiconductor properties of single site trivalent gallium impurity atom substitution in Mg₂GeO₄ (Fd3m) arising from various single site substitutions of Ge sites with Ga. Shown in table 1900 is the particular Ge site 1910 that is being substituted, corresponding to the Geᵢ cation site of FIG. 18A. For example, in the first row of table 1900, Ge site “Ge16” is substituted with a Ga atom, becoming a Ga site “Ga16.” Also shown in table 1900 are the normalized x, y and z coordinates and calculated semiconductor properties such as the bandgap classification 1920 and bandgap energy value 1925, the type of semiconductor 1930 (E_{fermi}) and the formation energy 1940 (E_{Formation}). As can be seen, for the various Ge sites indicated, the resulting doped Mg₂GeO₄ (Fd3m) is a direct bandgap p-type material. Aspects include semiconductor structures and devices in which an epitaxial layer of MgₓGe₁₋ₓO₂₋ₓ is a direct bandgap p-type material and comprises a Ga dopant (e.g., Ga atoms). The Ga dopant is located in a Ge site of a corresponding undoped (i.e., the corresponding undoped structure is the nominal MgₓGe₁₋ₓO₂₋ₓ structure that is not doped) MgₓGe₁₋ₓO₂₋ₓ crystal structure. Methods of doping an epitaxial layer of MgₓGe₁₋ₓO₂₋ₓ include substituting a Ge site of a corresponding undoped MgₓGe₁₋ₓO₂₋ₓ crystal structure with Ga to result in a p-type conductivity.

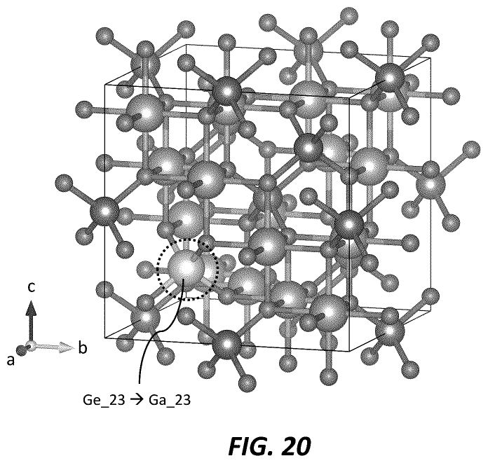

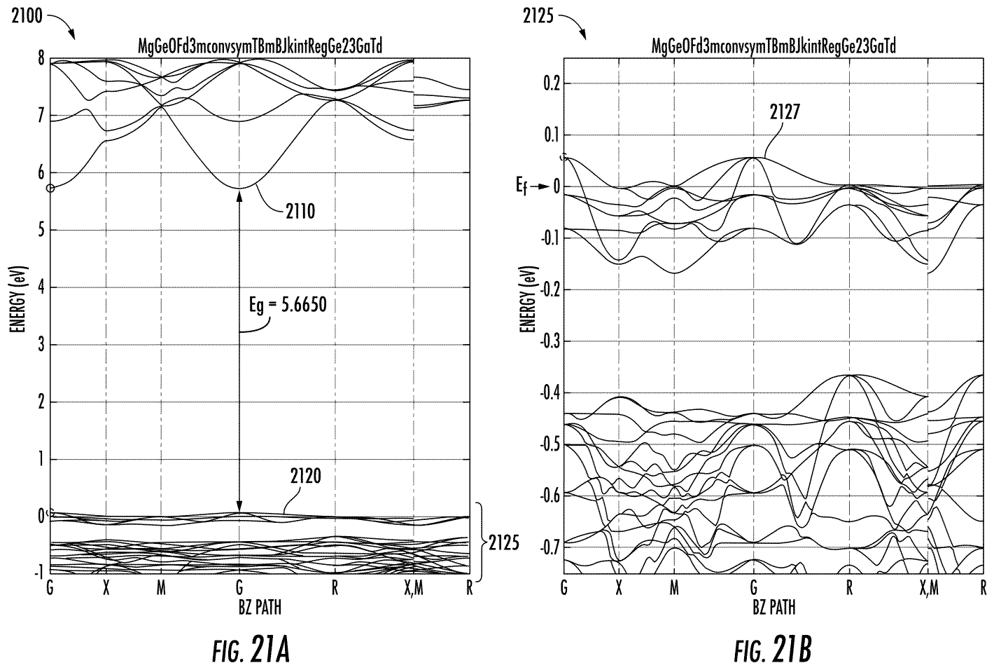

FIG. 20 shows a crystal structure diagram of a doped Mg₂GeO₄ (Fd3m) showing in this example the Ge₂₃ site substituted with Ga. FIGS. 21A and 21B show E-k diagrams for Mg₂GeO₄(Fd3m) arising from the Ge site substitution with Ga illustrated in FIG. 20. The diagram 2100 of FIG. 21A shows the valence band 2120 and conduction band 2110 structure, and diagram 2125 of FIG. 21B shows an enlarged view of the valence band structure. As can be seen, the doped Mg₂GeO₄(Fd3m) is a direct bandgap semiconductor material where the maximum of the valence band 2120 and the minimum of the conduction band 2110 occur at the zone center at k=0. As best seen in FIG. 21B, the maximum 2127 of the valence band is above the Fermi energy (E_{f}) indicating that the doped Mg₂GeO₄ (Fd3m) in this example is a p-type material. In summary, the degenerate Fermi energy E_{f} is located within the valence band and the direct bandgap energy is reduced by ˜140 meV, being Eg=5.6650 eV for this Ge-site substituted form compared to an E_{g} of 5.8056 eV for the undoped case in FIG. 8A. The doped Mg₂GeO₄ (Fd3m) still has an ultrawide bandgap, being greater than 4 eV.

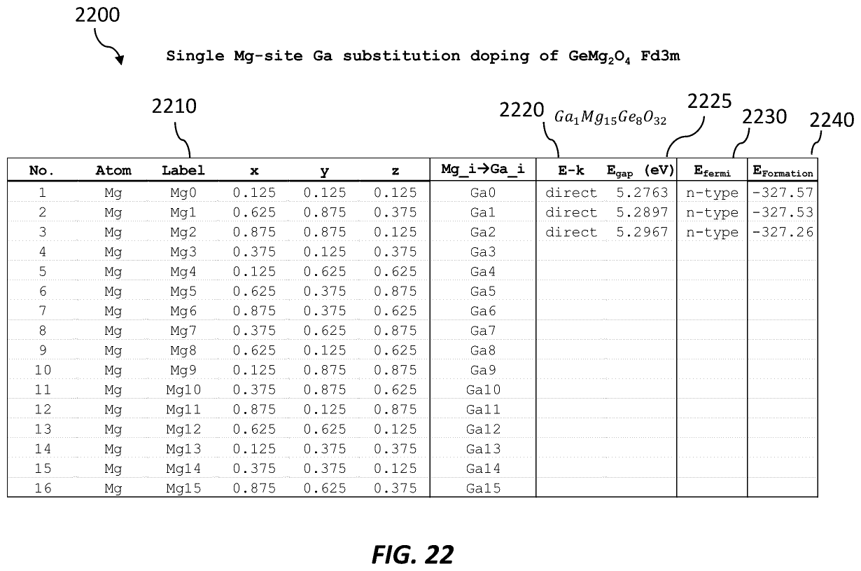

In some aspects, Mg_{Oh} sites can be substituted with Ga (resulting in Ga_{Oh} sites) to create a direct bandgap n-type material, as shall be described in FIGS. 22-24. In FIG. 22, table 2200 discloses calculated semiconductor properties of Ga-doped Mg₂GeO₄ (Fd3m) arising from various single site substitutions of distinct Mg sites with Ga. Shown in table 2200 are the Mg sites 2210 that are being substituted and their normalized x, y and z coordinates. Example semiconductor properties such as the bandgap classification 2220 and bandgap energy 2225, type of semiconductor 2230 and the formation energy 2240 are shown for selected substitution cases. The semiconductor properties shown have values that are very similar to each other; the other substitution aspects shown in table 2200 are expected to exhibit similar results. As can be seen, for the various Mg sites indicated, the resulting doped Mg₂GeO₄ (Fd3m) is a direct bandgap n-type material. That is, the single site substitution of a trivalent cation at a divalent Mg site results in n-type conductivity. Aspects include semiconductor structures and devices in which an epitaxial layer of MgₓGe₁₋ₓO₂₋ₓ is a direct bandgap n-type material and comprises a Ga dopant (e.g., Ga atoms). The Ga dopant is located in a Mg site of a corresponding undoped (i.e., compared to a nominal) MgₓGe₁₋ₓO₂₋ₓ crystal structure. Methods of doping an epitaxial layer of MgₓGe₁₋ₓO₂₋ₓ include substituting a Mg site of a corresponding undoped MgₓGe₁₋ₓO₂₋ₓ crystal structure with Ga to result in an n-type conductivity.

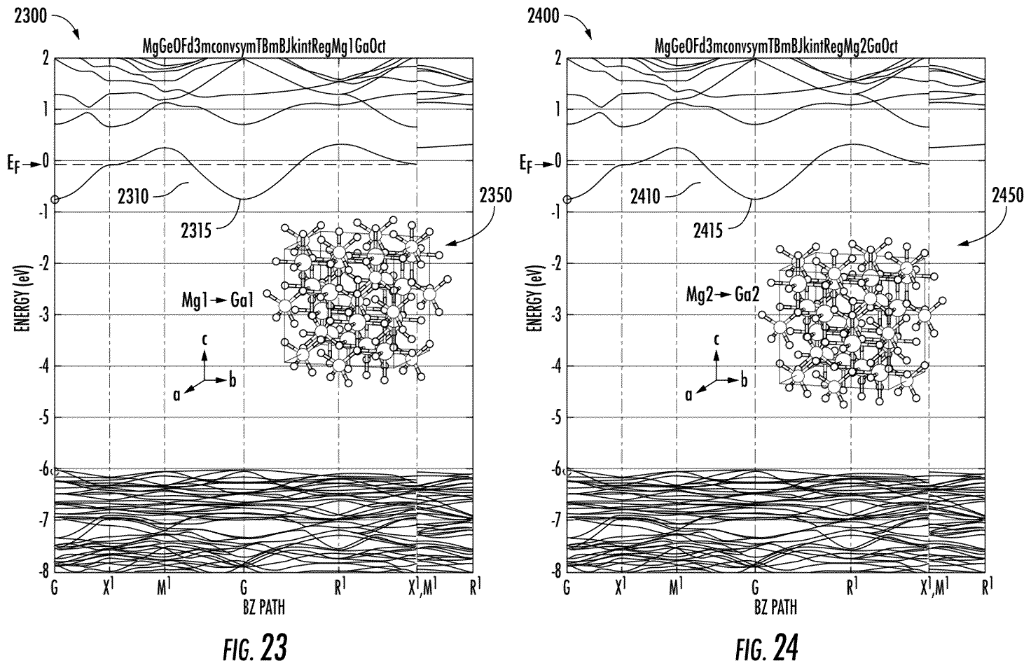

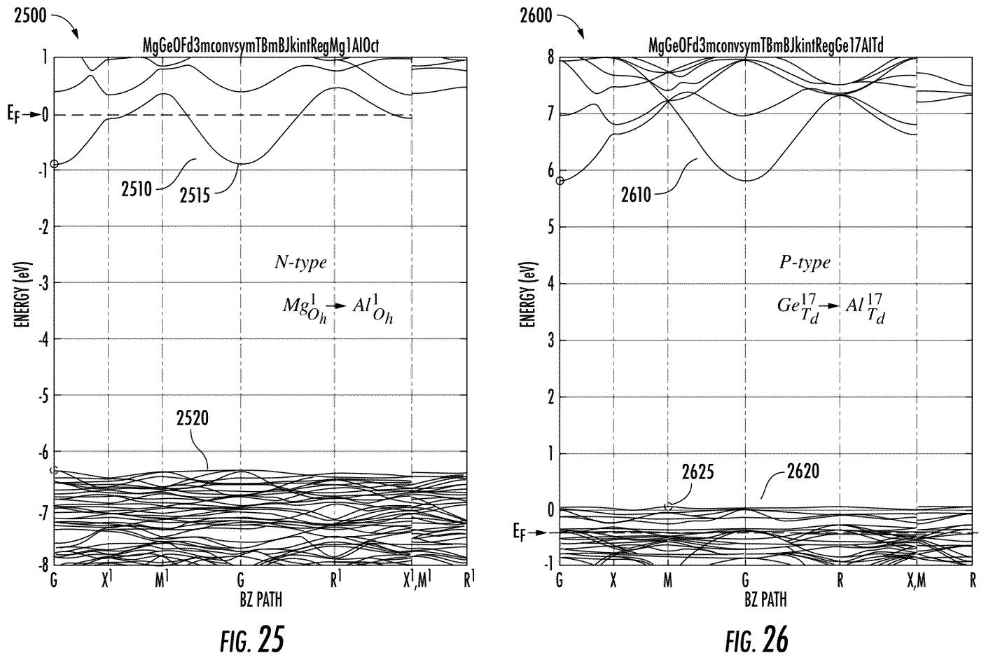

FIG. 23 shows a crystal structure diagram 2350 of a doped Mg₂GeO₄ (Fd3m) in which for this example the Mg₁ site is substituted with Ga. Also shown in FIG. 23 is the associated E-k diagram 2300 for the n-type doped semiconducting material. As can be seen, the resulting doped Mg₂GeO₄ (Fd3m) is a direct bandgap semiconductor material. The minimum 2315 of the conduction band 2310 is below the Fermi energy (E_{f}) indicating that the doped Mg₂GeO₄ (Fd3m) in this example is a n-type material.

FIG. 24 is similar to FIG. 23, but for the Mg₂ site substituted with Ga. FIG. 24 includes a crystal structure diagram 2450 of a doped Mg₂GeO₄ (Fd3m) and the associated E-k diagram 2400 for the n-type doped semiconducting material. As can be seen, the resulting doped Mg₂GeO₄ (Fd3m) is a direct bandgap semiconductor material, and the minimum 2415 of the conduction band 2410 is below the Fermi energy (E_{f}) indicating that the doped Mg₂GeO₄ (Fd3m) in this example is a n-type material.

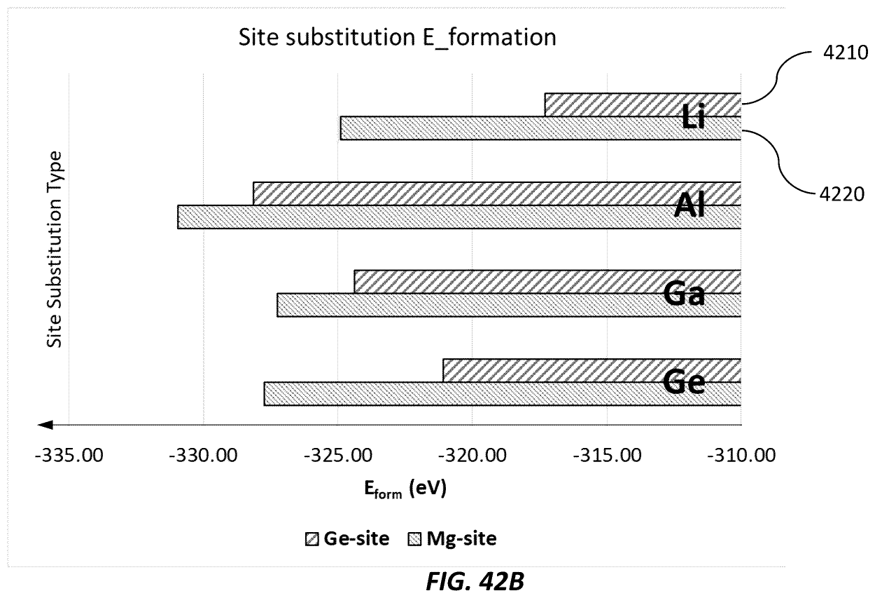

In some aspects, Al may be substituted at Mg_{Oh} sites to create a direct bandgap n-type material by, in one example, co-deposition using an additional elemental aluminum source (e.g., see FIG. 42B). FIG. 25 is an E-k diagram 2500 showing the valence band 2520 and conduction band 2510 structure for a doped Mg₂GeO₄(Fd3m) arising from the octahedral Mg₁ site being substituted with Al. As can be seen, the resulting doped Mg₂GeO₄ (Fd3m) is a direct bandgap semiconductor material. The minimum 2515 of the conduction band 2510 is below the Fermi energy (E_{f}), indicating that the doped Mg₂GeO₄ (Fd3m) in this example is a n-type material. That is, the Fermi energy is positioned within the conduction band 2150 and is expected to exhibit n-type conductivity. Aspects include semiconductor structures and devices in which an epitaxial layer of MgₓGe₁₋ₓO₂₋ₓ is a direct bandgap n-type material and comprises an Al dopant (e.g., Al atoms). The Al dopant is located in a Mg site of a corresponding undoped MgₓGe₁₋ₓO₂₋ₓ crystal structure. Methods of doping an epitaxial layer of MgₓGe₁₋ₓO₂₋ₓ include substituting a Mg site of a corresponding undoped MgₓGe₁₋ₓO₂₋ₓ crystal structure with Al to result in an n-type conductivity.

In some aspects, Al may be substituted at Ge_{Td} sites to create a direct bandgap p-type material. FIG. 26 is an E-k diagram 2600 showing the valence band 2620 and conduction band 2610 structure for a doped Mg₂GeO₄ (Fd3m) arising from the tetrahedral Ge₁₇ site being substituted with Al. As can be seen, the resulting doped Mg₂GeO₄(Fd3m) is a direct bandgap semiconductor material. The maximum 2625 of the valence band 2620 is above the Fermi energy (E_{f}), indicating that the doped Mg₂GeO₄ (Fd3m) in this example is a p-type material. That is, the Fermi energy is positioned within the valence band 2620 and is expected to exhibit p-type conductivity. Aspects include semiconductor structures and devices in which an epitaxial layer of MgₓGe₁₋ₓO₂₋ₓ is a direct bandgap p-type material and comprises an Al dopant (e.g., Al atoms). The Al dopant is located in a Ge site of a corresponding undoped MgₓGe₁₋ₓO₂₋ₓ crystal structure. Methods of doping an epitaxial layer of MgₓGe₁₋ₓO₂₋ₓ include substituting a Ge site of a corresponding undoped MgₓGe₁₋ₓO₂₋ₓ crystal structure with Al to result in a p-type conductivity.

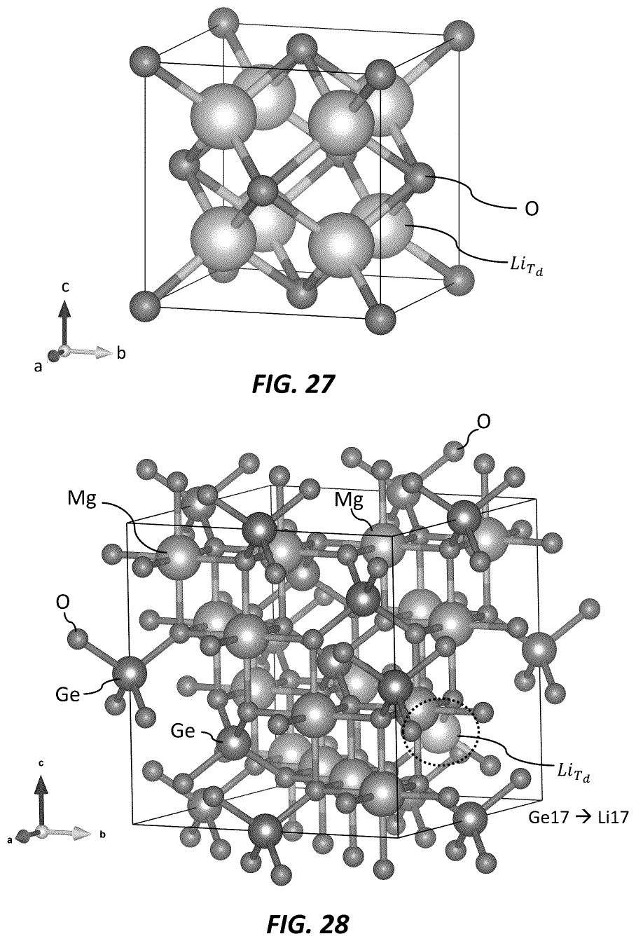

In some aspects, Ge_{Td} or Mg_{Oh} sites can be substituted with Li doping to create a direct bandgap p-type material, as shall be described by FIGS. 27-30. FIG. 27 shows a unit cell crystal structure diagram of cubic lithium-oxide Li₂O (Fm3m) showing the monovalent Li⁺ atoms tetrahedrally bonded to oxygen. Li₂O is a stable oxide where the Li atoms are tetrahedrally bonded (T_{d}) to oxygen atoms.

FIG. 28 shows a unit cell crystal structure diagram of doped Mg₂GeO₄ (Fd3m), showing in this example the tetrahedral Ge₁₇ site substituted with Li⁺ as an impurity atom. Both oxides of Li⁺ and Ge⁴⁺ energetically prefer tetrahedral bonding with oxygen and therefore it is expected that Li⁺ preferentially substitutes for Ge-sites compared to octahedral sites.

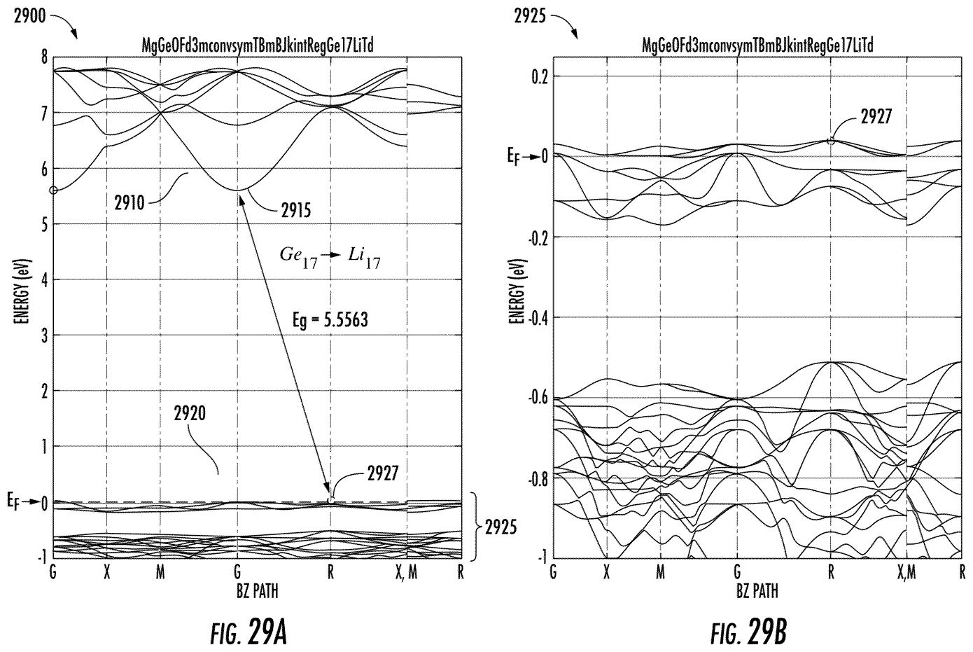

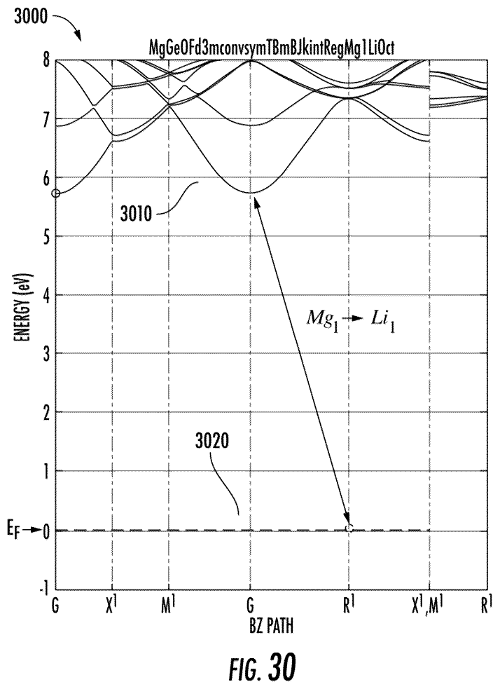

FIG. 29A is an E-k diagram 2900 for the Li-doped Mg₂GeO₄(Fd3m) arising from the Li substitution at a Ge site illustrated in FIG. 28. Valence band 2920 and conduction band 2910 structure are shown. FIG. 29B is an enlarged view 2925 of the valence band structure 2920 of FIG. 29A. As can be seen, the doped Mg₂GeO₄(Fd3m) is an indirect bandgap semiconductor with a bandgap energy of 5.5563 eV between the conduction band minimum 2915 and the valence band maximum 2927. As best seen in FIG. 29B, the doped Mg₂GeO₄ (Fd3m) in this example is a degenerate p-type material. That is, the Fermi energy (E_{f}) is positioned within the valence band 2920 (view 2925) and therefore creates p-type conductivity, and the valence band maximum 2927 is no longer at the Brillouin-zone center.

FIG. 30 is an E-k diagram 3000 corresponding to doped Mg₂GeO₄ (Fd3m) where the Mg₁ site is substituted with Li. Conduction band 3010 and valence band 3020 structures are shown. FIG. 30 shows that the Li-doping at the Mg₁ site results in an indirect bandgap semiconductor. In viewing FIG. 29A and FIG. 30, both show that the effect of substituting a Ge₁₇ atom or Mg₁ atom with Li creates p-type materials, with the Ge substitution resulting in a degenerate p-type material. Aspects include semiconductor structures and devices in which an epitaxial layer of MgₓGe₁₋ₓO₂₋ₓ is a direct bandgap p-type material and comprises a Li⁺ dopant (e.g., Li⁺ atoms). The Li⁺ dopant is located in a Ge site or a Mg site of a corresponding undoped MgₓGe₁₋ₓO₂₋ₓ crystal structure. Methods of doping an epitaxial layer of MgₓGe₁₋ₓO₂₋ₓ include substituting a Ge site or a Mg site of a corresponding undoped MgₓGe₁₋ₓO₂₋ₓ crystal structure with Li⁺ to result in an p-type conductivity.

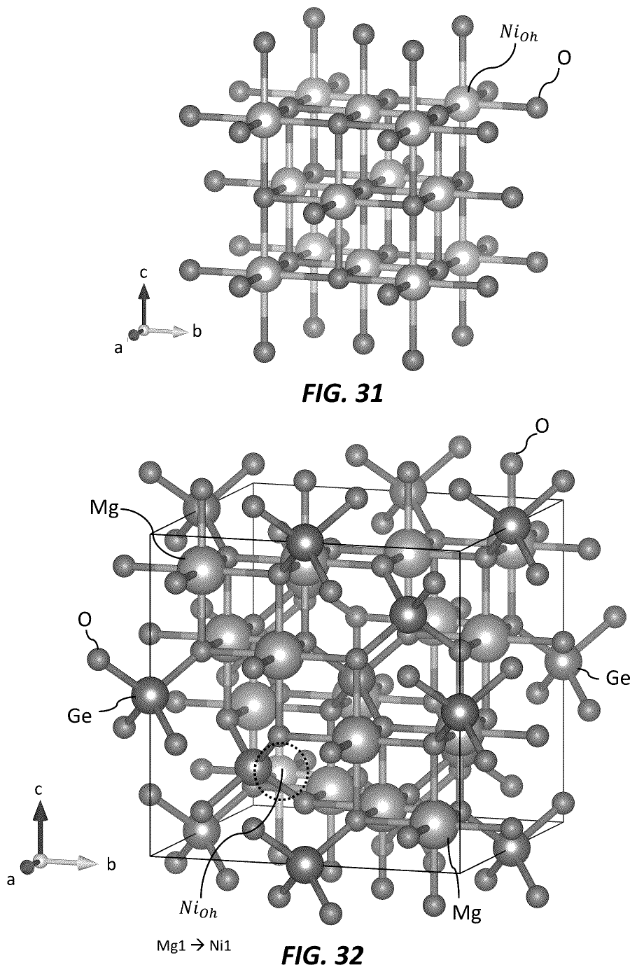

In some aspects, Mg_{Oh} sites can be substituted with Ni atoms to create defect bands and a reduced bandgap compared to an undoped form, as shall be described by FIGS. 31-33B. FIG. 31 shows a crystal structure diagram of a cubic NiO (space group Fd3m) unit cell. NiO is a stable oxide where the Ni atoms are octahedrally bonded (Ni_{Oh}) to oxygen atoms. Ni_{Oh} atoms are chosen to substitute for Mg.

FIG. 32 shows a unit cell crystal structure diagram of Ni-doped Mg₂GeO₄ (Fd3m), showing in this example the octahedral Mg₁ site substituted with Ni⁺ as an impurity atom.

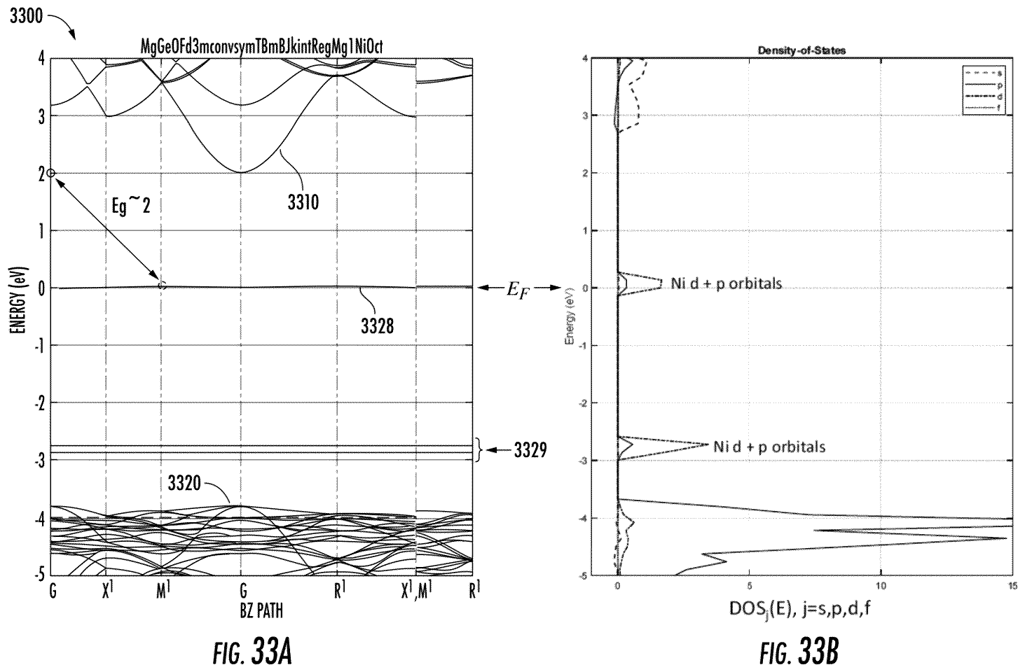

FIG. 33A is an E-k diagram 3300 for the Ni-doped Mg₂GeO₄ (Fd3m) illustrated in FIG. 32, showing structures for valence band 3320 and conduction band 3310. As can be seen, the resulting doped material has an indirect bandgap with a bandgap energy E_{g} that is reduced to approximately 2 eV. Furthermore, there are a number of defect bands 3328 and 3329 in addition to the normal valence band 3320, and also parasitic absorption within the gap between defect bands. The Ni atom substitution at a Mg site results in deep levels created within the bandgap due to the Ni p- and d-orbitals. These calculated results demonstrate that Ni does not appreciably alter the conductivity type of Mg₂GeO₄ but does introduce parasitic optical absorption within the bandgap.

FIG. 33B is a density of states (DOS) diagram for the Ni-doped Mg₂GeO₄ (Fd3m) illustrated in FIG. 32. The DOS indicates the disadvantageous sub-bandgap energy states due to Ni p- and d-orbitals. Aspects include semiconductor structures and devices in which an epitaxial layer of MgₓGe₁₋ₓO₂₋ₓ comprises a Ni⁺ dopant (e.g., Ni⁺ atoms). The Ni⁺ dopant is located in a Mg site of a corresponding undoped MgₓGe₁₋ₓO₂₋ₓ crystal structure. Methods of doping an epitaxial layer of MgₓGe₁₋ₓO₂₋ₓ include substituting a Mg site of a corresponding undoped MgₓGe₁₋ₓO₂₋ₓ crystal structure with Ni⁺.

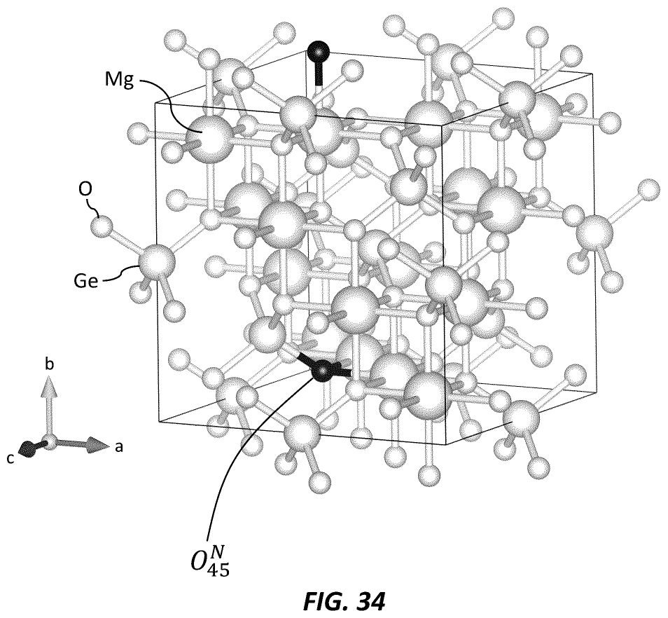

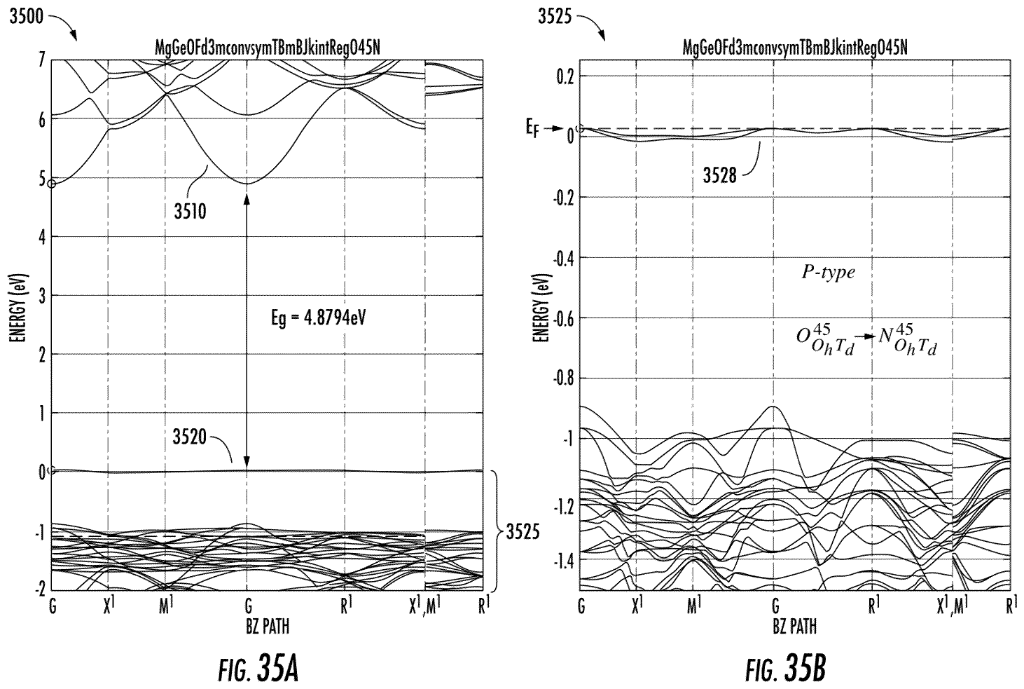

In some aspects, O sites can be substituted with N atoms (nitrogenic doping, N³⁺) to create a direct bandgap p-type material, as shall be described in FIGS. 34-35B. FIG. 34 shows a unit cell crystal structure diagram of an N atom substituted at an oxygen site within Mg₂GeO₄ (Fd3m). In this example, the anion O₄₅ site is substituted with a trivalent nitrogen as an impurity atom, labelled as O₄₅^{N}.

FIG. 35A is an E-k diagram 3500 for the N-doped Mg₂GeO₄ (Fd3m) arising from the N site substitution illustrated in FIG. 34. The valence band 3520 and conduction band 3510 structure are shown. FIG. 35B is an enlarged view 3525 of the valence band structure in FIG. 35A. As can be seen from FIG. 35A, the N-doped Mg₂GeO₄ (Fd3m) is a direct bandgap semiconductor with a bandgap energy reduced to approximately 4.88 eV compared to the undoped E_{g} of 5.8056 eV in FIG. 8A. As best seen in FIG. 35B, for the N-doped Mg₂GeO₄(Fd3m) the induced relatively shallow energy band 3528 close to the Fermi energy (E_{f}) due to the nitrogenic impurity results in a p-type material. Aspects include semiconductor structures and devices in which an epitaxial layer of MgₓGe₁₋ₓO₂₋ₓ is a direct bandgap p-type material and comprises a N³⁺ dopant (e.g., N³⁺ atoms). The N³⁺ dopant is located at an oxygen site of a corresponding undoped MgₓGe₁₋ₓO₂₋ₓ crystal structure. Methods of doping an epitaxial layer of MgₓGe₁₋ₓO₂₋ₓ include substituting an oxygen site of a corresponding undoped MgₓGe₁₋ₓO₂₋ₓ crystal structure with N³⁺.

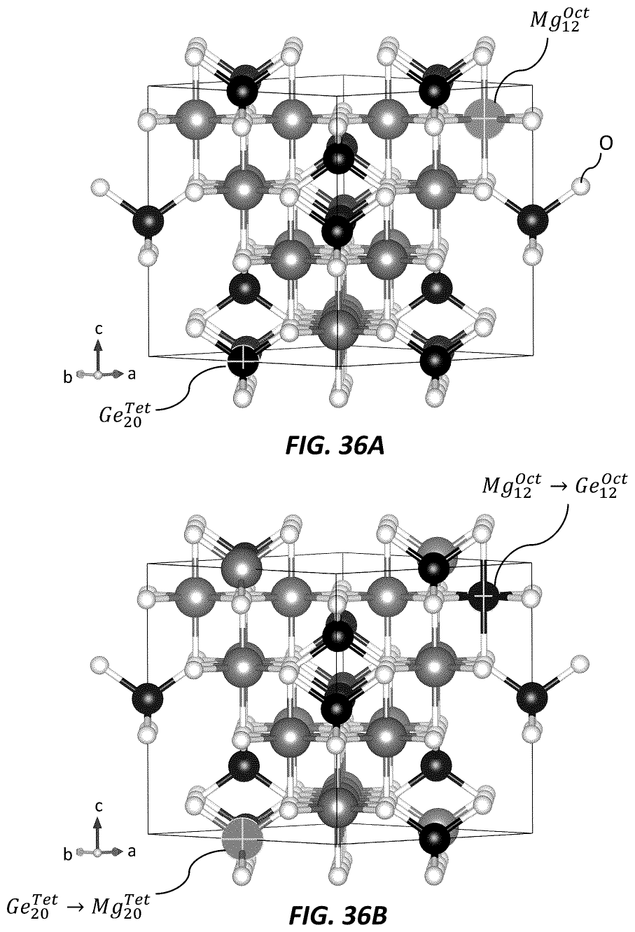

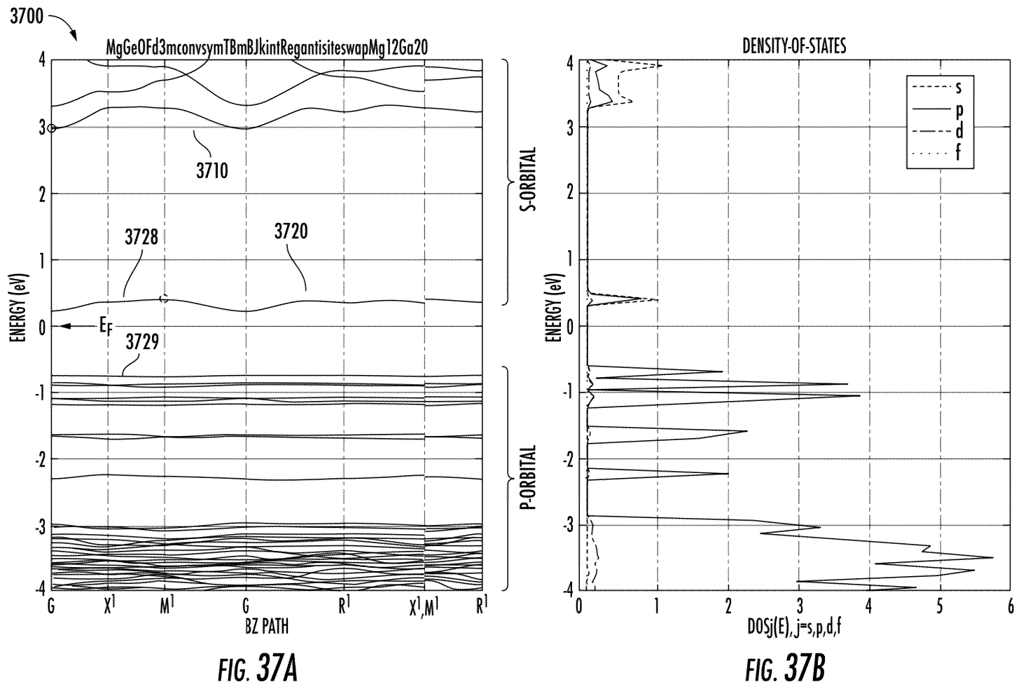

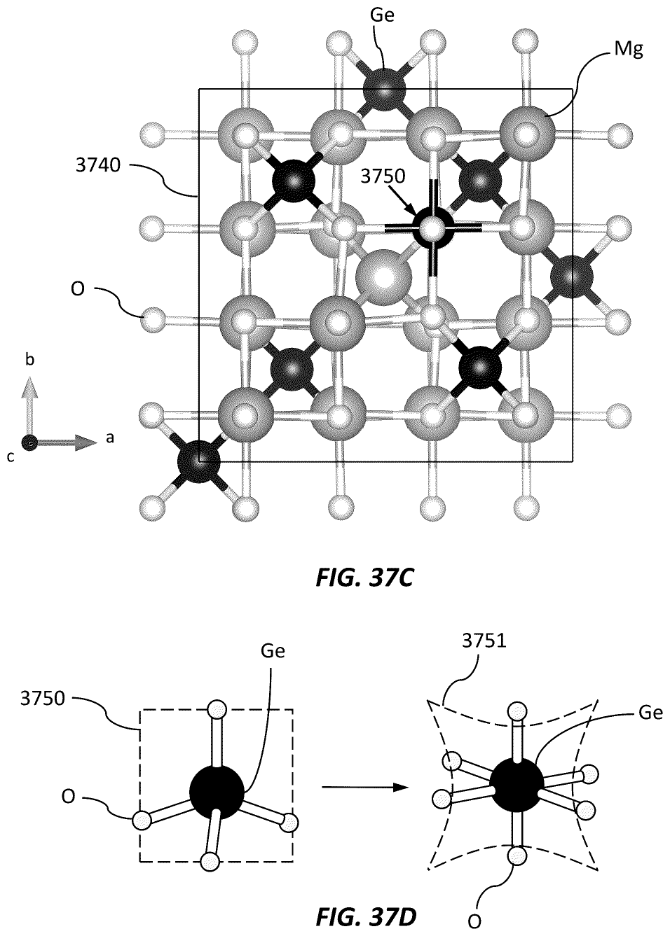

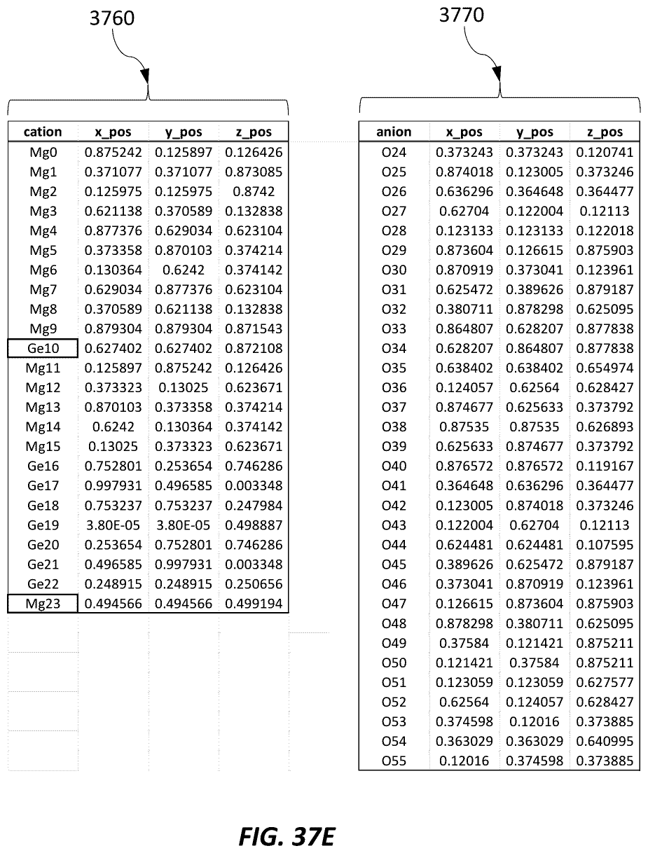

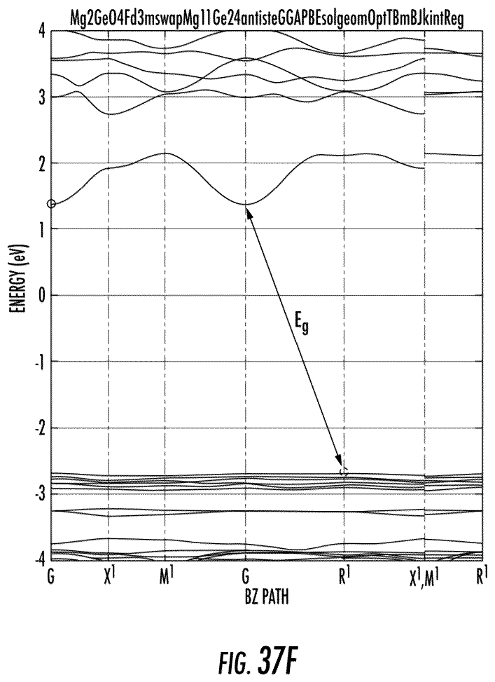

In some aspects, atoms within a unit cell can be replaced by each other to create a p-type material. This replacement technique shall be referred to in this disclosure as anti-site substitution or anti-site doping, such as Mg and Ge being substituted with the other type of atom (Ge and Mg, respectively) at their respective tetrahedrally and octahedrally bonded locations. Anti-site substitution shall be described in FIGS. 36A-37F.

In FIG. 36A, the stoichiometric unit cell crystal structure of cubic Mg₂GeO₄ (Fd3m) is shown, identifying normal structural positions of selected Mg and Ge atomic sites that will be used in a cation anti-site doping process. In this example, atoms in the tetrahedrally bonded Ge₂₀ location (Ge₂₀^{Tet}) and the octahedrally bonded Mg₁₂ location (Mg₂₀^{Oct}) will be replaced by another atom.

FIG. 36B shows an aspect of an anti-site cross-substitution where in this example the exchange process comprises a nominal Mg₁₂ site that is replaced by a Ge atom during formation of the crystal structure to become Ge₁₂^{Oct}, and where also a nominal Ge₂₀ site is replaced by a Mg atom during formation of the crystal structure to become Mg₂₀^{Oct}. It is noted that the total number of Mg and Ge cations within the unit cell remain unchanged, thus preserving the total number of Mg and Ge atoms in the unit cell. As a result of the anti-site substitution, the original Fd3m (cubic) space group crystal becomes Cm (monoclinic) space group.

FIG. 37A shows the resultant E-k diagram 3700 for the anti-site exchange within Mg₂GeO₄ (Fd3m) illustrated in FIG. 36B, showing the valence band 3720 and conduction band 3710 structure. In this example, the selective Mg↔Ge anti-site cross-substitution results in a non-ideal character of the E-k band structure by altering the new unit cell space group symmetry from that of a normally cubic (i.e., no anti-site exchange) into a monoclinic structure. Anti-site exchange is energetically unfavorable for a simple swap of the atomic position of one Mg atom into a local tetrahedral site and conversely one Ge atom into a local octahedral site. The band structure becomes reduced in magnitude compared to the most stable normal Fd3m configuration. The intermediate bands (e.g., defect bands 3728, 3729) created deep within the gap indicate the electronic structure is self-compensated as the Fermi level (E_{f}) is positioned between the lowest energy s-orbital and highest p-orbital energy across the k-vectors in the Brillouin-zone. FIG. 37B is an electronic density of states diagram for the Mg↔Ge anti-site exchange example of FIG. 36B.

FIG. 37C shows the distorted crystal unit cell 3740 resulting from geometric optimization via the process of energy minimization for a single Mg↔Ge anti-site atom exchange in the Mg₂GeO₄ crystal structure illustrated in FIG. 36B. An example Ge atom local environment 3750 is highlighted.

FIG. 37D is a schematic diagram of the cubic bonding local environment 3750 of a Ge atom (tetrahedrally bonded) within a nominal Fd3m crystal and the resulting distorted crystal field 3751 when the Ge atom is substituted into an octahedral bonding site. The lattice distortion minimizes the resulting unit cell formation energy.

Shown in FIG. 37E are table 3760 and table 3770 of cation and anion positions, respectively, for a distorted crystal structure, for the case of a single anti-site substitution. In this example of FIG. 37E, the Mg₁₀ site is substituted with Ge (Ge₁₀), and the Ge₂₃ site is substituted with Mg (Mg₂₃).

FIG. 37F is an E-k band structure of a geometry-optimized single anti-site substitution in which Mg₁₁ site is substituted with Ge (Ge₁₁), and the Ge₂₄ site is substituted with Mg (Mg₂₄). The resulting bandgap E_{g} is indirect type and is smaller than the nominal stoichiometric Fd3m case. Aspects include semiconductor structures and devices in which an epitaxial layer of MgₓGe₁₋ₓO₂₋ₓ has a doped unit cell structure and a corresponding undoped unit cell structure (i.e., the corresponding undoped structure is the nominal MgₓGe₁₋ₓO₂₋ₓ structure that is not doped). With the doped unit cell structure, the MgₓGe₁₋ₓO₂₋ₓ is an indirect bandgap p-type material; where the doped unit cell structure comprises a Ge atom in a first location that is occupied by Mg in the corresponding undoped unit cell structure; and the doped unit cell structure comprises a Mg atom in a second location that is occupied by Ge in the corresponding undoped unit cell structure. In the doped unit cell structure, the Ge atom is octahedrally bonded and the Mg atom in the second location is tetrahedrally bonded. Methods of doping an epitaxial layer of MgₓGe₁₋ₓO₂₋ₓ include placing a Ge atom in a first location that is occupied by Mg in a corresponding undoped unit cell structure of the MgₓGe₁₋ₓO₂₋ₓ and placing a Mg atom in a second location that is occupied by Ge in the corresponding undoped unit cell structure.

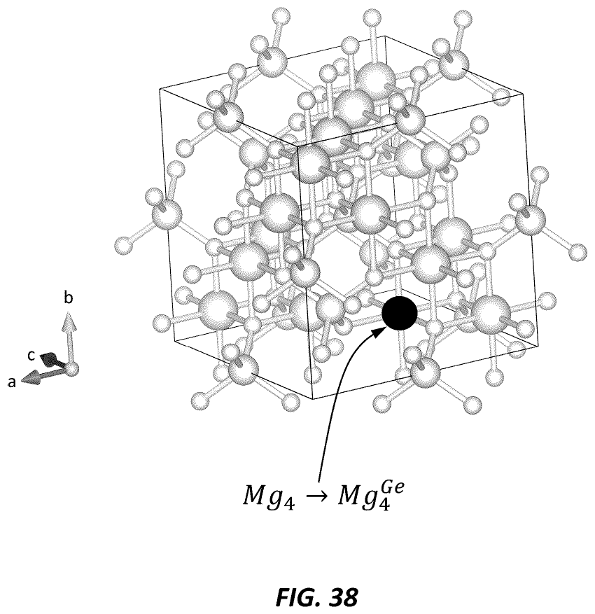

In some aspects, either excess Mg or excess Ge atoms can be utilized to create a doped material, as shall be described by FIGS. 38-41. Aspects include semiconductor structures and devices in which an epitaxial layer of MgₓGe₁₋ₓO₂₋ₓ is doped with excess Ge atoms or excess Mg atoms. Methods of doping an epitaxial layer of MgₓGe₁₋ₓO₂₋ₓ include doping with excess Ge atoms or excess Mg atoms. FIG. 38 shows a unit cell crystal structure diagram of the cation lattice positions for a space group Fd3m transformed from a normal configuration to a germanium-rich configuration. In this example, an excess of Ge-atoms is created by transforming, for example, the Mg₄ site into an additional Ge atom. The resulting composition exhibits a new space group symmetry of R3m, the resulting composition being equivalent to:

$${Mg}_{\frac{16}{24}} {Ge}_{\frac{8}{24}} {O}_{\frac{32}{24}} {\to }^{Ge - excess} {Mg}_{\frac{15}{24}} {Ge}_{\frac{9}{24}} {O}_{\frac{32}{24}}$$

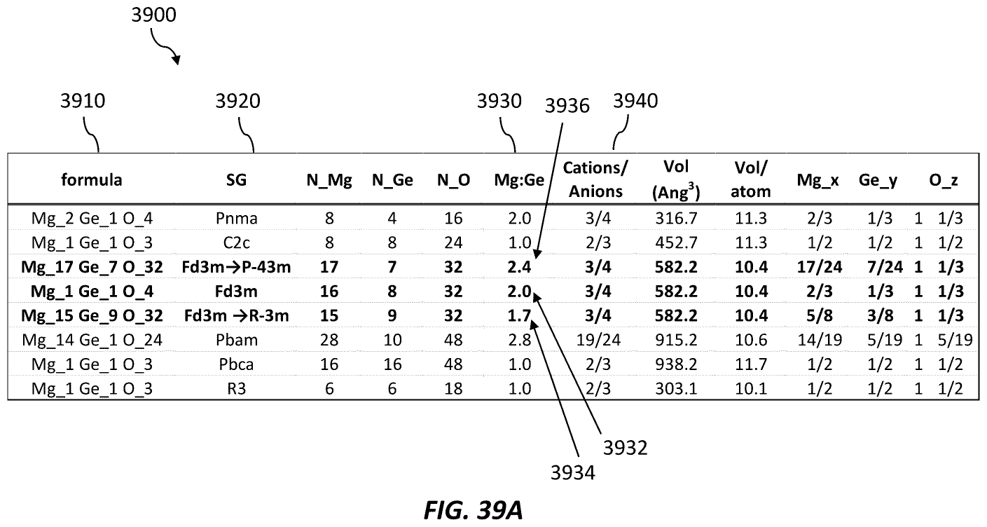

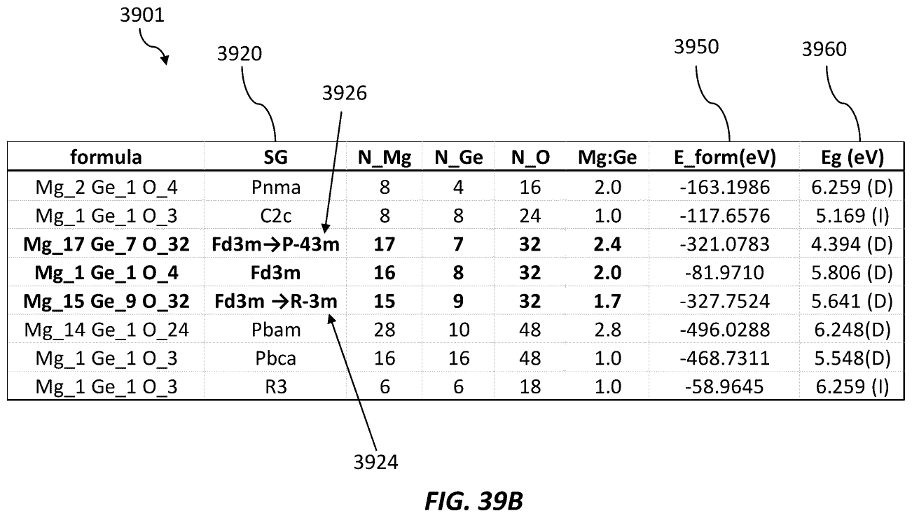

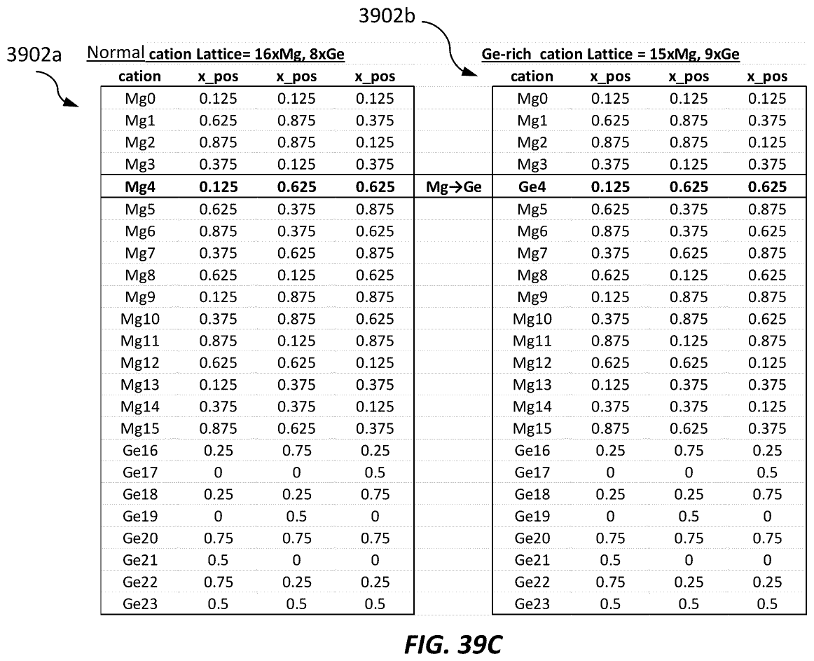

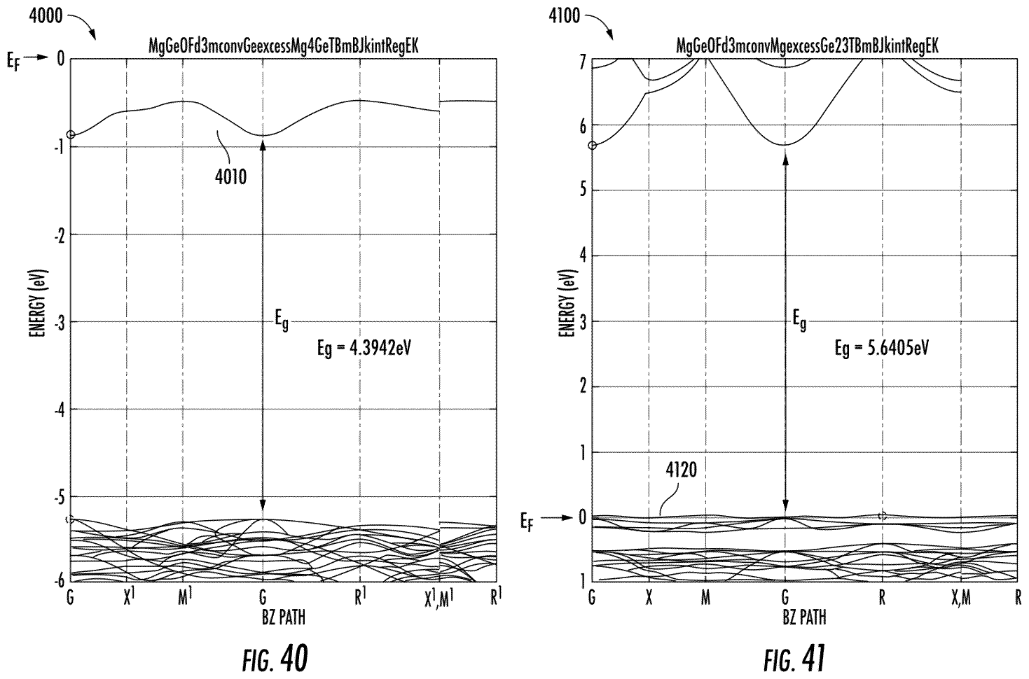

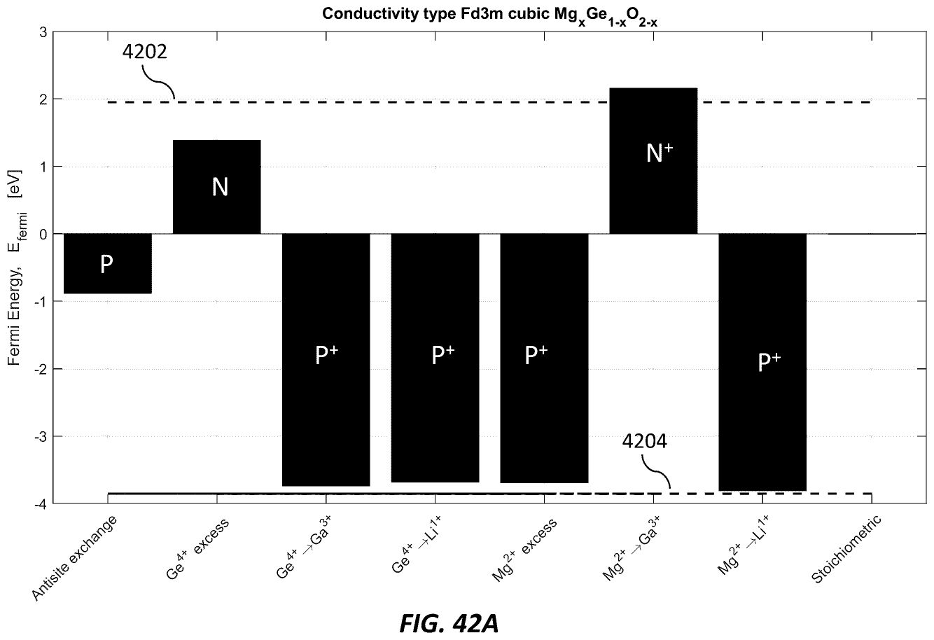

FIG. 39A is a table 3900 of possible compositions (formula 3910) of MgₓGe_{y}O_{z}, in accordance with some aspects, with respective crystalline space groups 3920. The number of Mg atoms (N_Mg), Ge atoms (N_Ge) and oxygen atoms (N_O) in each unit cell are listed, along with the relative number 3940 of cations and anions within the crystal unit cell. The ratio 3930 of Mg:Ge atoms within each unit cell is calculated for a given space group. For the example case of a nominal Mg₂GeO₄ Fd3m crystal space group, the ratio of cations to anions Mg:Ge is 2.0 (marked by arrow 3932). With excess Ge atoms (9 atoms instead of 8 atoms in the nominal state), the ratio Mg:Ge is 1.7 (arrow 3934), and with excess Mg atoms (17 atoms instead of 16 in the nominal state), the ratio Mg:Ge is 2.4 (arrow 3936).

FIG. 39B is a table 3901 of the formation energy 3950 and lowest energy bandgap 3960 for the example MgₓGe_{y}O_{z} compounds referred to in FIG. 39A. For the case of Fd3m Mg₂GeO₄ crystal when modified into Mg-excess, this composition exhibits P-43m symmetry (marked by arrow 3926), and with Ge-excess the composition exhibits R-3m symmetry (marked by arrow 3924). Both cases of Mg-rich or Ge-rich structures are less energetically favorable with intrinsically higher formation energy; that is, the doped forms are less stable.

In FIG. 39C, table 3902a shows the atomic positions within a normal Fd3m crystal, and table 3902b shows a Fd3m crystal formed with Ge-excess. In this example, the excess Ge atom is inserted by substituting a Mg-site (Mg₄ in this example) with Ge. While the total number of cations (Mg and Ge) is preserved, the number of Ge atoms per unit cell is increased.

FIG. 40 is an E-k diagram 4000 of Ge-doped Mg₂GeO₄ (Fd3m) where there is an excess of Ge. As can be seen, the doped Mg₂GeO₄(Fd3m) is a direct bandgap semiconductor with a bandgap energy of 4.3942 eV at zone center that is less than the undoped case of FIG. 8A. The Fermi energy (E_{f}) is deep within the conduction band 4010 and therefore exhibits n-type conductivity.

FIG. 41 is an E-k diagram 4100 of Mg-doped Mg₂GeO₄ (Fd3m) where there is an excess of Mg. As can be seen, the doped Mg₂GeO₄ (Fd3m) is a direct bandgap semiconductor with a bandgap energy of 5.6405 eV that is less than the undoped case of FIG. 8A. The Fermi energy (E_{f}) is positioned close to the edge of the valence band 4120 and therefore exhibits p-type conductivity.

FIG. 42A is a diagram summarizing some of the doping strategy aspects described with respect to FIGS. 19 to 41. The diagram indicates the resulting type (i.e., n-type or p-type) of the doped Mg₂GeO₄ (Fd3m). The aspects may also be applied to other forms of MgₓGe₁₋ₓO₂₋ₓ. Other modifications include excess O- or O-vacancies which may result in deviation from stoichiometric composition. O vacancies and cation vacancies are all possible and may result in electronic and/or optical modifications of the band structure. The Fermi energy is plotted on the y-axis relative to the undoped intrinsic bands, labeled as conduction band 4202 and valence band 4204. As can be seen, the opportunity for p-type conductivity, which is very challenging conventionally, is possible using Ge-site substitutional doping by Ga and Li, and also by Mg-site substitutional doping by Ge (i.e., Mg excess) and Li. Lithium is distinguished by the ability to create p-type character materials for substitution on either or both Ge and Mg-sites. Ga substitution results in either p-type or n-type doping, depending on whether the Ga is substituted at a Ge site or Mg site, respectively. Controlling where the Ga is inserted can be achieved by, for example, creating deficiencies in the desired lattice sites during formation. For example, the MgₓGe₁₋ₓO₂₋ₓ structure (e.g., epitaxial layer) can be grown to be Ge-deficient, providing open Ge sites to be substituted by Ga. Similarly, Ga substitution at Mg sites can be achieved by growing the MgₓGe₁₋ₓO₂₋ₓ structure in a Mg-deficient manner. Aluminum doping (not shown in this chart) can be achieved using similar techniques, where Mg-deficient growth encourages Al to substitute in Mg sites, resulting in an n-type material, and Ge-deficient growth encourages Al to substitute in Ge sites, resulting in a p-type material. These substitution strategies are further explained by the formation energies in FIG. 42B.

FIG. 42B is a diagram showing the relative formation energy for selected substitutional impurity doping aspects of the Mg-site or Ge-site in Mg₂GeO₄ (Fd3m). In this diagram, the impurity specie is selected from Li, Al, Ga and Ge; however, others may also be possible such as Si, Bi, and/or Zn. Using the dopant Li as an example, bar 4210 represents the formation energy in eV for a Ge site being substituted with Li, and bar 4220 represents the formation energy in eV for a Mg site being substituted with Li. The diagram of FIG. 42B shows that the case of Li-doping exhibits the lowest formation energy of the impurity species presented, with both cases resulting in p-type conductivity character. In another example considering Ga as a dopant, FIG. 42B shows that the insertion of Ga at a Ge site requires more energy than inserting Ge at the Ge site. However, growing the MgₓGe₁₋ₓO₂₋ₓ structure with Ge deficiencies will allow the Ga atoms to substitute at the Ge sites.

Doped forms of magnesium-group IV compounds, including epitaxial layers of the doped compounds, may include doping scenarios as described above for magnesium-germanium-oxides.

In some cases, Mg₂(Siₓ(Ge_{y}Sn_{1-y})₁₋ₓ)O₄ materials where 0≤x≤1 and 0≤y≤1 can be formed with p-type conductivity using Si-site, Ge-site, and/or Sn-site substitutional doping by Ga and Li, and also by Mg-site substitutional doping by Si, Ge, and/or Sn (i.e., Mg deficient) and Li. For example, doping with lithium can form materials with p-type character when substituted on any of Si, Ge, Sn and/or Mg-sites.

Ga substitution results in either p-type or n-type doping, depending on whether the Ga is substituted at an Si, Ge, and/or Sn site, or at a Mg site, respectively. Controlling where the Ga is inserted can be achieved by, for example, creating deficiencies in the desired lattice sites during formation. For example, the Mg₂(Siₓ(Ge_{y}Sn_{1-y})₁₋ₓ)O₄ material structure (e.g., epitaxial layer) can be grown to be Si-deficient, Ge-deficient, and/or Sn-deficient, providing open Si, Ge, and/or Sn sites, respectively, to be substituted by Ga.

Similarly, Ga substitution at Mg sites can be n-type dopants and be achieved by growing the Mg₂(Siₓ(Ge_{y}Sn_{1-y})₁₋ₓ)O₄ material structure in a Mg-deficient manner. N-type materials can also be formed by growing the layer with an excess of Si, Ge, and/or Sn. Aluminum doping can also be achieved in these materials using similar techniques, where Mg-deficient growth encourages Al to substitute in Mg sites, resulting in an n-type material, and Si-deficient, Ge-deficient, and/or Sn-deficient growth encourages Al to substitute in Ge sites, resulting in a p-type material. In cases where the composition includes more than one group IV element, then the overall amount of group IV compared to Mg and/or O is what will determine if the material is Si-deficient, Ge-deficient, and/or Sn-deficient, or have an excess of Mg, since each group IV atom can be substituted in the same lattice positions as other group IV atoms in the crystal.

In some cases, Mg₂(Siₓ(Ge_{y}Sn_{1-y})₁₋ₓ)O₄ materials where 0≤x≤1 and 0≤y≤1 can be formed with one or more impurity species selected from Li, B, N, Al, Ga, In, Ge, Si, P, As, Ni, Bi, and/or Zn.

In some examples, the single crystal Mgₐ(Siₓ(Ge_{y}Sn_{1-y})₁₋ₓ)O_{b} may be a semi-insulating material may comprise a group III metal (e.g., Ga, In) in a group IV (Ge, Si, Sn) or group II (e.g., Mg) site of a corresponding undoped Mgₐ(Siₓ(Ge_{y}Sn_{1-y})₁₋ₓ)O_{b} crystal structure.

In some examples, single crystal Mgₐ(Siₓ(Ge_{y}Sn_{1-y})₁₋ₓ)O_{b} is doped. In some examples, the single crystal Mgₐ(Siₓ(Ge_{y}Sn_{1-y})₁₋ₓ)O_{b} may be a direct bandgap p-type material and may comprise B, Ga, Al or Li+ in a Ge, Sn, or Si site of a corresponding undoped Mgₐ(Siₓ(Ge_{y}Sn_{1-y})₁₋ₓ)O_{b} crystal structure. For example, at least one of the elements B, Ga, Al and/or Li+ can be present. In some examples, the single crystal Mgₐ(Siₓ(Ge_{y}Sn_{1-y})₁₋ₓ)O_{b} may be a direct bandgap p-type material and may comprise Li+ in a Mg site of a corresponding undoped Mgₐ(Siₓ(Ge_{y}Sn_{1-y})₁₋ₓ)O_{b} crystal structure. In some examples, he single crystal Mgₐ(Siₓ(Ge_{y}Sn_{1-y})₁₋ₓ)O_{b} may be a direct bandgap p-type material and may comprise N³⁺ in an O site of a corresponding undoped Mgₐ(Siₓ(Ge_{y}Sn_{1-y})₁₋ₓ)O_{b} crystal structure. In some examples, the single crystal Mgₐ(Siₓ(Ge_{y}Sn_{1-y})₁₋ₓ)O_{b} may be a direct bandgap p-type material and may comprise intrinsic defects of oxygen vacancies or excess oxygen.

In some examples, the the single crystal Mgₐ(Siₓ(Ge_{y}Sn_{1-y})₁₋ₓ)O_{b} may be a direct bandgap n-type material and may comprise P or As in a Ge, Sn, or Si site of a corresponding undoped Mgₐ(Siₓ(Ge_{y}Sn_{1-y})₁₋ₓ)O_{b} crystal structure. In some examples, the single crystal Mgₐ(Siₓ(Ge_{y}Sn_{1-y})₁₋ₓ)O_{b} may be a direct bandgap n-type material and may comprise Ga, Al or Ni+ in a Mg site of a corresponding undoped Mgₐ(Siₓ(Ge_{y}Sn_{1-y})O_{b} crystal structure. In some examples, the single crystal Mgₐ(Siₓ(Ge_{y}Sn_{1-y})₁₋ₓ)O_{b} may be a semi-insulating material may comprise a group III metal in a group IV or group II site of a corresponding undoped Mgₐ(Siₓ(Ge_{y}Sn_{1-y})₁₋ₓ)O_{b} crystal structure.

### Growth of Films and Semiconductor Structures

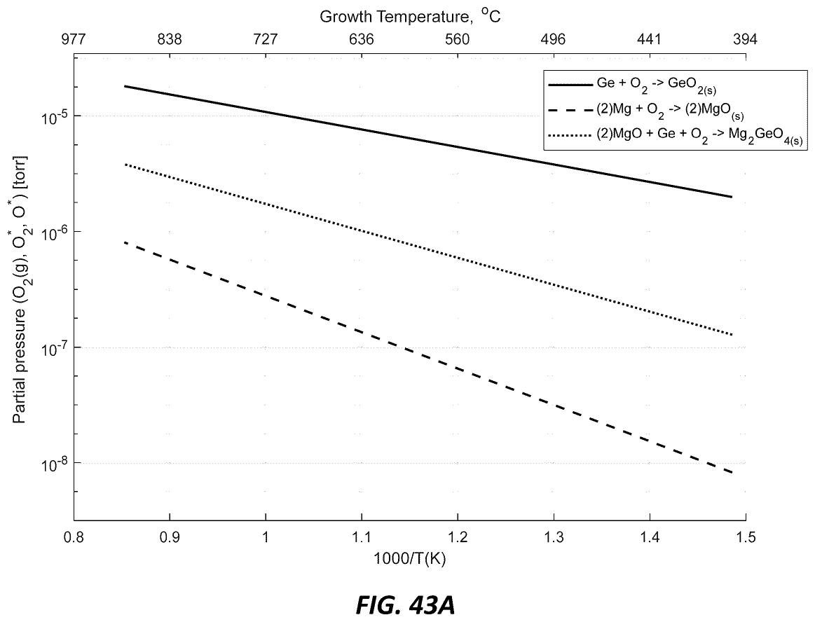

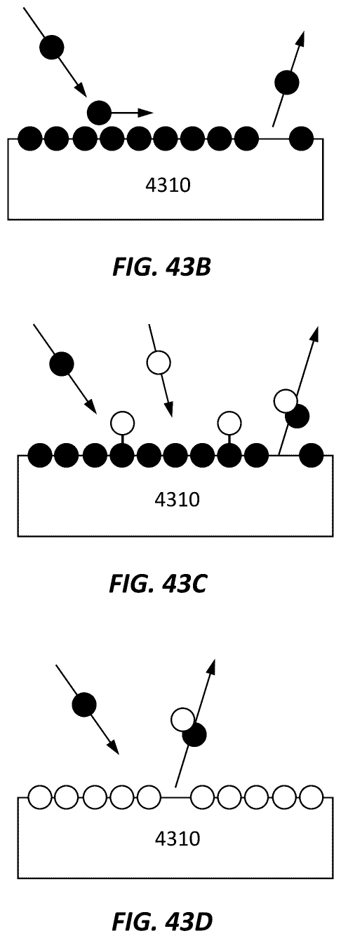

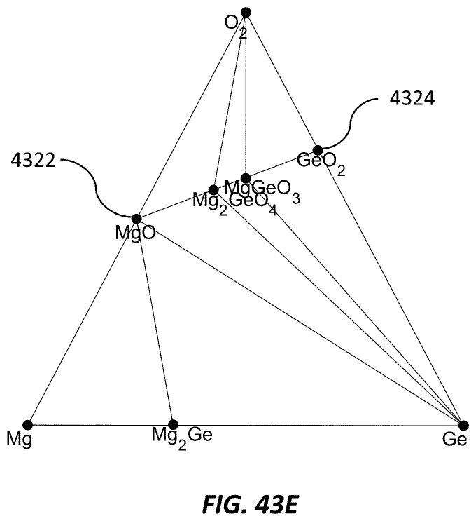

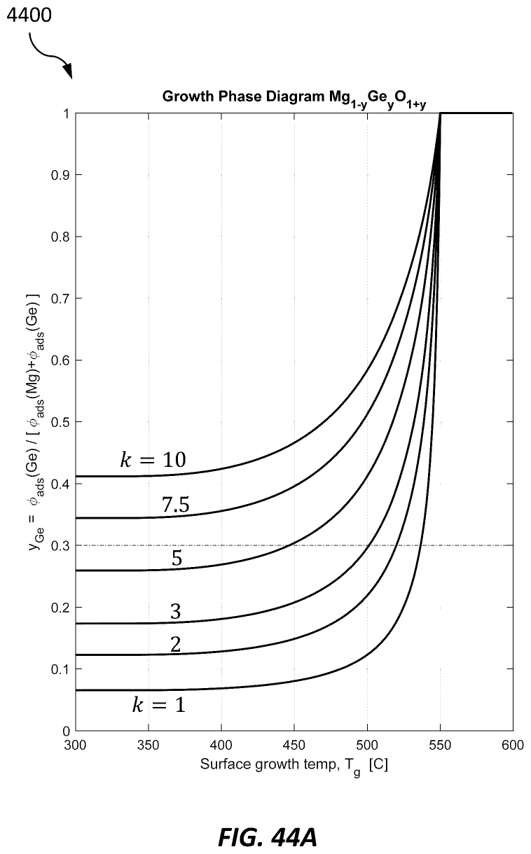

Methods of forming epitaxial layers of magnesium-group IV oxides, such as Mgₐ(Siₓ(Ge_{y}Sn_{1-y})₁₋ₓ)O_{b} or MgₓGe_{y}O_{z} require thermokinetic insights described herein to properly grow the structures, such as with molecular beam epitaxy (MBE). FIG. 43A shows a plot of a thermodynamic oxidation Ellingham diagram for the formation of binary oxides 2Mg+O₂→2MgO and Ge+O₂→GeO₂ and ternary oxide 2MgO+Ge+O₂→Mg₂GeO₄. For a given growth temperature and metal specie there exists an oxygen partial pressure where the metal begins to oxidize. A boundary line between the metal remaining oxide-free (below the boundary line) or the formation of the respective oxide (above the boundary line) is shown for each oxide reaction.

In general, the growth phase diagram to deposit a selected oxide compound from constituent species indicates that sufficient oxygen species is required at a given growth temperature to optimize the reaction pathway. The oxygen source can be selected from molecular oxygen, excited metastable molecular oxygen and atomic oxygen. In one aspect, activated oxygen such as atomic oxygen is utilized for growth of the oxides described in the present disclosure. The activated oxygen can be from an excited plasma source or an ozone source. For Mgₐ(Siₓ(Ge_{y}Sn_{1-y})₁₋ₓ)O_{b} or MgₓGe_{y}O_{z} thin film growth from elemental sources (e.g., solid effusion sources such as Knudsen cells), the Ellingham diagram of FIG. 43A (partial pressure of oxygen in Torr vs. 1000/temperature T in Kelvin) supports the need to supply a large incident excess of Ge-flux arriving at the surface throughout the temperature range with respect to the Mg-flux in order to create a Mgₐ(Siₓ(Ge_{y}Sn_{1-y})₁₋ₓ)O_{b} or MgₓGe_{y}O_{z} compound. If sufficient Ge is not supplied during co-deposition, the germanium oxide formed on a surface would be reduced to elemental Ge in the presence of Mg.

FIGS. 43B, 43C and 43D show schematic diagrams depicting the surface kinetics of film formation at an epi-surface 4310 using elemental fluxes of constituent specie. FIG. 43B shows the surface kinetics of incident Ge or Mg atoms in the absence of oxygen. The arrival rate of incident atoms minus the desorption rate results in a net deposited surface coverage. The desorption rate is dependent on surface temperature. For the growth conditions of interest in this disclosure, the desorption rate of the Mg dominates due to the low activation energy for desorption compared to Ge and follows an Arrhenius behavior. Furthermore, both Ge and Mg exhibit a sticking probability less than 1 for chemisorption and physisorption to the epi-surface 4310 which is also dependent upon the binding energy of the crystal-surface complex (which is intimately related to the surface reconstruction of the bound surface atoms and is a function crystal symmetry, surface temperature and oxygen environment). Higher growth temperatures in general favor surface migration of cations which aid in layer-by-layer growth regimes. At high growth temperatures for surface 4310, molecular oxygen readily dissociates; however, it is found that an activated form of oxygen, ideally atomic neutral or ionized oxygen atoms, are preferred, with neutral species more preferred. FIG. 43B shows the co-deposition of cations and anions toward the surface. For the case of Ge and O co-deposition the ratio of Ge:O determines where an oxide can form. Furthermore, GeO bound to the surface in crystalline form can readily decompose into GeO(g) vapor at sufficiently high temperature, such as >500° C. In the example of growth on MgO substrates, in considering the sticking coefficients Si of Mg and Ge, it was found experimentally in accordance with the present disclosure that δ_{Mg}˜10×δ_{Ge} with δ_{Mg}˜0.5. That is, Mg tends to deposit more easily on the MgO substrate than Ge.

FIG. 43C shows the arrival towards the epi-surface 4310 of cations (filled circles) and anions (open circles). For the case of a cation=Mg and an anion=O, the formation of MgO occurs. Similarly, for the case of cation=Ge the surface formation of GeO₂ is possible. For high enough surface temperature, the solid GeO₂ formed on the epi-surface will decompose into a volatile GeO vapor with the activation temperature for GeO₂ decomposition being −500° C.

FIG. 43D shows a case where high Ge fluxes are incident with respect to the co-deposition oxygen flux. In such a scenario, Ge can etch either the GeO₂ or MgO formed on the epi-surface 4310. The growth limit between deposition and etching can be controlled by the Ge:[active-O]ratio, where deposition for the conditions of Ge:O<1 and growth temperatures are less than ˜600° C. For the etching process of the surface, Ge:O>1 with increasing etch rate for surface temperatures 400-800° C.

FIGS. 43C and 43D illustrate that for successful formation of a desired MgₓGe_{y}O_{z} layer, a careful balance must be maintained with the growth temperature and the flux ratios between Mg, Ge, and O, to enable the Ge to be deposited while preventing Ge and/or Mg from being removed from the surface. For example, as described in FIG. 43A, a large incident excess of Ge-flux with respect to the Mg-flux is needed in order to create and stabilize MgₓGe_{y}O_{z} compound. However, too much Ge flux can result in temperature-dependent effects that are counter-productive to MgₓGe_{y}O_{z} formation, such as the Ge becoming a volatile vapor as explained in FIG. 43C or having the Ge etch away either the GeO₂ or MgO as explained in FIG. 43D. Furthermore, pure GeO₂ single crystal films are found to be challenging due to the surface kinetics and equally possible polymorphs, resulting in polycrystalline and amorphous construction. In aspects of the present disclosure, Mg and Zn are ideal crystal growth modifiers that stabilize the formation of GeO-based compounds, and the compounds can attain extremely high crystallinity in a predetermined crystal structure.

FIG. 43E shows a summary ternary phase diagram for the Mg—Ge—O system as calculated using DFT, showing the stable compositions of MgO, GeO₂, Mg₂GeO₄ and MgGeO₃, all being along the same line from point 4322 (MgO) to point 4324 (GeO₂). The relative mole fractions are represented by the configuration points on the phase diagram. Note the absence of continuous alloy compositions, as the compositions shown represent the most stable forms.

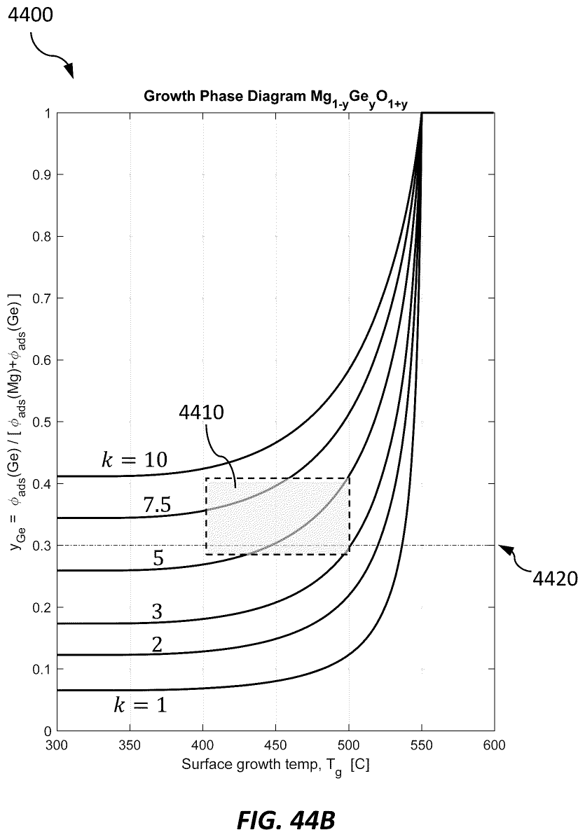

FIG. 44A shows a representative growth phase diagram 4400 for epitaxial co-deposition of Mg_{1-y}Ge_{y}O_{1+y} (0≤y<1) compound (equivalent to MgₓGe₁₋ₓO₂₋ₓ, 0<x≤1) using elemental Ge, Mg and active-O fluxes as a function of surface growth temperature. Note x=0 and y<1 are excluded in the above formulae only to emphasize that the single crystal form of GeO₂ is challenging to realize as a single crystal film. It is however possible that small amounts of stabilizing species operating as a surfactant may indeed stabilize crystalline GeO₂ films. For example, Bi may be used as a surfactant. For a given growth temperature and incident Ge:Mg flux ratio, the resulting surface adatom ratio y_{Ge} is plotted in FIG. 44A.

Isotherms of incident flux ratio k=Φ_{Ge}^{inc}/Φ_{Mg}^{inc} ranging from 1 to 10 are shown. The constructed phase diagram (y_{Ge}, T_{g}, k) illustrates the underlying kinematic process where Mg deposited on a surface exhibits an Arrhenius desorption rate as a function of temperature. Ge deposited on the epi-surface reacts with oxygen to form either an oxide compound or decomposes into GeO monoxide vapor, with an activation temperature of approximately 500-550° C. Therefore, the elemental incident flux ratio Φ_{Ge}^{inc}/Φ_{Mg}^{inc} is modified by the deposition surface temperature to retain an adsorbed surface species ratio given by Φ_{Ge}^{ads}/Φ_{Mg}^{ads}.

FIG. 44B shows the same growth phase diagram 4400 of FIG. 44A but depicting an experimentally determined growth window 4410 for high quality single crystal Mg₂GeO₄ with Fd3m crystal structure deposited on an MgO substrate. The surface growth temperature in this window 4410 is from about 400° C. to about 500° C., with values of k=Φ_{Ge}^{inc}/Φ_{Mg}^{inc} of approximately k=3 to 9, and the surface adatom ratio y_{Ge} is from about 0.28 to about 0.4. The line marked by arrow 4420 indicates the stoichiometric value y_{Ge}=1/3 (i.e., to achieve the desired stoichiometry of Mg₂GeO₄). The growth window 4410 demonstrates conditions in which actual growth of Mg₂GeO₄ was verified experimentally, where the growth window 4410 is overlaid on the theoretical projections graphed in the chart.

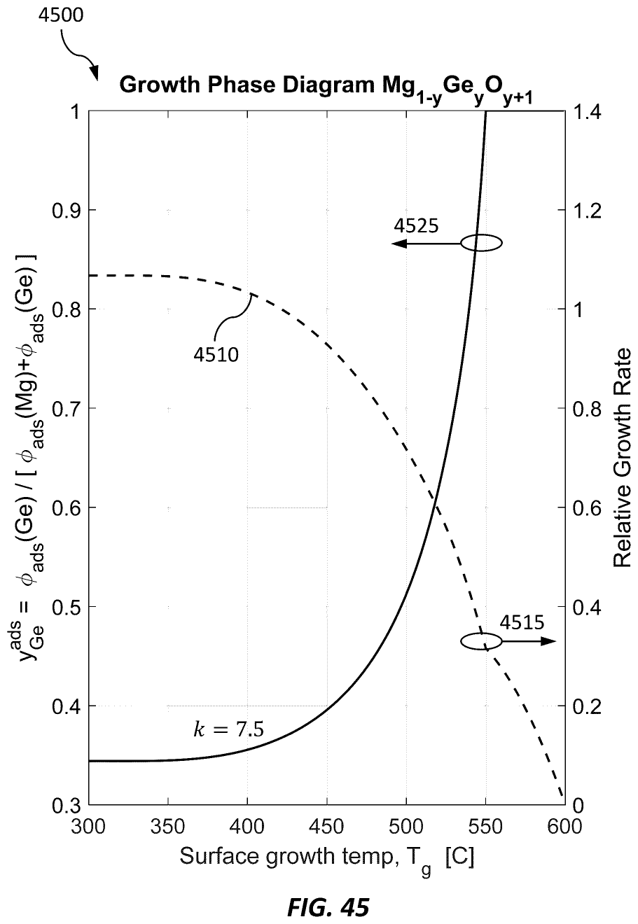

FIG. 45 shows a growth phase diagram 4500 for Mg_{1-y}Ge_{y}O_{1+y} for the case of k=Φ_{Ge}^{inc}/Φ_{Mg}^{inc}=7.5. The resulting variation in growth rate 4510 of the film is shown, with the units shown on the right-hand y-axis relating to the relative growth rate where zero corresponds to negligible adsorbed species on the growth surface and values above one indicate net accumulation of surface species. Two kinetic effects limit the growth rate, namely, Mg surface desorption and GeO decomposition. For fixed incident Ge:Mg flux ratio the stoichiometric control window of y_{Ge}=1/3 required for Mg₂GeO₄ has an optimal growth temperature 450° C.<Tg<500° C. as discussed above. The inherent self-assembly of the stable Mg₂GeO₄ during co-deposition allows slight deviations from optimal fluxes and temperatures. In FIG. 45, as the growth temperature increases and exceeds the growth window, the growth rate decreases dramatically as indicated by arrow 4515. Arrow 4525 indicates that as temperature decreases, the adatom y_{Ge} ratio decreases.

Methods of forming a semiconductor device include providing a substrate comprising a substantially single crystal substrate material that has a crystal symmetry compatible with an epitaxial layer of Mgₐ(Siₓ(Ge_{y}Sn_{1-y})₁₋ₓ)O_{b} or MgₓGe₁₋ₓO₂₋ₓ; and co-depositing materials onto the substrate to form the epitaxial layer of Mgₐ(Siₓ(Ge_{y}Sn_{1-y})₁₋ₓ)O_{b}, with 1.5≤a≤2.5, 3≤b≤5, 0≤x≤1, and 0≤y≤1, or an epitaxial layer of MgₓGe₁₋ₓO₂₋ₓ, with x having a value of 0≤x≤1. The materials comprise at least two elements selected from Mg, Ge, Sn, Si and oxygen in accordance with the value of x, the Mg, Ge, Sn, Si and oxygen being supplied by a Mg source, a Ge source, a Sn source, a Si source, and an activated oxygen source, respectively. In some aspects, the epitaxial layer is a substantially single crystal structure and strained to a lattice mismatched layer or substrate. In yet another aspect the epitaxial film and substrate may each have different space group symmetry by configured to have favorable surface configuration for low lattice mismatched heterointerface. In some aspects, the co-depositing is performed using a molecular beam epitaxy process or a co-deposition process of elemental fluxes. Organometallic or other precursor species are also possible for transporting Ge, Mg, Sn, Si and O to the growth surface. In some aspects, methods include depositing a buffer layer between the substrate and the epitaxial layer of Mgₐ(Siₓ(Ge_{y}Sn_{1-y}) O or MgₓGe₁₋ₓ O₂₋ₓ, for example a buffer layer comprising MgO or other forms of magnesium germanium oxides. In some aspects, in the co-depositing, the epitaxial layer of Mgₐ(Siₓ(Ge_{y}Sn_{1-y})₁₋ₓ)O_{b} or MgₓGe₁₋ₓO₂ self-assembles.

Aspects may include determining an elemental incident flux ratio of the Ge source to the Mg source (Φ_{Ge}^{inc}/Φ_{Mg}^{inc}) according to a deposition surface temperature, to retain an adsorbed surface species ratio of the Ge to the Mg (Φ_{Ge}^{ads}/Φ_{Mg}^{ads}). In some aspects, the co-depositing comprises using a growth temperature of 400-500° C., and a flux ratio k of the Ge source to the Mg source (Φ_{Ge}^{inc}/Φ_{Mg}^{inc}) of k=3 to 9. For example, the flux ratio k may have a value from 3 to 7.5 and the MgₓGe₁₋ₓO₂₋ₓ may be Mg₂GeO₄. Methods may include forming a superlattice on the substrate, wherein the superlattice has a unit cell comprising a first layer and a second layer, wherein the first layer in the superlattice is the epitaxial layer of MgₓGe₁₋ₓO₂₋ₓ. In some aspects, the second layer of the superlattice is a second epitaxial layer of Mg_{y}Ge_{1-y}O_{2-y}, wherein y ranges from 0 to 1 and x≠y.

Various semiconductor structures for electronic devices and optoelectronic devices can be formed with the ultrawide bandgap epitaxial layers of Mgₐ(Siₓ(Ge_{y}Sn_{1-y})₁₋ₓ)O_{b} or MgₓGe₁₋ₓO₂₋ₓ grown as epitaxial single crystal structures on deliberately chosen substrates, in accordance with the present disclosure. For example, any of the substrate materials listed in FIG. 12 may be utilized, such as for growing epitaxial layers of Mg₂GeO₄ or MgGeO₃. In some aspects, a semiconductor structure includes a substrate comprising a substantially single crystal substrate material; and an epitaxial layer of MgₓGe₁₋ₓO₂₋ₓ on the substrate, with x having a value of 0≤x<1; where the epitaxial layer of MgₓGe₁₋ₓO₂₋ₓ has a crystal symmetry compatible with the substrate material. In some aspects, a a semiconductor structure includes a substrate comprising a substantially single crystal substrate material; and an epitaxial layer of single crystal Mgₐ(Siₓ(Ge_{y}Sn_{1-y})₁₋ₓ)O_{b}, wherein 1.5≤a≤2.5, 3≤b≤5, 0≤x≤1, and 0≤y≤1; wherein the single crystal Mgₐ(Siₓ(Ge_{y}Sn_{1-y})₁₋ₓ)O_{b} has a crystal symmetry compatible with the substrate or the underlying layer

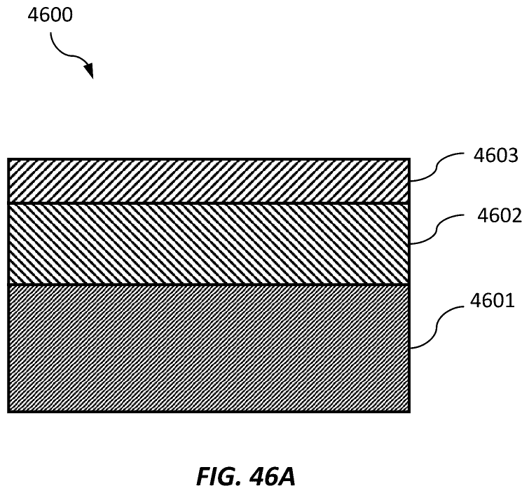

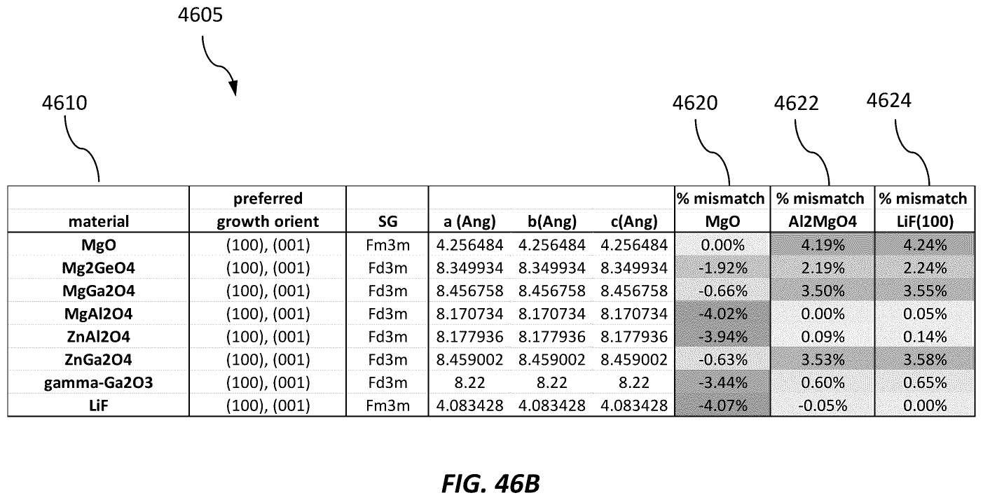

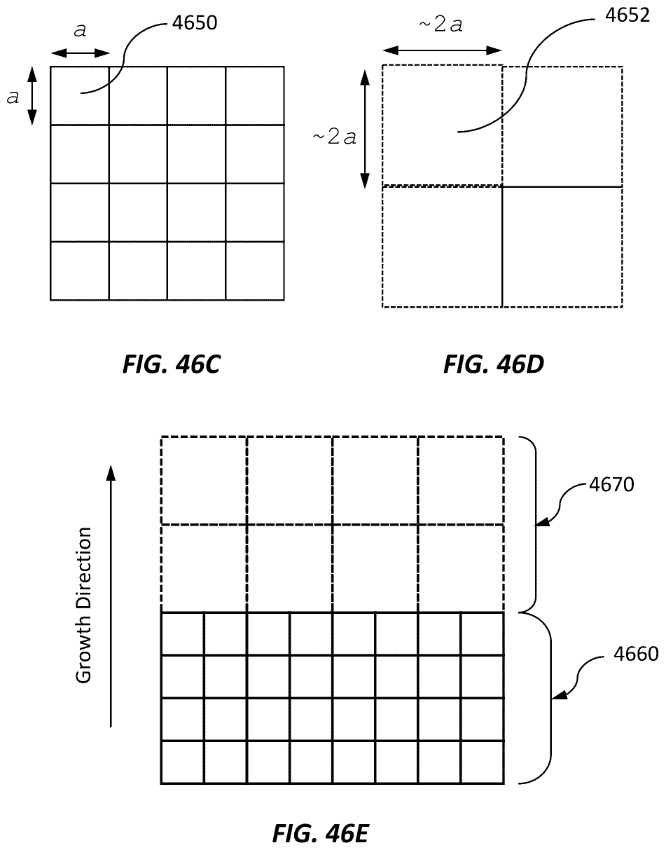

FIG. 46A shows a sectional view of an epitaxially formed layered semiconductor structure 4600 comprising a substrate 4601, a substantially single crystal epilayer (i.e., epitaxial layer) 4602 (which may include one or more epilayers), and an optional cap 4603. In some aspects, the substrate 4601 may be MgO, the epilayer 4602 may comprise Mg₂GeO₄ (Fd3m), and the cap 4603 may be formed of MgO. In this example, the epilayer(s) 4602 are formed via a deposition process on a prepared substrate 4601 having a surface crystal structure advantageous for growth of the epilayer as described herein.

FIG. 46B shows a table 4605 of crystal structure properties of example epitaxial film materials 4610 and substrates that are compatible with Mg₂GeO₄, in accordance with some aspects. It was found experimentally that the misfit in lattice matching between Mg₂GeO₄ and the substrate or other listed cubic oxides can be managed to form extremely low defect density structures with high coherence. The smallest lattice mismatch between Mg₂GeO₄ and substrate was found to be for the substrate material MgO (column 4620) followed by Al₂MgO₄ (column 4622) and LiF (column 4624). These substrates are important because of their high optical transparency in the extreme ultraviolet range. All the compounds listed are cubic, with MgO and LiF having approximately half the lattice constant for the AB₂O₄ compounds, where {A,B} are selected from {Al, Ga, Ge, Zn}.

FIG. 46C shows a cubic crystal structure diagram of a substrate selected from MgO or LiF or similar crystal structure, having a symmetric lattice constant, a, for each unit cell 4650. Other substrates such as monoclinic beta-phase Ga₂O₃ are also possible using the unique (100)-oriented surface.

FIG. 46D shows a cubic crystal structure diagram of a substrate or epilayer selected from Mg₂GeO₄, MgGa₂O₄, ZnGa₂O₄ or MgAl₂O₄ (or similar), having a symmetric lattice constant for each unit cell 4652 approximately twice as large as that illustrated in FIG. 46C, namely 2a.

FIG. 46E shows a schematic diagram depicting coherent epitaxial layer formation along a growth direction of two distinct cubic crystal structures having large difference in lattice constants. Layer 4660 has a lattice constant a (see FIG. 46C), and layer 4670 has a lattice constant ˜2×a (see FIG. 46D). For example, an epilayer 4670 of Mg₂GeO₄ (or γ-Ga2O3, MgGa₂O₄, ZnGa₂O₄ or MgAl₂O₄) can be formed with low dislocation density at the growth interface between layers 4660 and 4670 by matching the epilayer lattice constant with a multiple (e.g., integer multiple) of the lattice constant of the underlying film or substrate (layer 4660). In the example of FIG. 46E, the lattice constants are matched with an integer multiple of about 2 in the plane of the heterointerface; that is, the lattice constant a of layer 4660 matched with the lattice constant 2a of layer 4670. Put another way, within an x-y growth plane perpendicular to the growth direction, the lattice constants are matched with an integer multiple of 2 corresponding to a 2×2 array of unit cells. For example, this may be achieved in the cubic Mg₂GeO₄ deposited on MgO substrate.

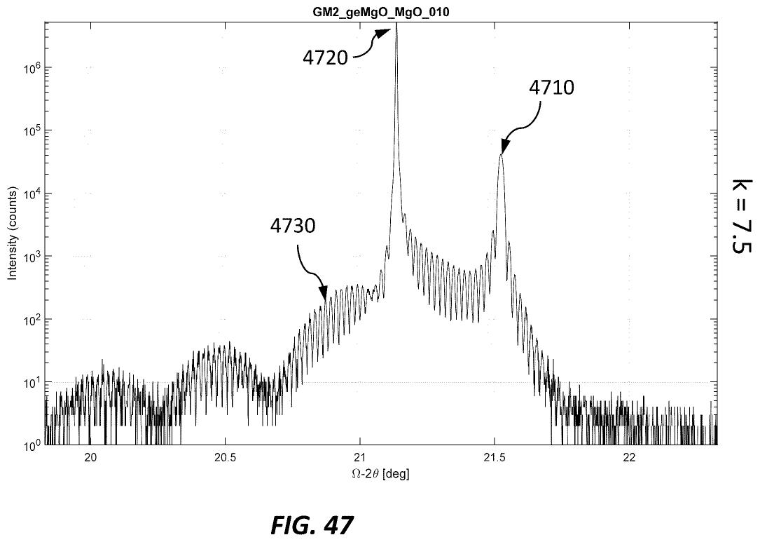

FIGS. 47-50 show X-ray diffraction (XRD) diagrams (intensity versus angle in an Ω-2θ scan) of example layered semiconductor structures for different flux values of k=Φ_{Ge}^{inc}/Φ_{Mg}^{inc}, demonstrating the effect of flux ratio of the impinging species on the resulting grown layers, in accordance with some aspects.

In FIG. 47, an experimentally determined triple axis XRD diagram is shown of the layered semiconductor structure illustrated in FIG. 46A. A 240 nm Mg₂GeO₄ (Fd3m) epitaxial layer was formed with incident Ge and Mg fluxes of Φ_{Ge}^{inc}/Φ_{Mg}^{inc}˜7.5 and a growth temperature of 425° C. A thin MgO cap (˜11 nm) was deposited on the surface to form an X-ray Fabry-Perot structure. In this example, the extremely narrow full-width half-max (FWHM) of the Mg₂GeO₄ peak 4710 compared to the MgO substrate peak 4720 clearly shows the high quality of the structure. Furthermore, the MgO cap layer further induces high frequency Pendellosung oscillations 4730 in the XRD curve indicative of a fully coherent structure, of extremely high quality, with low defect density. The MgO substrate, cubic Mg₂GeO₄ film and MgO cap were highly crystalline and plane parallel on an atomic scale with coherence throughout the structure thereby inducing an X-ray Fabry-Perot effect, as shown. The bulk Mg₂GeO₄(400) 4710 peak separation from the substrate MgO(200) peak 4720 is 1395.9 s.

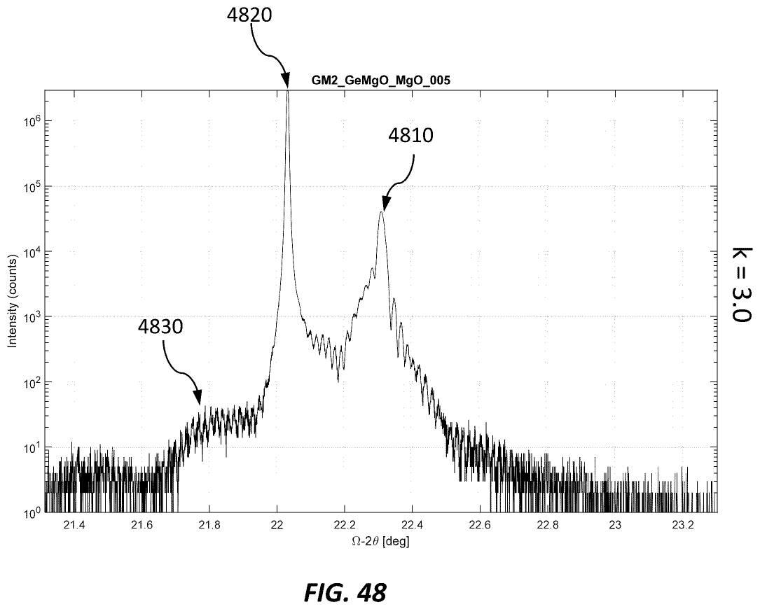

FIG. 48 shows an experimentally determined triple axis XRD diagram of the layered semiconductor structure illustrated in FIG. 46A where an approximately 254 nm thick Mg₂GeO₄ (Fd3m) layer was formed with incident Ge and Mg fluxes of Φ_{Ge}^{inc}/Φ_{Mg}^{inc}˜3 and a growth temperature of 425° C. A substrate of MgO (peak 4820) and an Mg₂GeO₄ peak 4810 show that a crystalline film of Mg₂GeO₄ was formed. A cap of MgO similar to FIG. 47 was also included in the structure, however, there are less high frequency fringes 4830 indicating that the crystal structure is less coherent than in FIG. 47.

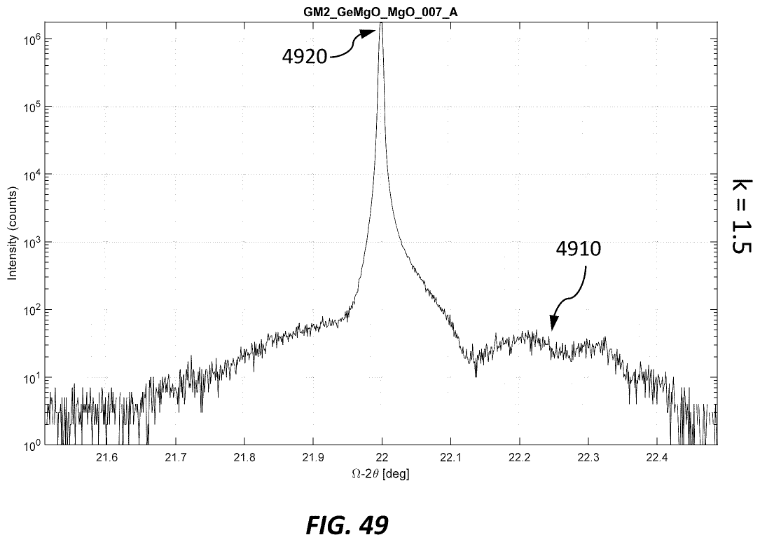

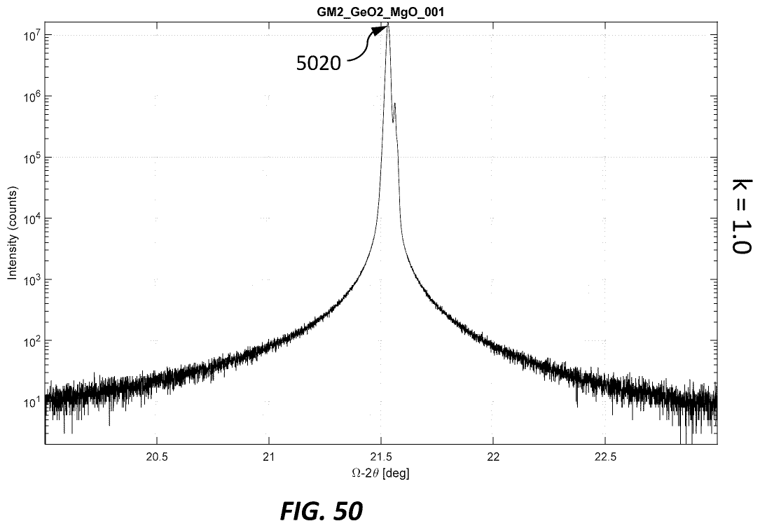

FIG. 49 shows an experimentally determined triple axis XRD diagram of the layered semiconductor structure illustrated in FIG. 46A where a Mg₂GeO₄ (Fd3m) layer was formed with incident Ge and Mg fluxes of Φ_{Ge}^{inc}/Φ_{Mg}^{inc}˜1.5 and a growth temperature of 425° C. As can be seen from the substrate peak 4920 and the Mg₂GeO₄ peak 4910, only minimal formation of a Mg₂GeO₄ (Fd3m) layer appeared.

FIG. 50 is an experimentally determined triple axis XRD diagram of the layered semiconductor structure illustrated in FIG. 46A where the incident Ge and Mg fluxes were Φ_{Ge}^{inc}/Φ_{Mg}^{inc}˜1.0 and the growth temperature was 425° C. As can be seen, there was no formation of a Mg₂GeO₄ (Fd3m) layer, with the layered semiconductor structure only comprising MgO (peak 5020). FIGS. 47-50 illustrate that higher relative amounts of Ge flux (k=Φ_{Ge}^{inc}/Φ_{Mg}^{inc}) in the molecular beam epitaxy process improved the quality of the epitaxial Mg₂GeO₄ (Fd3m) layer for the growth conditions used. A very high quality Mg₂GeO₄ (Fd3m) epitaxial layer on MgO was achieved, as demonstrated by FIG. 47.

### Multilayered Structures

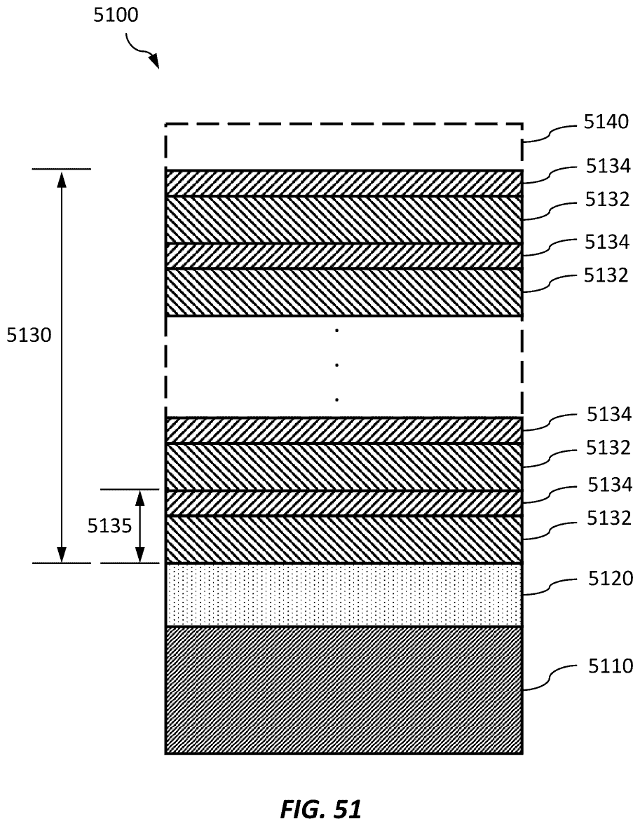

Epitaxial layers of magnesium-group IV oxides, such as Mgₐ(Siₓ(Ge_{y}Sn_{1-y})₁₋ₓ)O_{b} or MgₓGe_{y}O_{z}, as disclosed herein may be used in various semiconductor device structures, such as those including multilayered structures and chirp layers. Multilayered structures may be, for example, a superlattice (“SL”, which may include short-period superlattices), multiple superlattices, a compositionally varied (or graded) layer, or a compositionally varied (or graded) multilayer structure (or region). Aspects of multilayered structures shall be described by FIGS. 51-53. Although certain combinations of substrate materials, buffer layers and multilayered layers shall be described, other combinations are possible using the Mgₐ(Siₓ(Ge_{y}Sn_{1-y})₁₋ₓ)O_{b} and MgₓGe_{y}O_{z} materials and compatible substrates as described throughout this disclosure.

Aspects include semiconductor structures and devices having a superlattice, the superlattice comprising a unit cell having a first layer, where the epitaxial layer of Mgₐ(Siₓ(Ge_{y}Sn_{1-y})₁₋ₓ)O_{b} or MgₓGe₁₋ₓO₂₋ₓ is the first layer in the superlattice. In some aspects, the unit cell of the superlattice further comprises a second layer of Mgₐ(Siₓ(Ge_{y}Sn_{1-y})₁₋ₓ)O_{b} wherein 1.5≤a≤2.5, 3≤b≤5, 0≤x≤1, and 0≤y≤1, or Mg_{y}Ge_{1-y}O_{2-y}, wherein y ranges from 0 to 1 and x y. For example, the first layer may be MgO having a Fm3m space group, where in some aspects, the unit cell of the superlattice further comprises a second layer, the second layer made of Mg₂GeO₄ that has a Fd3m space group. In some aspects, the unit cell of the superlattice further comprises a second layer of MgGa₂O₄ or gamma-Ga₂O₃.

In some aspects, superlattices may comprise unit cells having bi-layers, tri-layers, or other numbers of sub-layers, where one or more of the sub-layers may be made of Mgₐ(Siₓ(Ge_{y}Sn_{1-y})₁₋ₓ)O_{b} wherein 1.5≤a≤2.5, 3≤b≤5, 0≤x≤1, and 0≤y≤1, or Mg_{y}Ge_{1-y}O_{2-y}, wherein y ranges from 0 to 1 and x≠y. In some examples, the sub-layers of a superlattice in a semiconductor device may comprise Mg₂SiO₄, Mg₂GeO₄ and/or Mg₂SnO₄.

FIG. 51 shows a sectional view of an epitaxially formed layered semiconductor structure 5100 comprising a substrate 5110, an optional buffer layer 5120, a superlattice or multilayered periodic structure 5130, and an optional cap 5140. The periodic structure 5130 (e.g., superlattice) comprises repeated unit cells 5135 consisting of two layers 5132 and 5134 in this example. The figure shows layer 5132 being thicker than layer 5134; however, in other aspects, layer 5132 may be thinner than layer 5134 or the layers 5132 and 5134 may be equal in thickness. In an example aspect, the layered semiconductor structure 5100 comprises a MgO(100)-oriented substrate 5110, superlattice (periodic structure 5130) comprising a unit cell 5135 of MgGeO and MgO having a definite period, and a final cap 5140 of MgO. Substrate 5110 may be prepared for deposition using an oxygen plasma source to terminate the MgO surface with oxygen specie.

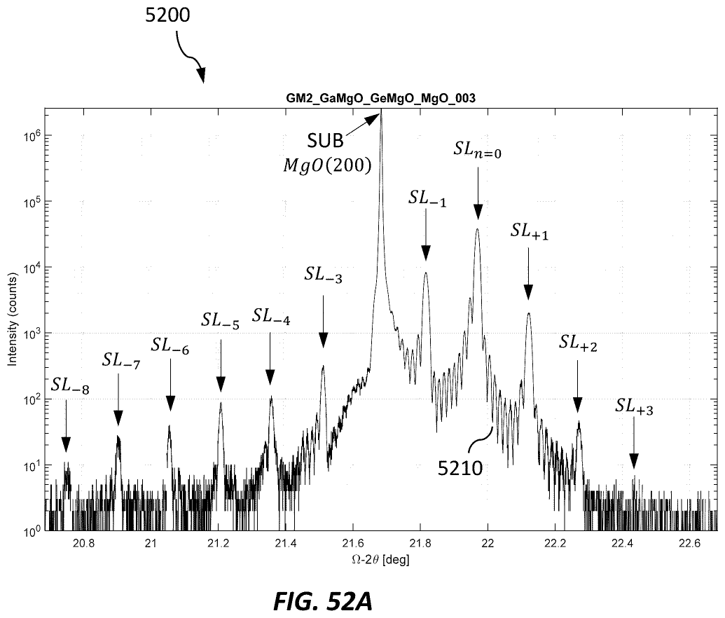

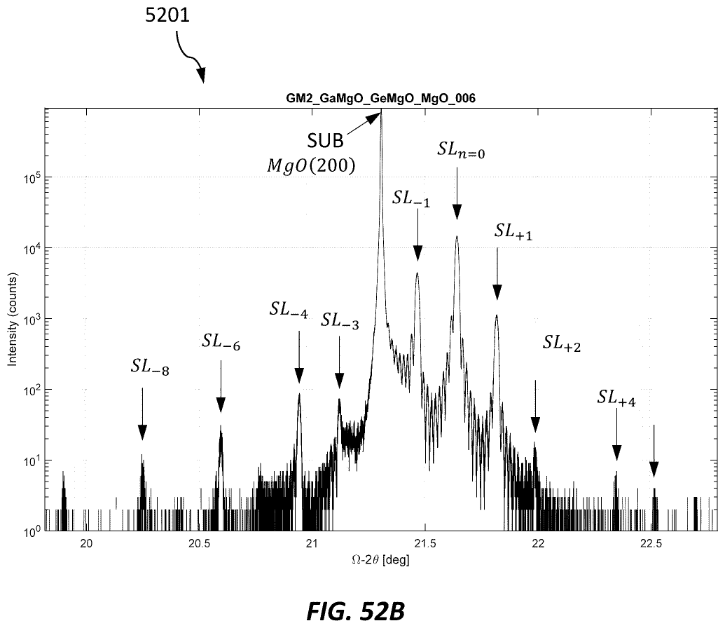

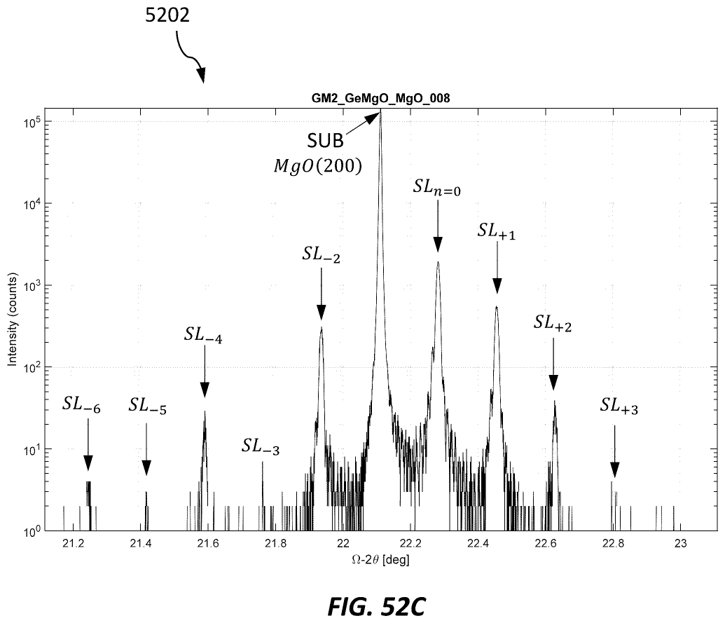

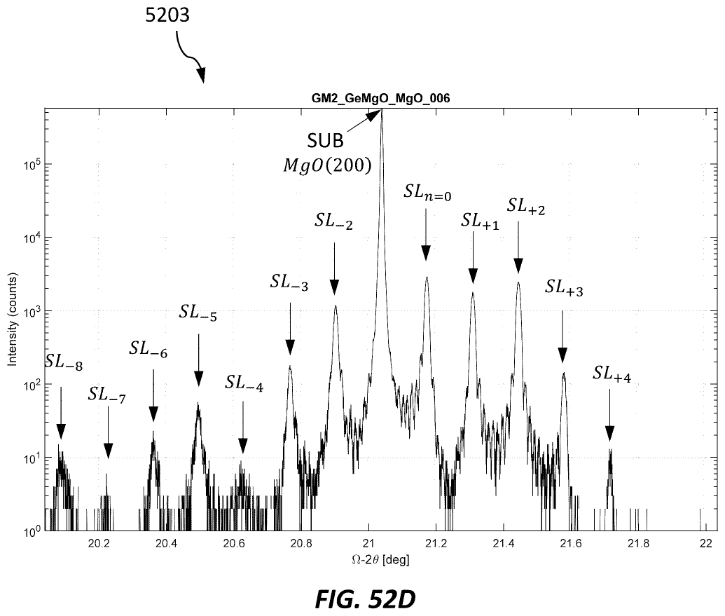

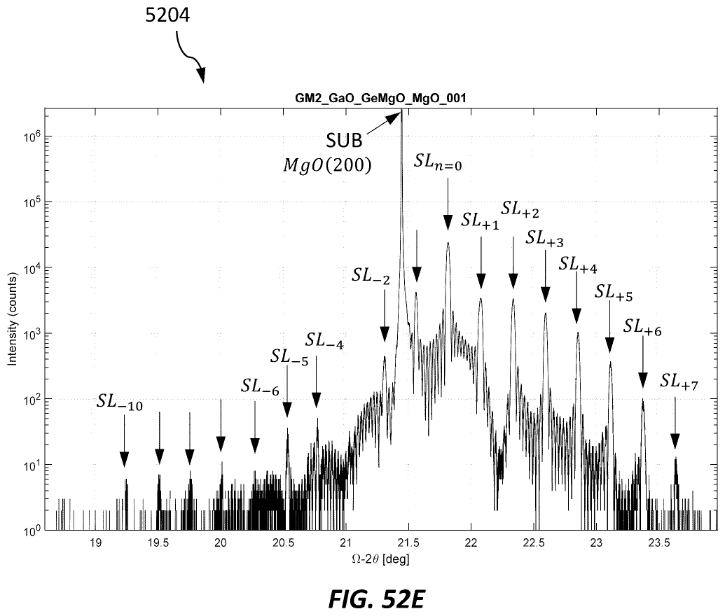

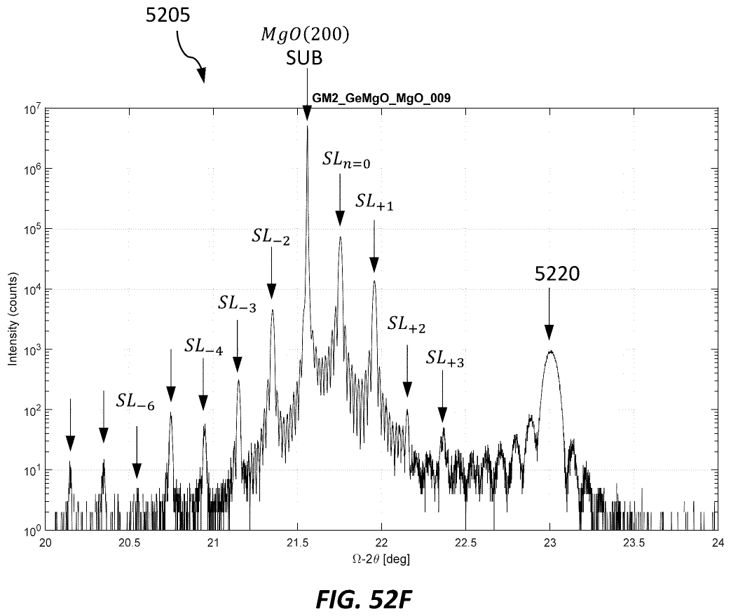

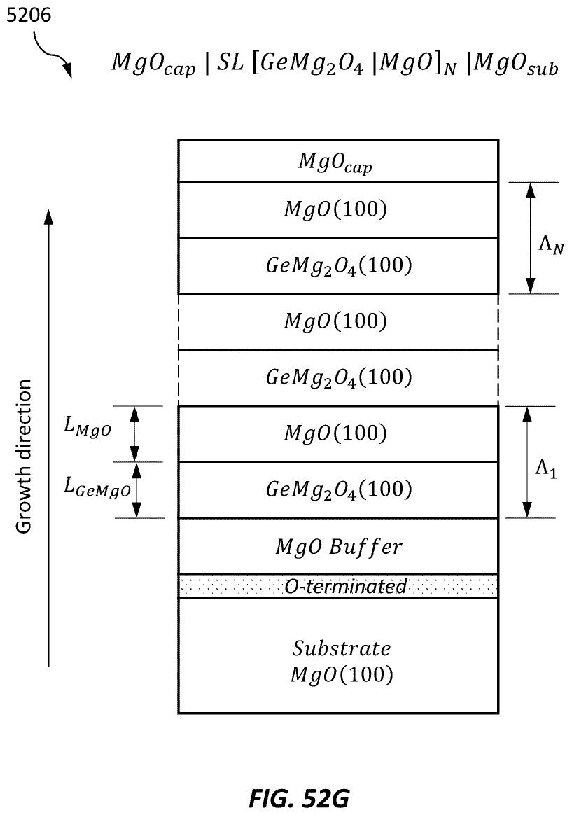

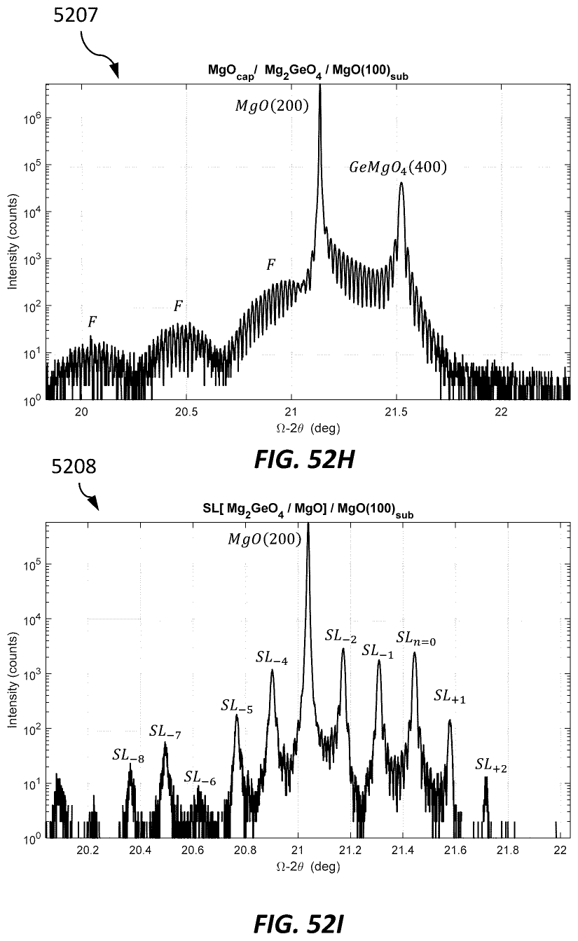

FIGS. 52A-52F show experimentally determined XRD diagrams for aspects of the semiconductor structure illustrated in FIG. 51, where the structures included superlattices. In FIGS. 52A-52F, the peak representing the substrate is marked as “SUB.” The additional arrows point to “satellite peaks,” which are features of the XRD pattern caused by the periodic SL structure. FIGS. 52H-52I show experimentally determined XRD diagrams for aspects of the semiconductor structure illustrated in FIG. 52G.

FIG. 52A is an experimentally determined XRD diagram 5200 of the layered semiconductor structure illustrated in FIG. 51 for a superlattice 5130 where layer 5132 was a Fd3m MgGa₂O₄ and layer 5134 was Mg₂GeO₄ (Fd3m). The Mg₂GeO₄ (Fd3m) layer was formed with incident Ge and Mg fluxes of Φ_{Ge}^{inc}/Φ_{Mg}^{inc}˜7 deposited upon a MgO buffer layer 5120 which was deposited on a MgO(100) substrate 5110. As can be seen, the high frequency fringes (one example labeled as fringes 5210) indicate an extremely high crystal quality, implying excellent matching between the in-plane lattice constants of the MgGa₂O₄ and Mg₂GeO₄ (Fd3m) layers forming the superlattice. The sharp satellite peaks (marked by arrows SLₙ) persist to higher orders without broadening and are indicative of a coherently grown structure of high structural quality. The SL period is 26 nm and the MgO(200) substrate separation from the SLₙ₌₀ peak is 1024.8 s.

FIG. 52B shows an experimentally determined XRD diagram 5201 of the layered semiconductor structure illustrated in FIG. 51 for a superlattice 5130 where layer 5132 was Mg₂GeO₄ (Fd3m) and layer 5134 was MgGa₂O₄ (Fd3m). The superlattice was deposited upon a MgO buffer layer 5120 and a MgO(100) substrate 5110. The sharp satellite peaks (SLₙ) are again indicative of a coherently grown structure of high structural quality. FIG. 52B demonstrates a superlattice having a unit cell in which the first layer of the unit cell is Mg₂GeO₄ having a Fd3m space group, and a second layer of the unit cell is MgGa₂O₄ having a Fd3m space group. The SL period is 27.2 nm with 10 periods, and the MgO(200) substrate separation from the SLₙ₌₀ peak is 1206.7 s indicating a thicker MgGe₂O₄ layer compared to FIG. 52A.

FIG. 52C is an experimentally determined XRD diagram 5202 of the layered semiconductor structure illustrated in FIG. 51 for a superlattice 5130 where layer 5132 was Mg₂GeO₄ (Fd3m) and layer 5134 was MgO (Fm3m). The superlattice was deposited upon a MgO buffer layer 5120 and a MgO(100) substrate 5110. The sharp satellite peaks (SLₙ) are indicative of a coherently grown structure of high structural quality. FIG. 52C demonstrates a superlattice having a unit cell in which the first layer of the unit cell is MgO having a Fm3m space group, and a second layer of the unit cell is made of Mg₂GeO₄ that has a Fd3m space group. This result demonstrates that Mg₂GeO₄ can be formed on MgO and also MgO can be formed on Mg₂GeO₄. The SL period is 26.6 nm and has N=10 periods with N-2 thickness oscillations between the satellite peaks. The SLₙ₌₀ separation to the MgO(200) substrate is 614.2 s indicating the SL effective alloy of (MgO)ₓ(GeMg₂O₄)₁₋ₓ is

$$x = \frac{614.2}{1395.5} = 0.44 .$$

FIG. 52D shows an experimentally determined XRD diagram 5203 of the layered semiconductor structure illustrated in FIG. 51 for a superlattice 5130 where layer 5132 was Mg₂GeO₄ (Fd3m) and layer 5134 was MgO (Fm3m). The layers of the structure represented in FIG. 52D were thicker than in FIG. 52C, as evidenced by there being more satellite peaks (SLₙ) in FIG. 52D than in FIG. 52C. The superlattice was deposited upon a MgO buffer layer 5120 and a MgO(100) substrate 5110. The sharp satellite peaks are indicative of a coherently grown structure of high structural quality. The SL period is 35.6 nm and grown with 10 periods.

FIG. 52E is an experimentally determined XRD diagram 5204 of the layered semiconductor structure illustrated in FIG. 51 for a superlattice 5130 where layer 5132 was Mg₂GeO₄ (Fd3m) and layer 5134 was stabilized cubic gamma-Ga₂O₃. The superlattice was deposited upon a MgO buffer layer 5120 and a MgO(100) substrate 5110. The sharp satellite peaks (SLₙ) are indicative of a coherently grown structure of high structural quality. The superlattice period is 18.4 nm and has 10 periods. The MgO(200) substrate separation from the SLₙ₌₀ peak is 1337.6 s indicating an effective digital alloy comprising (γGa₂O₃)ₓ(GeMg₂O₄)₁₋ₓ=Ga₂ₓGe₁₋ₓMg₂₍₁₋ₓ₎O₄₋ₓ. The cubic γGa₂O₃ layers are stabilized by intentionally growing the layers below the critical layer thickness (CLT) wherein it becomes energetically favorable to form βGa₂O₃ unless stabilized with another species.

FIG. 52F is an experimentally determined XRD diagram 5205 of the layered semiconductor structure illustrated in FIG. 51 for a superlattice 5130 where layer 5132 was Mg₂GeO₄ (Fd3m) and layer 5134 was MgO. After the deposition of a 10× period SL [MgO/Mg₂GeO₄], a thick beta-Ga₂O₃ cap layer was formed with thickness exceeding the CLT (note: below the CLT a stabilized gamma-Ga₂O₃ can be formed). The superlattice was deposited upon a MgO buffer layer 5120 and a MgO(100) substrate 5110. In this example, a thick beta-phase Ga₂O₃ film 5220 was grown as the cap layer 5140 showing highly coherent structure. The sharp satellite peaks (SLₙ) are indicative of a coherently grown structure of high structural quality. The SL acts as a pseudo-substrate for the formation of high-quality beta-Ga₂O₃(100) oriented films with biaxial strain suitable for tuning of the valence band edge. FIG. 52F demonstrates a superlattice having a unit cell in which the first layer of the unit cell is Mg₂GeO₄ having a Fd3m space group, and a second layer of the unit cell is MgO having a cubic symmetry, and a further thick epitaxial beta-phase Ga₂O₃ is grown on the SL acting as a pseudosubstrate.

FIG. 52G shows a complex epilayer structure 5206 of dissimilar cubic oxide layers integrated into a superlattice or multi-heterojunction structure in a further example. Shown are large lattice constant cubic GeMg₂O₄ (i.e., Mg₂GeO₄) and small lattice constant MgO layers forming a superlattice having a repeating period A with N repetitions, grown along a growth direction. A MgO(100)-oriented substrate enables the lattice “2×” cube-on-cube matching to GeMg₂O₄. The direct bandgap E-k of both materials enables unique electronic band structure tuning using quantized energy levels pre-selected from specific layer thicknesses comprising the SL period. If the layers thicknesses “L” comprising the SL are thin, such that each of L_{GeMgO} and L_{Mg}o are less than approximately 10-20× their respective unit cells in thickness (i.e., layer thicknesses less than about 150 nm), then a digital pseudo-alloy can be formed having an effective composition (MgO)ₓ(GeMg₂O₄)₁₋ₓ≡Ge₁₋ₓMg₂₋ₓO₄₋₃ₓ where 0<(x=L_{MgO}/λ)≤1. An optional MgO cap layer is shown that can be used to protect the final surface of the structure.

FIG. 52H shows the experimental XRD data 5207 of a Fd3m crystal structure Mg₂GeO₄ deposited as a high quality bulk layer on a Fm3m MgO(100) substrate and further comprising a MgO cap.

FIG. 52I shows the experimental XRD data 5208 of a Fd3m crystal structure Mg₂GeO₄ when incorporated as a SL structure comprising 20× period SL[Mg₂GeO₄/MgO] on a Fm3m MgO(100) substrate.

As shown in FIG. 52H, the extraordinarily high quality Mg₂GeO₄ is evidenced by the small FWHM epilayer (labelled “GeMgO₄ 400”) diffraction peak and the high frequency thickness oscillations generated by the X-ray Fabry-Perot effect of the parallel atomic planes of the film and MgO cap layer, which are strained and coherent with the underlying substrate crystal. As shown in FIG. 52I, this high degree of lattice matching between Mg₂GeO₄ and MgO can be further utilized to form complex SL structures. FIG. 52I shows such a SL comprising 20× period SL[Mg₂GeO₄/MgO]/MgO_{sub}(100). Again, the large number of sharp SL satellite peaks SLₙ is evidence of a coherently strained structure. Both Mg₂GeO₄ and MgO constituent materials are direct bandgap with E₉(Mg₂GeO₄)<E_{g}(MgO).

For a thin layer of smaller bandgap material ˜1-5 crystal unit cells in thickness, the conduction band minimum and valence band maximum can be quantum confined when sandwiched between a larger bandgap material such as MgO. The transition energy between the lowest quantized energy level in the conduction band and the highest quantized energy level in the valence band of Mg₂GeO₄ can be tuned by varying the thickness via the quantum confined effect. This tuning method enables a transition energy to vary from about 5.81 eV to 7.69 eV. This energy range is ideal for optoelectronic emissive devices operating in the deep ultraviolet (161-213 nm) portion of the electromagnetic spectrum.

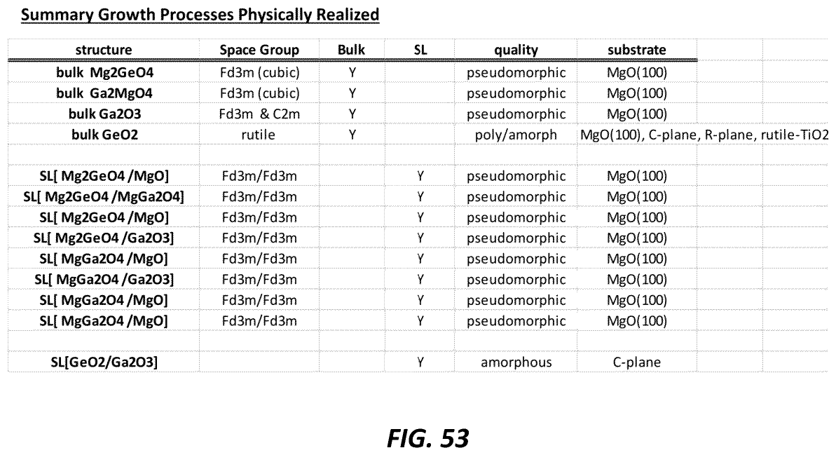

FIG. 53 is a summary table of properties of example structures comprising MgₓGe_{y}O_{z} epilayers that were physically realized, in accordance with aspects of the present disclosure. The table lists the epilayer structures built, the space group of the structures, whether the structure layers were bulk or superlattice, the quality, and the substrate material. As is demonstrated by these examples, the compatibility of MgGa₂O₄, Mg₂GeO₄, MgO, beta-Ga₂O₃ and gamma-Ga₂O₃ is advantageous for bandgap energy designs for electronic and optoelectronics devices.

### Conduction Devices

Semiconductor structures, such as conduction devices, comprising the Mgₐ(Siₓ(Ge_{y}Sn_{1-y})₁₋ₓ)O_{b} and MgₓGe_{y}O_{z} epitaxial oxide materials and compatible substrates disclosed herein shall be described. A semiconductor structure comprising epitaxial oxide materials described herein can be a single layer on a substrate or multiple layers on a substrate. Such a semiconductor structure with multiple layers can include a single quantum well, multiple quantum wells, a superlattice, multiple superlattices, a compositionally varied (or graded) layer, a compositionally varied (or graded) multilayer structure (or region), a doped layer (or region), and/or multiple doped layers (or regions). Such semiconductor structures with one or more doped layers (or regions) can include layers (or regions) that are doped p-n, p-i-n, n-i-n, p-i-p, n-p-n, p-n-p, p-metal (to form a Schottky junction), and/or n-metal (to form a Schottky junction).

In some aspects, semiconductor devices include a substrate comprising a substantially single crystal substrate material; and an active region on the substrate, the active region comprising an epitaxial layer of MgₓGe₁₋ₓO₂₋ₓ, with x having a value of 0≤x<1. The epitaxial layer of MgₓGe₁₋ₓO₂₋ₓ has a crystal symmetry compatible with the substrate material. In some aspects, the semiconductor device is an optoelectronic device comprising a light emitting diode or a photodetector. For example, the optoelectronic device emits or absorbs light having a wavelength in a range from 150 nm to 280 nm, such as from 150 nm to 260 nm, or less than approximately 260 nm, or less than approximately 250 nm, or less than approximately 220 nm. In some aspects, the semiconductor device is an electronic device comprising a diode or a transistor. In some aspects, the epitaxial layer of MgₓGe₁₋ₓO₂₋ₓ is an intrinsic layer of the semiconductor device. In some aspects, the epitaxial layer of MgₓGe₁₋ₓ O₂₋ₓ is a doped layer comprising n-type or p-type conductivity, being doped by methods as disclosed herein.

Examples include a semiconductor structure comprising an epitaxial layer comprising single crystal Mgₐ(Siₓ(Ge_{y}Sn_{1-y})₁₋ₓ)O_{b}, wherein 1.5≤a<2.5, 3≤b≤5, 0≤x≤1, and 0≤y≤1; and a substrate or an underlying layer on which the single crystal Mgₐ(Siₓ(Ge_{y}Sn_{1-y})₁₋ₓ)O_{b} is grown; wherein the single crystal Mgₐ(Siₓ(Ge_{y}Sn_{1-y})₁₋ₓ)O_{b} has a crystal symmetry compatible with the substrate or the underlying layer. For any of the semiconductor structures and conduction devices described herein, the Mgₐ(Siₓ(Ge_{y}Sn_{1-y})₁₋ₓ)O_{b} materials described herein, wherein 1.5≤a≤2.5, 3≤b≤5, 0≤x≤1, and 0≤y≤1 (e.g., as described in FIGS. 72A-80, may be used as epitaxial oxide materials for semiconductor layers. The semiconductor layers may be, for example, an active region, a transition layer, an intermediate layer, or other layer, and can be doped or non-doped.

In some examples of semiconductor structures, the substrate or the underlying layer comprises a substantially single crystal substrate material. In some examples of semiconductor structures, the substrate is made of Si, AlLaO₃, MgF₂, MgO, MgGa₂O₄, MgAl₂O₄, LiF, β-Ga₂O₃, LiAlO₂, ZrO₂, LiNbO₃, LiTaO₃, Fe₂O₃, BN, LiGaO₂, TiO₂, AlN, SiC, BaF₂, BN, CdWO₄, SiC, or miscut SiC. In some examples of semiconductor structures, the single crystal Mgₐ(Siₓ(Ge_{y}Sn_{1-y})₁₋ₓ)O_{b} is strained and is lattice mismatched to the substrate or the underlying layer. In some examples of semiconductor structures, the single crystal Mgₐ(Siₓ(Ge_{y}Sn_{1-y})₁₋ₓ)O_{b} comprises a lattice mismatch of less than or equal to 10% with the substrate or the underlying layer. In some examples, an optoelectronic device comprises the semiconductor structure having an epitaxial layer comprising single crystal Mgₐ(Siₓ(Ge_{y}Sn_{1-y})O_{b}, wherein the optoelectronic device comprises a light emitting diode or a photodetector. In some examples, an electronic device comprises the semiconductor structure having an epitaxial layer comprising single crystal Mgₐ(Siₓ(Ge_{y}Sn_{1-y})₁₋ₓ)O_{b}, wherein the semiconductor structure comprises a diode or a transistor. In some examples of semiconductor structures, the epitaxial layer comprising the single crystal Mgₐ(Siₓ(Ge_{y}Sn_{1-y})₁₋ₓ)O_{b} is in an active region of the semiconductor structure. In some examples of semiconductor structures, the epitaxial layer comprising the single crystal Mgₐ(Siₓ(Ge_{y}Sn_{1-y})₁₋ₓ)O_{b} is a doped layer having n-type or p-type conductivity. In some examples the semiconductor structures disclosed herein further comprise a second epitaxial layer forming a heterostructure with the single crystal Mgₐ(Siₓ(Ge_{y}Sn_{1-y})₁₋ₓ)O_{b}.

The devices having the semiconductor structures comprising the magnesium-group IV oxide materials described herein, such as Mgₐ(Siₓ(Ge_{y}Sn_{1-y})₁₋ₓ)O_{b} or magnesium germanium oxide materials, can include electronic and optoelectronic devices. For example, the devices described herein can be resistors, capacitors, inductors, diodes (e.g., unipolar diodes), transistors (switches, e.g., field effect transistors, RF power switches, bipolar heterojunction transistors), vertical conduction devices, amplifiers, sensors, photodetectors, LEDs, lasers, optical modulators. In some aspects, the devices comprising the semiconductor structures comprising the magnesium germanium oxide materials described herein are optoelectronic devices (i.e., light emitters or light detectors), such as photodetectors, LEDs and lasers, that detect or emit UV light (e.g., with a wavelength from 150 nm to 280 nm). In some cases, the device comprises an active region wherein the detection or emission of light occurs, and the active region comprises a magnesium germanium oxide material with a bandgap selected to detect or emit UV light (e.g., with a wavelength from 150 nm to 280 nm).

Doped layers in the conduction devices may comprise a donor (n-type), or acceptor (p-type) impurity (or dopant) material. The impurities can act as extrinsic dopants providing the doped layer with an n-type or p-type conductivity. For example, a doped layer can be formed by co-depositing (e.g., using molecular beam epitaxy or chemical vapor deposition) an epitaxial oxide semiconductor with a high concentration (e.g., doping concentrations of about 1e17 cm⁻³ to about 1e20 cm³, or greater than about 1e20 cm⁻³) of an impurity (or dopant) that can act as a donor (n-type), or acceptor (p-type) material. Doping can be achieved by various doping strategies disclosed herein, such as described in relation to FIGS. 18A-42B.

Referring now to FIG. 54A, there is shown an epitaxial multiple layer structure 5400 for forming an electronic or optoelectronic device, comprising a substrate 5410, optional buffer layer 5420, a first conductivity type layer 5430, a second conductivity type region 5440, a third conductivity type region 5450 and an electrical contact layer 5460. The structure 5400 is formed sequentially layer-by-layer along a growth direction Z. The first, second and third conductivity types may be selected from p-, i-, and n-types, and may be used in various combinations such as p-n, n-p, p-i-n, n-i-n, p-i-p, n-p-n, or p-n-p. Bulk layers or superlattices of the MgₓGe_{y}O_{z} or Mg, (Siₓ(Ge_{y}Sn_{1-y})₁₋ₓ)O_{b} epitaxial oxide materials disclosed herein may be used for the layers 5420, 5430, 5440, 5450 and/or 5460.

FIG. 54B shows possible electrical conductivity types for MgₐGe_{b}O_{c} that may be used in the semiconductor structure 5400. A process for creating the conductivity is schematically drawn, illustrating MgₐGe_{b}O_{c} 5490 plus doping 5492 resulting in conductivity type 5494. In one example, MgₐGe_{b}O_{c} may be Mg₂GeO₄ (a=2, b=0, c=4). The conductivity types of FIG. 54B may use co-doping or crystal growth modification during epitaxial layer formation. The doped layer can be formed in any of the regions described in FIG. 54A. In some aspects, the electrically activated doped or conductivity type regions can have an atomically abrupt interface with the other dissimilar regions, or the regions may be graded over a predetermined distance.

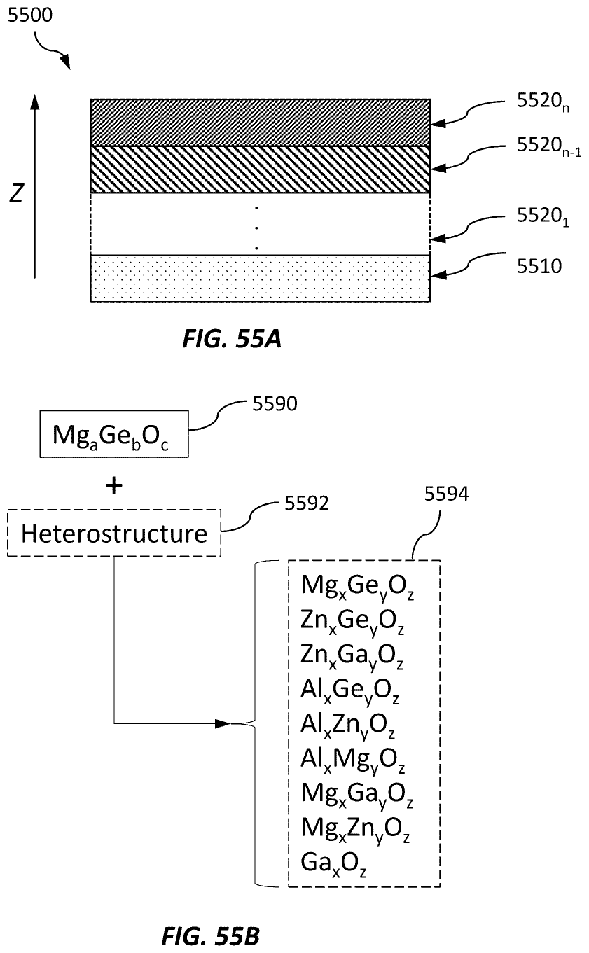

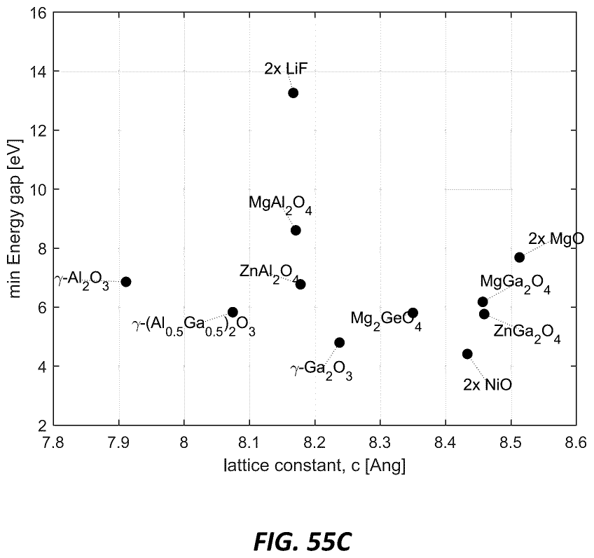

FIG. 55A shows a multilayer structure 5500 used to form an electronic device having distinct regions comprising at least one layer of MgₐGe_{b}O_{c} or Mgₐ(Siₓ(Ge_{y}Sn_{1-y})₁₋ₓ)O_{b}. A substrate 5510 has epitaxial layers 5520ₙ (e.g., films or regions) deposited along a growth direction Z. The layers 5520ₙ comprising the device are selected from at least one Mg₂GeO₄ or Mgₐ(Siₓ(Ge_{y}Sn_{1-y})₁₋ₓ)O_{b} form and may be integrated with, for example, compositions of the type selected from: ZnₓGe_{y}O_{z}, ZnₓGa_{y}O_{z}, AlₓGe_{y}O_{z}, AlₓZn_{y}O_{z}, AlₓMg_{y}O_{z}, MgₓGa_{y}O_{z}, MgₓZn_{y}O_{z}, and GaₓO_{z}, where x, y, z represent relative mole fractions.

FIG. 55B is a figurative diagram showing example compositions that may be combined with MgₐGe_{b}O_{c} to form a heterostructure. The combination is schematically drawn, illustrating MgₐGe_{b}O_{c} 5590 plus a heterostructure material 5592 where in this example the heterostructure material compositions 5594 comprise MgₓGe_{y}O_{z}, ZnₓGe_{y}O_{z}, ZnₓGa_{y}O_{z}, AlₓGe_{y}O_{z}, AlₓZn_{y}O_{z}, AlₓMg_{y}O_{z}, MgₓGa_{y}O_{z}, MgₓZn_{y}O_{z} and GaₓO_{z}. FIG. 55C is a plot of minimum energy gap (eV) versus lattice constant (c, in Angstroms) for Mg₂GeO₄ and other materials that may be used in heterostructures for semiconductor structures of the present disclosure. The plot may be used to determine compatible crystal structure lattice matching for materials combinations. Aspects include semiconductor structures and devices (and methods for making the structures and devices) in which an epitaxial layer of MgₓGe₁₋ₓO₂₋ₓ is on a substrate, with x having a value of 0≤x<1, and a second epitaxial layer forms a heterostructure with the epitaxial layer of MgₓGe₁₋ₓO₂₋ₓ. The second epitaxial layer may comprise ZnₓGe_{y}O_{z}, ZnₓGa_{y}O_{z}, AlₓGe_{y}O_{z}, AlₓZn_{y}O_{z}, AlₓMg_{y}O_{z}, MgₓGa_{y}O_{z}, MgₓZn_{y}O_{z}, or GaₓO_{z}, where x, y and z are mole fractions.

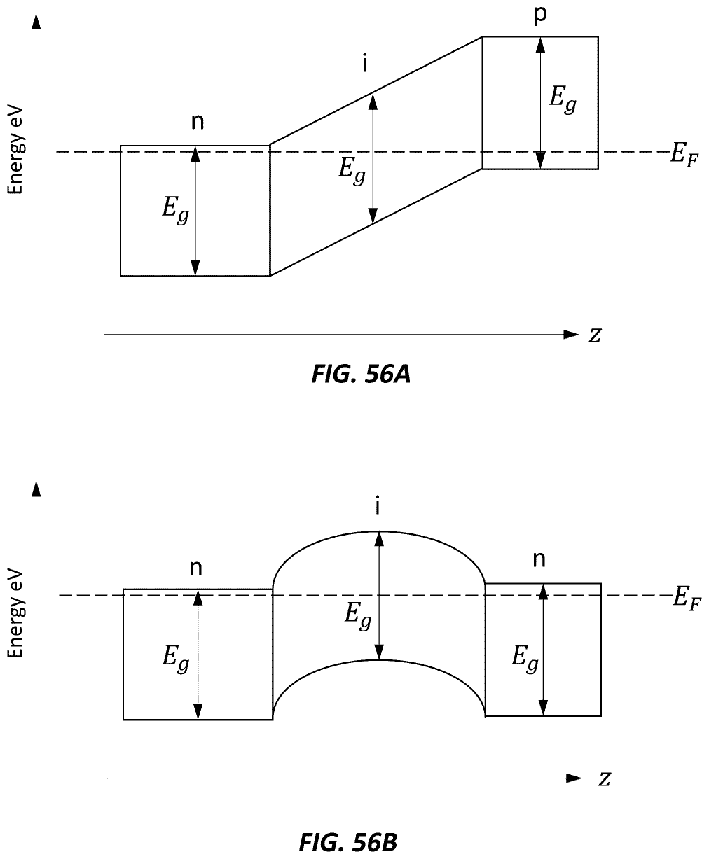

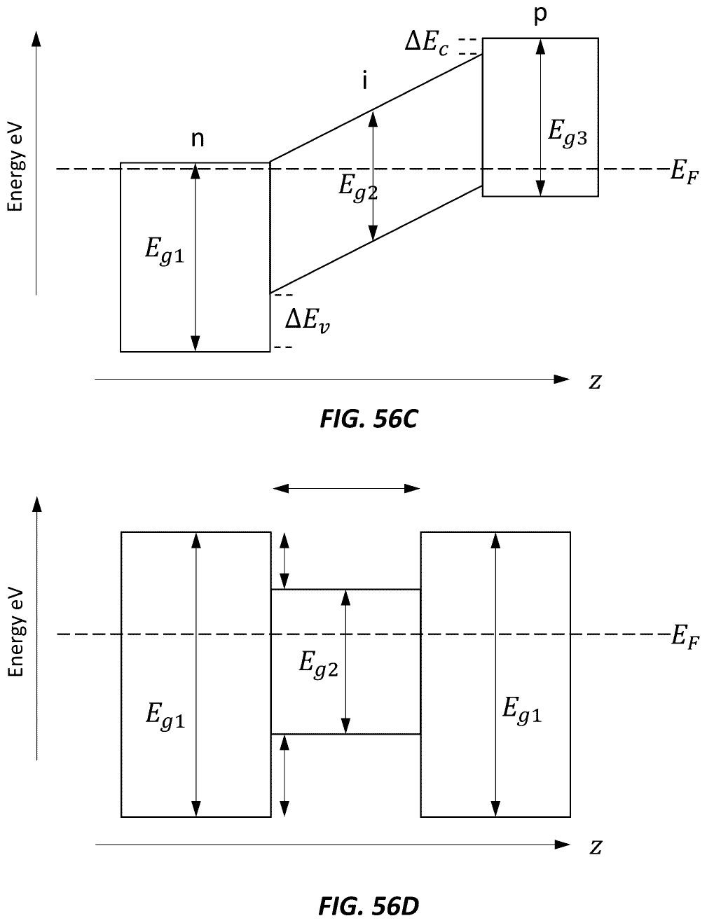

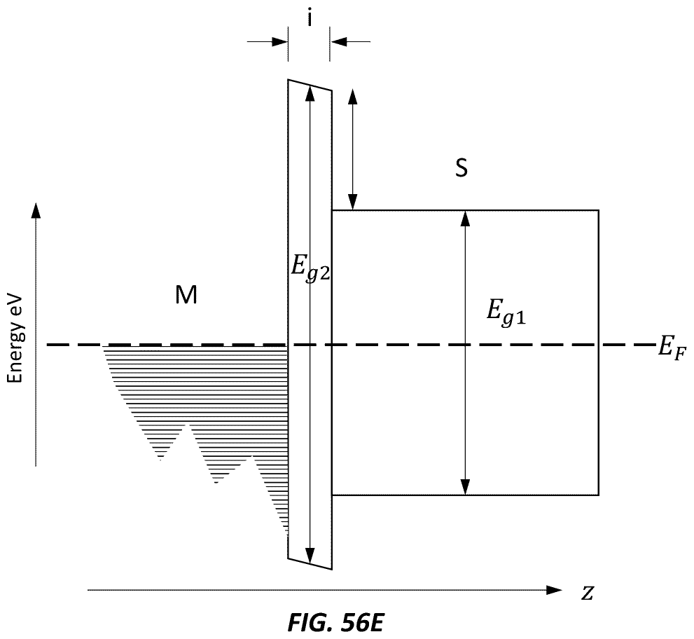

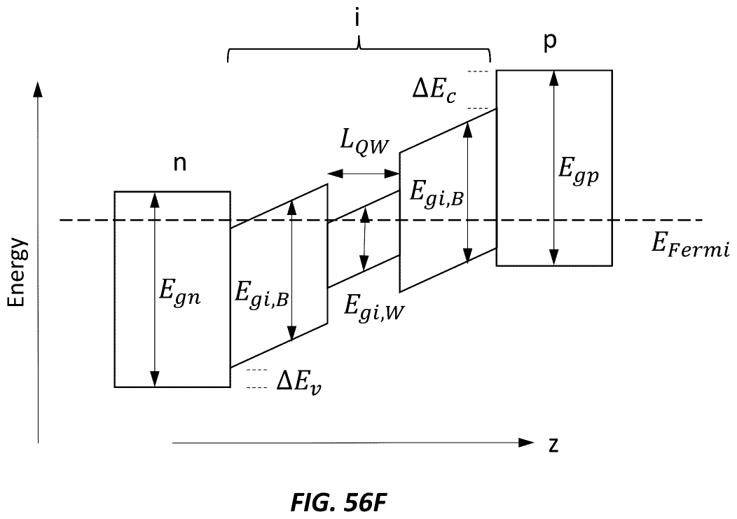

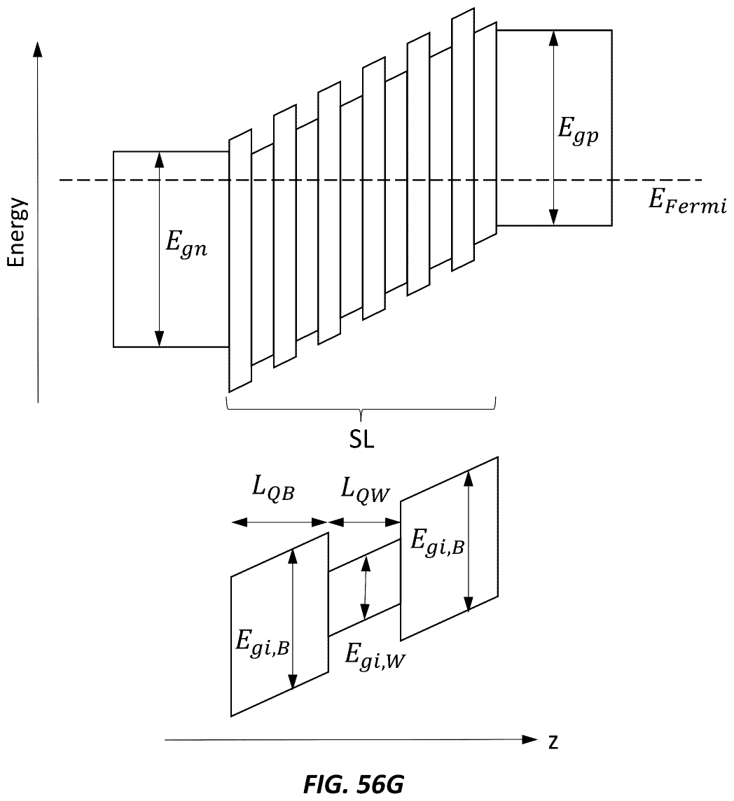

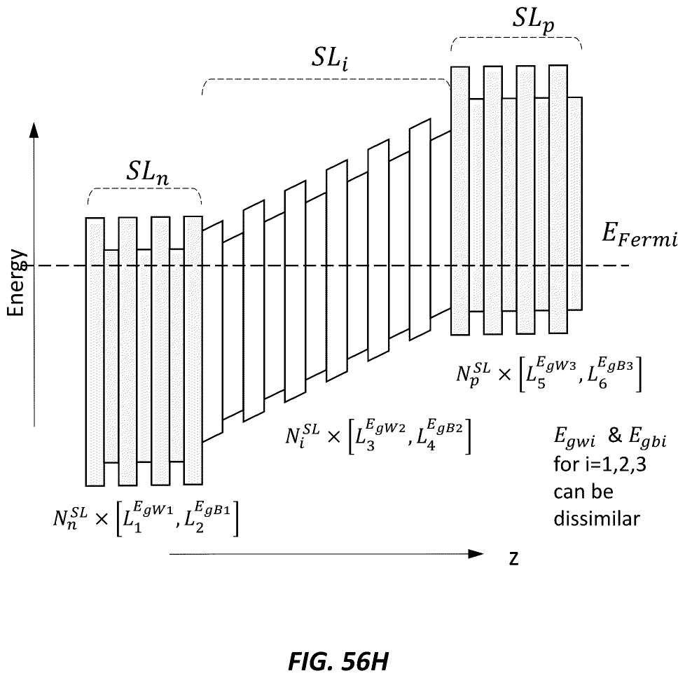

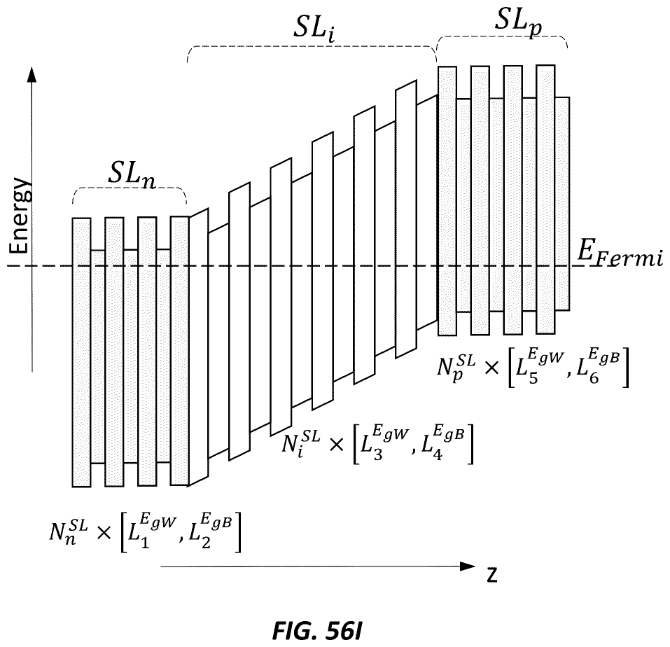

FIG. 56A is a band structure diagram of bandgap energy (eV) as a function of growth direction Z, representing a homojunction device comprising a p-i-n structure. The structure is formed along a growth direction Z, using spatial control of the doping regions. Moving from left to right along the growth direction, first an n-type region is formed, followed by a not-intentionally doped region (intrinsic “i” region), and then a p-type region. In various aspects, the doping transition between the n-, i-, and p-regions may be abrupt or graded over a distance. The height of the bandgaps for each region is the same, showing that the bandgap energies E_{g} for the n-, i-, and p-regions are equal. The p- and n-regions form a diode. An electric field between the p- and n-regions is applied across the central intrinsic region along the Z-axis, causing electrons and holes to be injected into the i-region. In aspects, a device having the structure of FIG. 56A may comprise MgₓGe_{y}O_{z} or Mgₐ(Siₓ(Ge_{y}Sn_{1-y})O_{b}, such as Mg₂GeO₄, Mg₂SiO₄ or Mg₂SnO₄ for one or more of the p-i-n layers.

FIG. 56B is a band structure diagram representing a homojunction device, such as a diode, with an n-i-n structure. The n-i-n structure is formed along a growth direction Z, using spatial control of the doping regions. In various examples, the n-i local junctions can be abrupt or graded in doping concentration across a predetermined distance. In aspects, a device having the structure of FIG. 56B may comprise MgₓGe_{y}O_{z} or Mgₐ(Siₓ(Ge_{y}Sn_{1-y})O_{b}, such as Mg₂GeO₄, Mg₂SiO₄ or Mg₂SnO₄ for one or more of the n-i-n layers.

FIG. 56C is a band structure diagram representing a heterojunction device, such as a diode, with a p-i-n structure. The structure is sequentially formed along the growth direction Z, using spatial control of the composition and doping of the distinct regions. In various aspects, the composition and doping can be abrupt or graded across a predetermined distance. The bandgap energies E_{g} of the p- and n-regions do not have to be the same, where in this example the bandgap of the n-region is larger than that of the p-region. Heterojunction conduction band offset ΔE_{c} and valence band offset ΔEᵥ provide energy barriers for controlling carrier flow/confinement. The p-i-n-structure forms a diode, and the built-in electric field applies an electric field along the direction Z across the i-region, as shown. The heterojunction structure is useful for light emitting devices, as light generated from the center region will not be absorbed by the p- and n-regions and therefore will escape. In other words, heterojunction structure in FIG. 56C can advantageously be used as a light emitting device (e.g., an LED) because the wider bandgap n- and p-regions have low absorption coefficients of light emitted from the narrower bandgap i-layer. In aspects, a device having the structure of FIG. 56C may comprise MgₓGe_{y}O_{z} or Mgₐ(Siₓ(Ge_{y}Sn_{1-y})₁₋ₓ)O_{b}, such as Mg₂GeO₄, Mg₂SiO₄ or Mg₂SnO₄ for one or more of the layers.

FIG. 56D is band structure diagram representing a double heterojunction device, such as a quantum well. The structure is sequentially formed along a growth direction Z, using spatial control of the composition. The structure comprises a wide bandgap E_{g1} layer composition and a narrow bandgap region/layer E_{g2}, such that E_{g2}<E_{g1}. The narrow bandgap region is between two wide bandgap regions. For sufficiently thin narrow bandgap region, quantization occurs for the allowed energy levels within the quantum well. In various examples, this can be used for optoelectronic and electronic devices. In aspects, a device having the structure of FIG. 56D may comprise MgₓGe_{y}O_{z} or Mgₐ(Siₓ(Ge_{y}Sn_{1-y})₁₋ₓ)O_{b}, such as Mg₂GeO₄, Mg₂SiO₄ or Mg₂SnO₄ for one or more of the layers. As Mg₂GeO₄, Mg₂SiO₄ and Mg₂SnO₄ are direct bandgap materials, optical emission is possible for electrons and holes spatially recombining.

FIG. 56E shows a band structure diagram for a metal-insulator-semiconductor (MIS) structure. The semiconductor region has a bandgap E_{g1}, and the insulator region has a bandgap E_{g2}. In aspects, a device having the structure of FIG. 56E may comprise MgₓGe_{y}O_{z} or Mgₐ(Siₓ(Ge_{y}Sn_{1-y})₁₋ₓ)O_{b}, such as Mg₂GeO₄, Mg₂SiO₄ or Mg₂SnO₄ for one or more of the layers. For example, an Mg₂GeO₄ layer may be used as either the insulator or semiconductor. If the Mg₂GeO₄ semiconductor is used to form a metal-insulator-semiconductor structure, then the insulator can be selected from wider bandgap materials that are compatible as shown in FIG. 55C.

FIG. 56F is a band structure diagram representing a multiple heterojunction device, such as a diode, with a p-i-n structure and a single quantum well QW. In this example, the bandgaps of the n- and p-regions (E_{gn}, E_{gp} respectively) are greater than that of the barriers (bandgap E_{gi,B}) and quantum well (E_{gi,W}) of the QW region, where E_{gi,B}>E_{gi,W}. Electrons and holes are injected into the intrinsic region from their respective reservoir regions. Heterojunction conduction band offset ΔE_{c} and valence band offset ΔEᵥ provide energy barriers for controlling carrier flow/confinement. The heterojunction structure is useful for light emitting devices, as light generated from the center region will not be absorbed by the p- and n-regions and therefore will escape; that is, the wider bandgap n- and p-regions have low absorption coefficients of light emitted from the quantum well in the narrower bandgap i-layer. The quantum well, with bandgap E_{gi,W}, is designed such that the thickness L_{QW} can tune the quantized energy levels in the conduction and valence bands confined between the barriers, with bandgaps E_{gi,B}. In other aspects, the structure can have more than one, or multiple quantum wells in the intrinsic region. The energy levels in the multiple quantum well structure influence various properties of the structure, such as the minimum effective bandgap. In some cases, such as in light emitting devices, having more than one quantum well improves optical emission, such as due to increased quantum well capture rates of carriers injected into the i-region from the p- and n-regions. In aspects, a device having the structure of FIG. 56F may comprise MgₓGe_{y}O_{z} or Mgₐ(Siₓ(Ge_{y}Sn_{1-y})₁₋ₓ)O_{b}, such as Mg₂GeO₄, Mg₂SiO₄ or Mg₂SnO₄ for one or more of the layers.

FIG. 56G is a band structure diagram for a p-i-n structure with a superlattice (SL) in the i-region. The p-i-n structure has multiple quantum wells, where the barrier layers of the multiple quantum well structure in the i-region have larger bandgaps than the bandgap of the n- and p-layers. In other cases, the bandgaps of the barrier layers in the multiple quantum wells can be narrower than those of the n- and p-layers. The diagram in the bottom half of FIG. 56G shows a single quantum well of the multiple quantum well structure. The thickness L_{QB} of the barrier layers can be made thin enough that electrons and holes can tunnel through them (e.g., within the i-region, and/or when being transferred between the n- and/or p-layers into and/or out of the i-region). Such a multiple quantum well structure can behave as a digital alloy, whose properties are dependent on the materials comprising the barriers and the wells, and with the thicknesses of the barriers and the wells. In aspects, a device having the structure of FIG. 56G may comprise MgₓGe_{y}O_{z} or Mgₐ(Siₓ(Ge_{y}Sn_{1-y})O_{b}, such as Mg₂GeO₄, Mg₂SiO₄ or Mg₂SnO₄ for one or more of the layers.

FIG. 56H is a band structure diagram for a p-i-n structure with a superlattice in the p-, i-, and n-regions. For this full superlattice structure of p(SL)-i(SL)-n(SL), the p-, i-, and n-regions may be the same or different compositions. The n-region comprises Nₐ^{SL} pairs of wells (thickness Li and bandgap E_{gW1}) and barriers (thickness L₂ and bandgap E_{gB1}). The i-region comprises Nᵢ^{SL} pairs of wells (thickness L₃ and bandgap E_{gW2}) and barriers (thickness L₄ and bandgap E_{gB2}). The p-region comprises N_{pSL} pairs of wells (thickness L₅ and bandgap E_{gw3}) and barriers (thickness L₆ and bandgap E_{gB3}). The bandgaps of the barriers and wells in the i-region are narrower than those of the barriers and wells in both the n- and p-layers in this example. In other cases of structures with multiple quantum wells, the bandgaps of the barrier layers can be wider than those of the n- and p-layers. Additionally, in some cases, the thicknesses and/or bandgaps of the barriers and/or wells in the n-, i- and/or p-region can change throughout an individual region (e.g., to form a graded structure, or a chirp layer). The thicknesses L₂, L₄, and/or L₆ of the barrier layers can be made thin enough that electrons and holes can tunnel through them (e.g., within the i-region, and/or when being transferred between the n- and/or p-layers into and/or out of the i-region). Each region in the structure can behave as a digital alloy, whose properties are dependent on the materials comprising the barriers and the wells, and with the thicknesses of the barriers and the wells. For example, the materials and layer thicknesses can be chosen such that the n- and p-regions have wider bandgaps and are therefore transparent (or have a low absorption coefficient) to the wavelength of light emitted from the i-region superlattice. In aspects, a device having the structure of FIG. 56H may comprise MgₓGe_{y}O_{z} or Mgₐ(Siₓ(Ge_{y}Sn_{1-y})O_{b}, such as Mg₂GeO₄, Mg₂SiO₄ or Mg₂SnO₄ for one or more of the layers.

FIG. 56I is a band structure diagram for a p-i-n structure similar to FIG. 56H. The bandgap and the thicknesses of the barriers and well in the n-, i- and p-regions are defined as in FIG. 56H. The superlattices in the n-, i- and p-regions in this example have the same alternating pairs of materials, with different well (or well and barrier) thicknesses in the i-region tuning the optical properties. The structure has a material A and a material B, where the barriers of the superlattice in the n-region comprise material A and the wells in the superlattice in the n-region comprise material B. In this example, the barriers of the i- and p-regions also comprise material A and the wells in the i- and p-regions also comprise material B. The wells in the i-region have been made thicker so that the quantized energy levels in the potential well are lower in energy with respect to the band edge of the host well, thereby making the effective bandgap of the superlattice in the i-region have a narrower bandgap (i.e., closer to that of material A in a bulk form) than that of the superlattices in the n- and p-region. Such a structure could therefore be used in a light emitting device (e.g., and LED), as described herein. In aspects, a device having the structure of FIG. 56I may comprise MgₓGe_{y}O_{z} or Mgₐ(Siₓ(Ge_{y}Sn_{1-y})₁₋ₓ)O_{b}, such as Mg₂GeO₄, Mg₂SiO₄ or Mg₂SnO₄ for one or more of the layers.

The materials, structures and methods described herein can be used in two-terminal, three-terminal, or other multi-terminal semiconductor devices, such as Schottky barrier (SB) diodes, p/n junction diodes, p-i-n diodes, transistors, switches, high-power switches, RF-switches, varactors, light emitting devices, semiconductor devices with quantum wells or superlattices, semiconductor devices with compositional (or doping density) gradients, and others. Example structures for these devices are shown in FIGS. 54A-71.

In the conduction structures and devices described in FIGS. 54A-71, one or more layers of the active regions may comprise MgₓGe_{y}O_{z} or Mgₐ(Siₓ(Ge_{y}Sn_{1-y})₁₋ₓ)O_{b} materials as disclosed herein. In some cases, the active region may be formed as an epitaxial oxide material. In some cases, the active regions, which may also be referred to as semiconductor layers or semiconductor layer regions, may serve as, for example, an n-type region, an intrinsic region, a p-type region, or other functional region.

In some examples, semiconductor structures and devices, such as those in FIGS. 54A-71, may include other layers such as include an epitaxial transition layer and/or epitaxial intermediate layer that comprise a magnesium-group IV oxide material of the present disclosure. For example, the epitaxial transition layer can be formed between the substrate and an epitaxial oxide layer (which may comprise a magnesium-group IV oxide material of the present disclosure or other oxide material). In some cases, the transition layer can provide an intermediate level of doping between the substrate and epitaxial oxide layer and/or manage interfacial strain, and can thereby impact the electronic and structural properties of the semiconductor devices (e.g., semiconductor diode devices), as described further herein. In another example, an intermediate layer can be formed between the epitaxial oxide layer and the metal layer. In embodiments involving a Schottky metal layer, the intermediate layer can advantageously alter the Schottky barrier properties and can thereby impact the electronic properties of the semiconductor diode device such as the turn-on voltage and/or the reverse breakdown voltage, as described further herein. In some examples, one or both of the transition layer and/or the intermediate layer are considered to be functionally part of the active region. In other example embodiments, one or both of the transition layer and/or the intermediate layer are not considered to be functionally part of the active region.

In some cases, a semiconductor device structure can include both a transition layer and an intermediate layer. The intermediate layer and the transition layer can each be a single layer or can include multiple layers of materials such as in a superlattice layer or a chirp layer.

The semiconductor layer regions may be formed as a unitary layer of a single composition, or may comprise multiple layers of different compositions, or a multilayered structure comprising repeating layers that are each formed of individual sub-layers. In the conduction devices, electrical materials forming the contacts to the electron and hole injector regions are selected from low- and high-work function metals, respectively. In one example, the metal ohmic contacts are formed in-situ (e.g., without breaking vacuum) directly on a final metal oxide surface, as a result reducing any mid-level traps/defects created at the semiconducting oxide-metal interface. Some examples of high work function metals that can be used in ohmic (or low resistance) contacts to a p-type epitaxial oxide layer are Ni, Os, Se, Pt, Pd, Ir, Au, and alloys thereof. Some examples of low work function materials that can be used in ohmic (or low resistance) contacts to an n-type epitaxial oxide layer are Cs, Na, and Lanthanides, however Al, Ti, Ti—Al alloys, and titanium nitride (TiN) being common metals can also be used. In some cases, the metal contact layer can contain two or more layers of metals with different compositions (e.g., a Ti layer and an Al layer).

In the semiconductor structures and devices disclosed herein, such as in FIGS. 54A-71, the magnesium-group IV oxide materials may be used in one layer (e.g., as an active region, a transition layer (e.g., a buffer layer), an intermediate layer, a drift layer, a channel region), and a different material may be used in another layer (e.g., an active region, a transition layer (e.g., a buffer layer), an intermediate layer, a drift layer, a channel region). The different material in the other layer may be an oxide material or non-oxide material. The different material (oxide or non-oxide) may be used as substrates, junction partners, and superlattice partners for the magnesium-IV oxide materials disclosed herein. Examples of oxide materials that may be used with the magnesium-group IV oxide materials in semiconductor structures include Materials 1-7 described below.

In Material 1, (A₂O₃)ₓ(BO)₁₋ₓ ≡A₂ₓB₁₋ₓO₂ₓ+0≤x≤1, 0<x≤1, 0≤x<1, or 0<x<1. These ranges are distinct from each other, for example, since some aspects of Material 1 (as described by the formula above) include binary materials, and others include binary or ternary materials. In other cases herein, the subscripts of formulas for materials can include or exclude zero and/or one to distinguish between binary, ternary, quaternary, or other materials. The atomic species of Material 1 can be selected from: trivalent A={Al, Ga, RE, Bi, B′, In}; and bivalent B={Ni, Mg, Zn}, where O=Oxygen, Al=Aluminum, Ga=Gallium, RE=at least one Rare-earth (e.g., Lanthanide), Bi=Bismuth, B′=Boron, In=Indium, Zn=Zinc, Mg=Magnesium, and Ni=Nickel.

For example, when x=1/2 in the above formula for Material 1, an epitaxial layer of a structure or device described herein can include A₂B₁O₄. Some examples of such materials are Al₂Mg₁O₄, Ga₂Mg₁O₄, Al₂Zn₁O₄, Ga₂Zn₁O₄, Al₂Ni₁O₄, Ga₂Ni₁O₄, and RE₂Zn₁O₄. In another example, when x=1/3 in the above formula for Material 1, an epitaxial layer of a structure or device described herein can include A₂B₂O₅. Some examples of such materials are Al₂Mg₂O₅, Ga₂Mg₂O₅, Al₂Zn₂O₅, Ga₂Zn₂O₅, Al₂Ni₂O₅, and Ga₂Ni₂O₅. In another example, when x=1/4 in the above formula for Material 1, an epitaxial layer of a structure or device described herein can include A₂B₃O₆. Some examples of such materials are Al₂Mg₃O₆, Ga₂Mg₃O₆, Al₂Zn₃O₆, Ga₂Zn₃O₆, Al₂Ni₃O₆, and Ga₂Ni₃O₆. In another example, when x=1/5 in the above formula for Material 1, an epitaxial layer of a structure or device described herein can include A₂B₄O₇. Some examples of such materials are Al₂Mg₄O₇, Ga₂Mg₄O₇, Al₂Zn₄O₇, Ga₂Zn₄O₇, Al₂Ni₄O₇, and Ga₂Ni₄O₇. In another example, when x=3/4 in the above formula, an epitaxial layer of a structure or device described herein can include A₆B₁O₁₀. Some examples of such materials are Al₆Mg₁O₁₀, Ga₆Mg₁O₁₀, Al₆Zn₁O₁₀, Ga₆Zn₁O₁₀, Al₆Ni₁O₁₀, Ga₆Ni₁O₁₀, and RE₆Zn₁O₁₀. In other examples, x in the above formula for Material 1 can be any of the values 0≤x≤1, 0<x≤1, 0≤x<1, and 0≤x≤1. For example, more dilute composition cases are also possible, such as when 0≤x≤0.1, or 0.9≤x≤1.0.

In Material 2, ((A_{y}C_{1-y})₂O₃)ₓ(BO)₁₋ₓ≡(A_{y}C_{1-y})₂B₁₋ₓO₂ₓ+₁, 0≤x≤1, 0<x≤1, 0≤x<1, or 0<x<1; and 0≤y≤1, 0≤y≤<1, 0≤y<1, or 0<y<1. The atomic species of Material 2 can be selected from: trivalent A and C selected from two of {Al, Ga, RE, Bi, B′, In}; and bivalent B={Ni, Mg, Zn}, where O=Oxygen. For example, when x=1/2 and y=1/10 in the above formula for Material 2, an epitaxial layer of a structure or device described herein can include (A_{0.1}C_{0.9})₂B₁O₄. Some examples of such materials are (Al_{0.1}Ga_{0.9})₂Mg₁O₄, (Al_{0.1}Ga_{0.9})₂Ni₁O₄, (Bi_{0.1}Ga_{0.9})₂Mg₁O₄, (RE_{0.1}Ga_{0.9})₂Zn₁O₄, and (RE_{0.1}Al_{0.9})₂Zn₁O₄.

In Material 3, ((A_{y}D_{z}C_{1-y-z})₂O₃)ₓ (BO)₁₋ₓ≡(A_{y}D_{z}C_{1-y-z})₂ₓB₁₋ₓO₂ₓ₊₁, 0≤x≤1, 0<x≤1, 0≤x<1, or 0<x<1; 0≤y≤1, 0≤y≤1, 0≤y<1, or 0<y<1; and 0≤z≤1, 0<z≤1, 0≤z<1, or 0<z<1. The above formula for Material 3 is also constrained such that the sum y+z<1. The atomic species of Material 3 can be selected from: trivalent A, D and C selected from three of {Al, Ga, RE, Bi, B′, In}; and bivalent B={Ni, Mg, Zn}, where O=Oxygen. For example, when x=1/2, y=18/20, and z=1/20 in the above formula for Material 3, an epitaxial layer of a structure or device described herein can include (A_{0.9}D_{0.05}C_{0.05})₂B₁O₄. Some examples of such materials are (Ga_{0.9}Al_{0.05}In_{0.05})₂Mg₁O₄, (Ga_{0.9}Al_{0.05}In_{0.05})₂Ni₁O₄, (B′_{0.05}Bi_{0.05}Ga_{0.9})₂Mg₁O₄, (RE_{0.05}In_{0.05}Ga_{0.9})₂Zn₁O₄, and (RE_{0.05}Ga_{0.9}Al_{0.05})₂Zn₁O₄.

In Material 4, (A₂O₃)₁₋ₓ(B_{y}C_{1-y}O)≡A₂₍₁₋ₓ₎B_{xy}C_{x(1-y)}O₃₋₂ₓ, 0≤x≤1, 0<x≤1, 0≤x<1, or 0<x<1; and 0≤y≤1, 0<y≤1, 0≤y<1, or 0<y<1. The atomic species of Material 4 can be selected from: trivalent A={Al, Ga, RE, Bi, B′, In}; and bivalent B and C selected from at least two of {Ni, Mg, Zn}, where O=Oxygen. For example, when x=1/2 and y=1/4 in the above formula for Material 4, an epitaxial layer of a structure or device described herein can include A₂B_{0.25}C_{0.75}O₄. Some examples of such materials are Ga₂Mg_{0.25}Zn_{0.75}O₄, Al₂Mg_{0.25}Zn_{0.75}O₄, Ga₂Mg_{0.25}Ni_{0.75}O₄, and Ga₂Zn_{0.25}Mg_{0.75}O₄.

In Material 5, ((A_{z}D_{1-z})₂O₃)₁₋ₓ (B_{y}C_{1-y}O)ₓ≡A_{2z(1-x)}D_{2(1-z)(1-x)}B_{xy}C_{x(1-y)}O₃₋₂ₓ, 0≤x≤1, 0<x≤1, 0≤x<1, or 0<x<1; 0≤y≤1, 0<y≤1, 0≤y<1, or 0<y<1; and 0≤z≤1, 0<z≤1, 0≤z<1, and 0<z<1. The atomic species of Material 5 can be selected from: trivalent A or D selected from at least two of {Al, Ga, RE, Bi, B′, In}; and bivalent B and C selected from at least two of {Ni, Mg, Zn}, where O=Oxygen. For example, when x=1/2, y=1/2, and z=1/2 in the above formula for Material 5, an epitaxial layer of a structure or device described herein can include A₁D₁B_{0.5}C_{0.5}O₄. Some examples of such materials are Al₁Ga₁Ni_{0.5}Mg_{0.05}O₄, In₁Ga₁Zn_{0.5}Mg_{0.5}O₄, and RE₁Al₁Zn_{0.5}Ni_{0.5}O₄.

In Material 6, (A₂O₃)ₓ(BO₂)₁₋ₓ≡A₂ₓB₁₋ₓOₓ₊₂, 0≤x≤1, 0<x≤1, 0≤x<1, or 0<x<1. The atomic species of Material 6 can be selected from: trivalent A={Al, Ga, RE, Bi, B′, In}; and bivalent B={Ge, Si, Sn}, where O=Oxygen, Al=Aluminum, Ga=Gallium, RE=at least one Rare-earth (e.g., Lanthanide), Bi=Bismuth, B′=Boron, Ge=Germanium, Si=Silicon, and Sn=Tin. For example, when x=1/2 in the above formula for Material 6, an epitaxial layer of a structure or device described herein can include A₂B₁O₅. Some examples of such materials are Al₂Si₁O₅, Ga₂Ge₁O₅, Al₂Ge₁O₅, RE₂Sn₁O₅, B′₂Ge₁O₅, and In₂Ge₁O₅. For example, when x=3/4 in the above formula for Material 6, an epitaxial layer of a structure or device described herein can include A₆B₁O₁₁. Some examples of such materials are Al₆Ge₁O₁₁, RE₆Ge₁O₁₁, and B′₆Si₁O₁₁.

In Material 7, (AO)ₓ(BO₂)₁₋ₓ≡AₓB₁₋ₓO₂₋ₓ, 0≤x≤1, 0<x≤1, 0≤x<1, or 0<x<1. The atomic species of Material 7 can be selected from: trivalent A={Mg, Ni, Zn}; and bivalent B={Ge, Si, Sn}, where O=Oxygen, Mg=Magnesium, Ni=Nickel, Zn=Zinc, Ge=Germanium, Si=Silicon, and Sn=Tin. For example, when x=1/2 in the above formula for Material 7, an epitaxial layer of a structure or device described herein can include A₁B₁O₃. Some examples of such materials are Zn₁Si₁O₃, Zn₁Ge₁O₃, Ni₁Ge₁O₃, Mg₁Sn₁O₃, Mg₁Zn₁O₃, and Ni₁Sn₁O₃. For example, when x=2/3 in the above formula for Material 7, an epitaxial layer of a structure or device described herein can include A₂B₁O₄. Some examples of such materials are Zn₂Si₁O₄, Mg₂Ge₁O₄, Ni₂Ge₁O₄, Mg₂Sn₁O₄, Mg₂Si₁O₄, and Ni₂Si₁O₄.

It is to be understood that, for any of the epitaxial layers of the structures and devices described herein (e.g., the epitaxial oxide layer(s) of the active region, the transition layer, and/or the intermediate layer), the composition fractions (e.g., x, y and/or z) of any of the formulas for materials described herein (e.g., Materials 1-7 described above) may vary within the layer from the exact amount. For example, the composition fraction may vary due to crystalline lattice defects (e.g., vacancies, antisite defects, and/or interstitial species) and random fluctuations within physical compositions. Therefore, the composition fractions of the formulas for materials described herein can be considered average compositions of the layer in some cases.

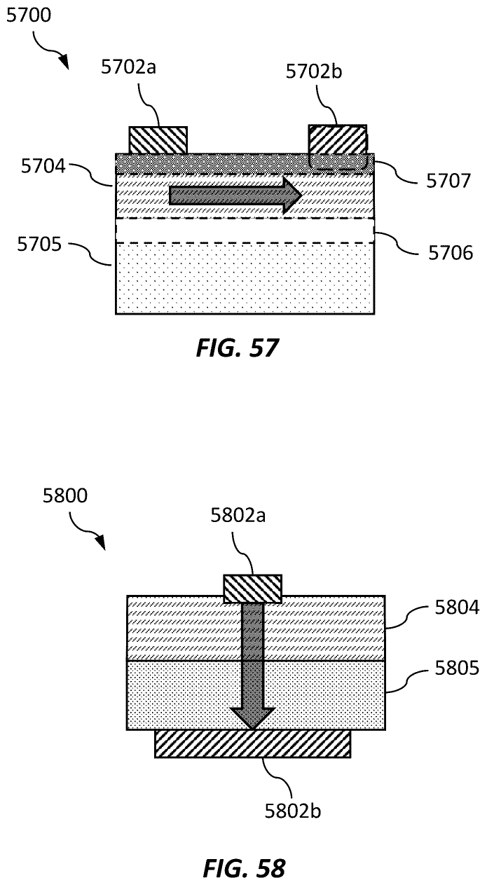

FIG. 57 shows a generalized example sectional view of an epitaxial oxide semiconductor device that implements a lateral conduction device 5700 (i.e., an in-plane conduction device). The device 5700 in this example comprises a substrate 5705 (e.g., an insulating substrate) and a semiconductor layer 5704 (e.g., an active region) formed on the substrate 5705, with electrical contacts and/or electrodes 5702a-b formed on or within the top semiconductor layer 5704 of the device. In this example, a first electrical contact or electrode 5702a is located on the top surface of semiconductor layer 5704, and a second electrical contact 5702b is spaced laterally from the first electrical contact 5702a and optionally embedded into the semiconductor layer 5704 as illustrated by the dashed lines below second electrical contact 5702b. The laterally spaced electrical contacts cause an in-plane current flow, when conducting, through the semiconductor layer 5704 as indicated by the large arrow.

In some aspects, the device of FIG. 57 may include additional layers, such as an optional transition layer 5706 that is formed between the active region (semiconductor layer 5704) and the substrate 5705. The transition layer can provide an intermediate level of doping between the substrate and semiconductor layer and/or manage interfacial strain and can thereby impact the electronic and structural properties of the semiconductor device 5700. In another example, an optional intermediate layer 5707 can be formed on the semiconductor layer 5704. For example, in cases involving a Schottky metal layer, the intermediate layer can advantageously alter the Schottky barrier properties and can thereby impact the electronic properties of a semiconductor diode device such as the turn-on voltage and/or the reverse breakdown voltage. In some examples, one or both of the transition layer and/or the intermediate layer are considered to be functionally part of the active region. In other examples, one or both of the transition layer and/or the intermediate layer are not considered to be functionally part of the active region. In some examples, the transition layer 5706 comprises a graded composition (e.g., a linear, a stepwise, or a chirped composition gradient). In some cases, the transition layer comprises a material that is doped with a single dopant concentration, or with a dopant concentration that varies in depth in the transition layer.

In some examples described with reference to FIG. 57, the electrical contact 5702a may comprise a Schottky metal, the electrical contact 5702b may comprise an ohmic metal, and the epitaxial oxide active region 5704, the transition layer 5706, and the intermediate layer 5707 may be configured to have the same conductivity type (e.g., all n-type or all p-type) to form a lateral Schottky diode. In some examples described with reference to FIG. 57, both the first and second electrical contacts 5702a-b may each comprise Schottky metals, and the epitaxial oxide active region 5704, the transition layer 5706, and the intermediate layer 5707 may be configured to have the same conductivity type (e.g., all n-type or all p-type) to form a Metal-Semiconductor-Metal (MSM) device.

FIG. 58 shows a vertical conduction device 5800 comprising in this example a conducting substrate 5805 and a semiconductor layer region 5804 formed on the substrate 5805, with the electrical contacts positioned on the top (electrical contact 5802a) and bottom (electrical contact 5802b) of the device. In this example, a first electrical contact 5802a of the electrical contacts is located on the top of the semiconductor layer region 5804 (either embedded in or on the top surface). A second electrical contact 5802b is located on the underside of the substrate 5805, vertically spaced from first electrical contact to cause vertical current flow as indicated by the large arrow.

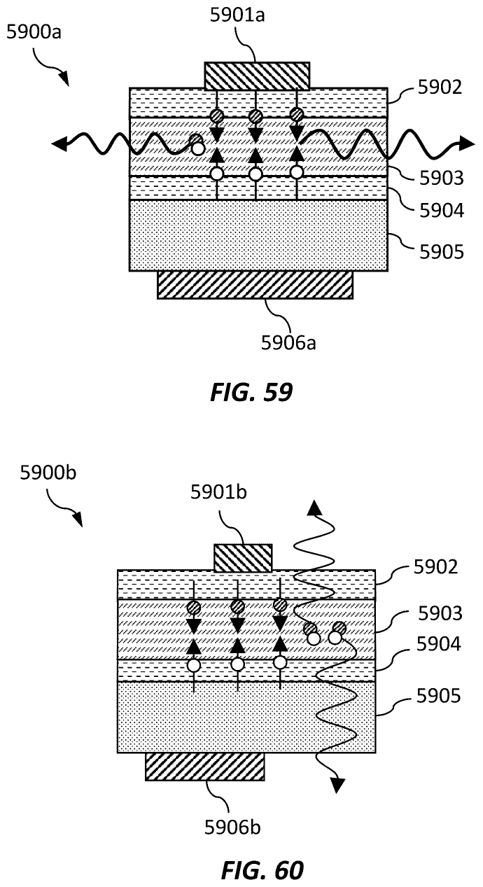

FIG. 59 shows a figurative sectional view of a semiconductor device 5900a for light emission (e.g., a light emitting diodes, laser diode, etc.). The semiconductor device 5900a may be a vertical conduction device 5900a having the electrical contact configuration illustrated in FIG. 58, configured as a plane parallel waveguide for the emitted light. The vertical conduction device 5900a comprises a substrate 5905, a first semiconductor layer 5904 formed on the substrate 5905, a second semiconductor layer 5903 formed on the first semiconductor layer 5904, and a third semiconductor layer 5902 formed on the second semiconductor layer 5903.

In one example, the semiconductor device 5900a comprises a substrate 5905, a first semiconductor layer 5904 having a first conductivity type, a second semiconductor layer 5903 having a second conductivity type), and a third semiconductor layer 5902 having a third conductivity type. For example, the first, second and third conductivity types may be, n-, i-, and p-as described throughout in this disclosure. A first electrical contact 5901a is on a top surface of the device, and a second electrical contact 5906a is on the bottom surface. Electrons and holes are injected into the central semiconductor layer, with light being emitted in a plane parallel to the plane of the layers (i.e., perpendicular to the growth direction). In some examples of semiconductor device 5900a, the first semiconductor layer 5904 may be a transition layer, the second semiconductor layer 5903 may be an active layer (i.e., active region), the third semiconductor layer 5902 may be an intermediate layer, and the first electrical contact 5901a may be an ohmic electrical contact. In some examples, of semiconductor device 5900a, the intermediate layer can be p-type while the other layers are n-type to form a p/n junction, and the metal layers can be Ohmic contacts in that case. In some examples, the semiconductor device 5900a may comprise a p-type substrate, a transition layer, and an active region with an n-type intermediate layer.

FIG. 60 shows a figurative sectional view of a semiconductor device 5900b (e.g., a vertical conduction device) for light emission (e.g., a light emitting diode, laser, etc.) having the electrical contact configuration illustrated in FIG. 58, configured as a vertical light emission device. The device 5900b comprises a substrate 5905, a first semiconductor layer 5904 having a first conductivity type, a second semiconductor layer 5903 having a second conductivity type, and a third semiconductor layer 5902 having a third conductivity type. For example, the first, second and third conductivity types may be, n-, i-, and p-as described throughout in this disclosure. A first electrical contact 5901b is on a top surface of the device, and a second electrical contact 5906b is on the bottom surface. Electrons and holes are injected into the central semiconductor layer (second semiconductor layer 5903). The substrate and other layers of the device can be designed to be transparent to the wavelength of light being emitted, such that light is emitted through one or both of the top and/or bottom surfaces of the device. As can be seen, the first electrical contact 5901b and second electrical contact 5906b are disposed on their respective surfaces to allow the passage of light. In this example, first electrical contact 5901b and second electrical contact 5906b are less wide (i.e., covers less lateral surface area) than first electrical contact 5901a and second electrical contact 5906a of FIG. 59, to allow light to pass through the top and bottom surfaces of semiconductor device 5900b. For example, first electrical contact 5901b and second electrical contact 5906b may be ring-shaped contacts where the light is emitted through the center of the ring, or fingers where the light is emitted between the fingers.

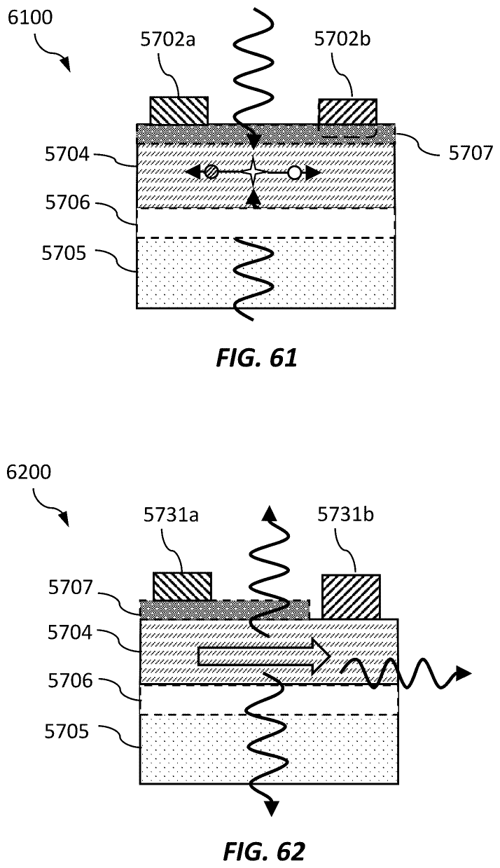

FIG. 61 shows a figurative sectional view of an in-plane conduction device 6100 for photo-detection (e.g., a photodetector) having the electrical contact configuration illustrated in FIG. 57, and configured to receive light passing through the semiconductor layer region and/or the substrate. As described for FIG. 57, the device 6100 includes a substrate 5705 and a semiconductor layer region 5704 formed on the substrate 5705, with electrical contacts positioned on the top semiconductor layer of the device. The in-plane conduction device 6100 may also include optional transition layer 5706 that is formed between the active region (semiconductor layer 5704) and the substrate 5705, and/or an optional intermediate layer 5707 formed on the semiconductor layer 5704. In this example, a first electrical contact or electrode 5702a is located on the top surface of the device (e.g., semiconductor layer 5704 or transition layer 5706 if present), and a second electrical contact 5702b is spaced laterally from first electrical contact 5702a, on or embedded into its supporting layer (e.g., the semiconductor layer 5704 or transition layer 5706 if present). The substrate material is transparent to the wavelength of interest. Light received by the device causes a current to be generated, where the current may be measured at the first and second electrical contacts.

In some examples of FIG. 61, both electrical contacts 5702a-b comprise a Schottky metal to configure the semiconductor device 6100 as a high-speed MSM photodetector. In other examples, the electrical contact 5702a may comprise a Schottky metal and the electrical contact 5702b may comprise an ohmic metal to configure the semiconductor device 6100 as a high-sensitivity photodetector. In either example, light received by the semiconductor device 6100 causes a predominantly lateral current (as depicted by the circles and arrows in the figure showing the generation and movement of an electron and a hole) to be generated, where the current may be measured at the first and second electrical contacts 5702a-b.

FIG. 62 shows a figurative sectional view of an in-plane conduction device 6200 for light emission (e.g., a light emitting diode, laser, etc.), having the electrical contact configuration illustrated in FIG. 57, and configured to emit light either vertically or in-plane. The device 6200 includes a substrate 5705 and a semiconductor layer region 5704 formed on the substrate 5705, with electrical contacts positioned on the top semiconductor layer of the device. The in-plane conduction device 6200 may also include optional transition layer 5706 that is formed between the active region (semiconductor layer 5704) and the substrate 5705, and/or an optional intermediate layer 5707 formed on the semiconductor layer 5704. In this example, a first electrical contact or electrode 5731a is located on the top surface of the device (e.g., semiconductor layer 5704 or transition layer 5706 if present), and a second electrical contact 5731b is spaced laterally from first electrical contact 5731a, on or embedded into its supporting layer (e.g., the semiconductor layer 5704 or transition layer 5706 if present). In aspects where the light is emitted vertically, the substrate material is transparent to the wavelength being generated.

In examples described with reference to FIG. 62, the electrical contacts 5731a-b may both comprise an ohmic metal, and the electrical contact 5731b is in direct electrical contact with the active region 5704. In such examples, the intermediate layer 5707 and the active region 5704 may be of alternating conductivity types (e.g., n-p, p-n) to form a PN junction diode or a light-emitting diode. In examples where the light is emitted vertically, the substrate material can in some cases be transparent to the wavelength being generated. In other examples, the substrate 5705 is thinned, removed, or holes or trenches formed to facilitate the extraction of light from the active region 5704.

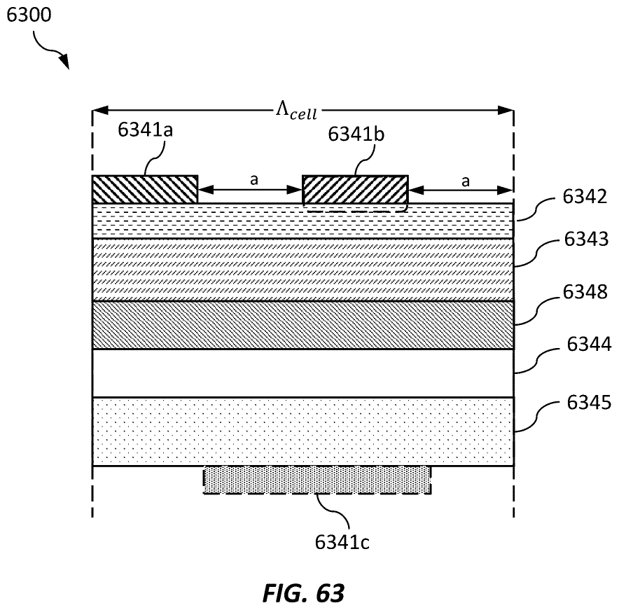

FIG. 63 shows a figurative sectional view of a three-terminal semiconductor device 6300. The device 6300 may include a substrate 6345, an optional transition layer 6344 formed on the substrate 6345, an active region 6343 formed on the substrate 6345 or on the transition layer 6344, and an optional intermediate layer 6342 formed on the active region 6343. Additional layer(s) 6348 may be included, such as between active region 6343 and transition layer 6344 as shown. Device 6300 can further include electrical contacts and/or electrodes 6341a-b formed on, or within, the optional intermediate layer 6342 and/or the active region 6343 (as illustrated by the dashed lines below the contact 6341b), and an electrical contact and/or electrode 6341c formed below the substrate 6345. For the case of a conductive substrate, the electrical contact 6341c may act as a vertical conduction collector or drain. For an insulating substrate, the electrical contact 6341c may act as a back gate of a field effect device. In some examples, the substrate 6345 is thinned to achieve a desired function and/or performance.

In one example, the three-terminal semiconductor device 6300 is an in-plane surface MSM conduction device comprising substrate 6345 and a semiconductor layer region comprising multiple semiconductor layers (active region 6343, optional transition layer 6344, and/or additional layer 6348). The top layer of metal comprises a pair of planar interdigitated electrical contacts 6341a-b, spaced apart by a distance “a.” The width of the repeating portion of the device is shown as A_{ce11}. In this example, the in-plane MSM conduction device comprises an optional third electrical contact 6341c located on the bottom surface of the substrate 6345. For the case of a conductive substrate, 6341c can act as a vertical conduction collector or drain. For an insulating substrate, 6341c may act as a back gate of a field effect device. In some aspects, a three-terminal epitaxial oxide semiconductor device may include multiple repeating unit cells Λ_{cell} of the device 6300. The cells may form elongated fingers in the plane of the figure.

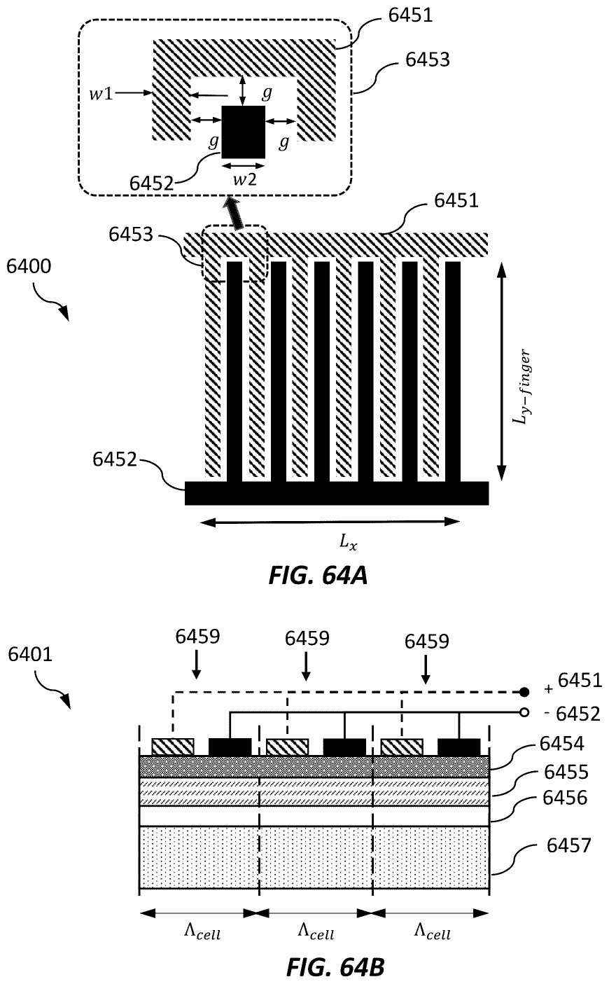

FIG. 64A shows a top view of a lateral semiconductor metal-semiconductor-metal (MSM) device 6400, e.g., an in-plane dual metal MSM conduction device. Device 6400 comprises a first electrical contact 6451 of a metal layer formed of a first metallic substance (e.g., a Schottky metal) interdigitated with a second electrical contact 6452 of the metal layer and formed of a second metallic substance (e.g., an Ohmic metal, or a Schottky metal). As can be seen in the enlarged view 6453 of a portion of the interdigitated contacts (electrical contacts 6451 and 6452), the first electrical contact 6451 has a finger width of w₁, and second electrical contact 6452 has a finger width of w₂ with a spacing of g between the contacts. The lateral gap, g, between the respective electrodes (electrical contacts 6451 and 6452) governs the in-plane electric field strength. The electrical contacts 6451 and 6452 may be formed from dissimilar metals, for example a high- and low-work function metal may be used.

FIG. 64B shows a figurative sectional view 6401 of the MSM device 6450 illustrated in FIG. 64A, formed of a substrate and a semiconductor layer region epitaxially formed on the substrate, showing the electrical contact unit cell arrangement. The device 6450 includes multiple repeating unit cells 6459 designated as Λ_{cell}, each comprising a shared substrate 6457, an optional transition layer 6456 formed on the substrate 6457, an epitaxial oxide active region 6455 formed on the transition layer 6456, an optional intermediate layer 6454 formed on the active region 6455, and the electrical contacts 6451 and 6452. The substrate 6457 can include any of the substrate compositions, configurations, and/or structures described in detail herein. The epitaxial oxide active region 6455 can include any of the epitaxial oxide compositions, configurations, and/or structures described in detail herein. The electrical contacts 6451 and 6452 may include any of the metals, compositions, configurations, and/or structures described in detail herein.

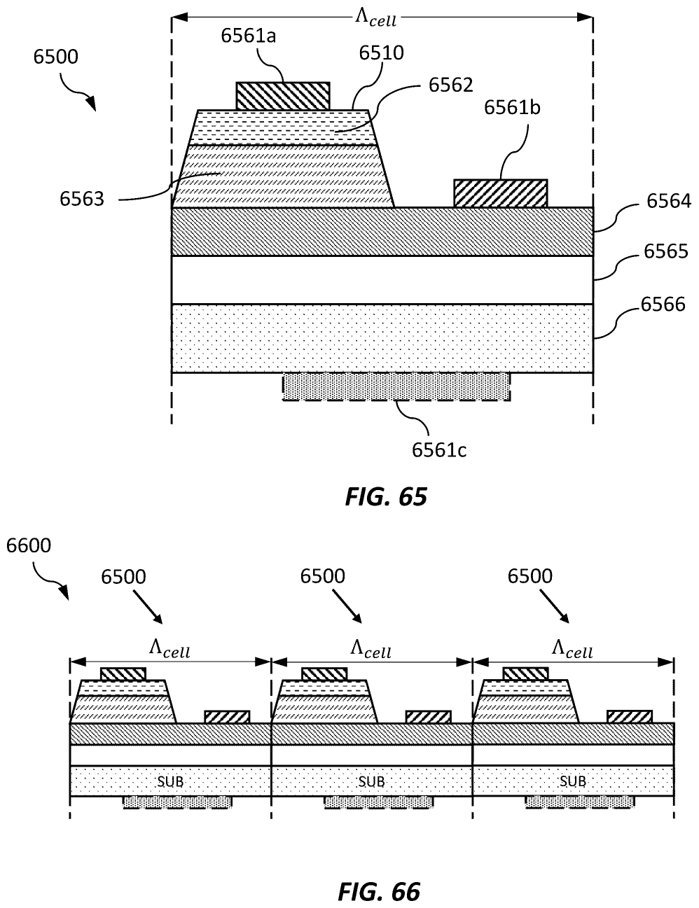

FIG. 65 shows a figurative sectional view of an example three-terminal epitaxial oxide mesa semiconductor device, i.e., a multilayered semiconductor device 6500. The device 6500 has a first electrical contact 6561a formed on a mesa surface 6510, and a second electrical contact 6561b spaced both horizontally and vertically from the first electrical contact 6561a. The device 6500 includes a substrate 6566 and semiconductor layers 6562, 6563, 6564, 6565. In this illustration, the first electrical contact 6561a is formed on an initial top surface of the semiconductor layer region which is etched to expose a sublayer for locating the second electrical contact 6561b. In this example, the multilayered semiconductor device further comprises a third electrical contact 6561c located on the underside of the substrate 6566. The 3-Terminal device comprising Contact1, Contact2 and Contact3 may act as a vertical heterojunction bipolar transistor or a vertical conduction FET switch.

In accordance with some examples, semiconductor layer 6565 is an optional transition layer formed on the substrate 6566, semiconductor layer 6564 is a first epitaxial oxide active region formed on either the substrate 6566 or the optional transition layer 6565, semiconductor layer 6563 is a second epitaxial oxide active region formed on the first active region (semiconductor layer 6564) as a mesa region, and semiconductor layer 6562 is an optional intermediate layer formed on the second active region (semiconductor layer 6563, which may be an epitaxial oxide or a nitride). The electrical contact 6561a is formed on either the optional intermediate layer 6562 or the second active region (semiconductor layer 6563), the electrical contact 6561b is formed on the active region (semiconductor layer 6564), and the electrical contact 6561c is formed below the substrate 6566. For the case of a conductive substrate, the electrical contact 6561c may act as a vertical conduction collector or drain. For an insulating substrate, the electrical contact 6561c may act as a back gate of a field effect device. In some cases, the substrate 6566 is thinned to achieve a desired function and/or performance.

In an example described with reference to FIG. 65, the three-terminal epitaxial oxide semiconductor device 6500 may be configured to implement a Bipolar Junction Transistor. In the example shown, the electrical contact 6561a is configured as an emitter terminal, the electrical contact 6561b is configured as a base terminal, and the electrical contact 6561c is configured as a collector terminal. The transition layer 6565 is configured as a region of a first conductivity type (e.g., n-type or p-type), the first epitaxial oxide active region 6564 is configured as a region of a second and opposite conductivity type (e.g., p-type or n-type), and the second epitaxial oxide active region 6563 and the optional intermediate layer 6562 are configured as regions of the first conductivity type (e.g., n-type or p-type).

FIG. 66 shows a figurative sectional view of an example three-terminal epitaxial oxide semiconductor device 6600 (e.g., an in-plane MSM conduction device) comprising multiple unit cells of the mesa structured device illustrated in FIG. 65. The unit cells Λ_{cell} are disposed adjacent to each other in a lateral direction. The cells may form elongated fingers in the plane of the figure.

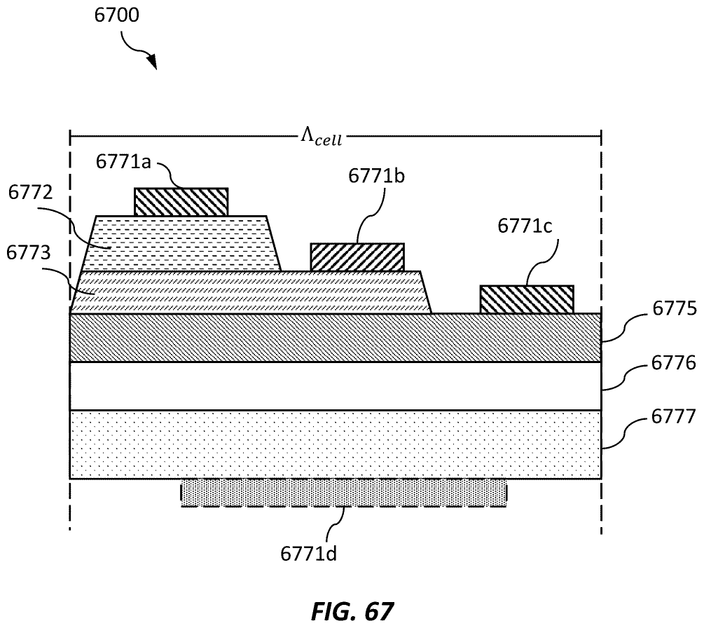

FIG. 67 shows a figurative sectional view of a multi-electrical terminal (four terminals in this example) device 6700 having multiple semiconductor layers 6772, 6773, 6775, 6776. In accordance with some examples, the mesa device 6770 includes a substrate 6777, an optional transition layer 6776 formed on the substrate 6777, a first epitaxial oxide active region 6775 formed on the optional transition layer 6776 or on the substrate 6777, a second epitaxial oxide active region 6773 formed as a mesa region on the first active region 6775, an optional intermediate layer 6772 formed on the second active region 6773, and electrical contacts and/or electrodes 6771a-d. The electrical contact 6771a is formed on the optional intermediate layer 6772 or on the second active region 6773, the electrical contact 6771b is formed on the second active region 6773, the electrical contact 6771c is formed on the first active region 6775, and the electrical contact 6771d is formed below the substrate 6777. The first electrical contact 6771a formed on a first mesa structure. The second electrical contact 6771b is spaced both horizontally and vertically from the first electrical contact 6771a and is formed on second mesa structure. The third electrical contact 6771c is spaced both horizontally and vertically from the second electrical contact 6771b.

In this illustrative example of FIG. 67, the device 6700 may be a four-terminal epitaxial oxide mesa semiconductor device. The first electrical contact 6771a is formed on an initial top surface of the semiconductor layer region (optional intermediate layer 6772), which is etched to expose a first sublayer (second active region 6773) for locating the second electrical contact 6771b. The first sublayer is further etched to expose another second sublayer (first active region 6775) for locating the third electrical contact 6771c. In this example, multi-electrical terminal device further comprises a fourth electrical contact 6771d located on the underside of substrate.

For the case of a conductive substrate, the electrical contact 6771d may act as a vertical conduction collector or drain. For an insulating substrate, the contact electrical contact 6771d may act as a back gate of a field effect device. In some aspects, the substrate 6777 is thinned to achieve a desired function and/or performance. For an electrically insulating substrate, the fourth electrical contact is optional.

In an example described with reference to FIG. 67, the four-terminal epitaxial oxide semiconductor device may be configured to implement a Bipolar Transistor. In the example shown, the electrical contact 6771a is configured as an emitter terminal, the electrical contact 6771b is configured as a base terminal, and the electrical contact 6771c is configured as a collector terminal. The electrical contact 6771d may be omitted or configured as a back bias terminal. In such cases, the intermediate/nitride layer 6772 is configured as a region of a first conductivity type (e.g., n-type or p-type), the second active region 6773 (which can be an epitaxial oxide or nitride) is configured as a region of a second and opposite conductivity type (e.g., p-type or n-type), and the first active region 6775 is configured as a region of the first conductivity type (e.g., n-type or p-type).

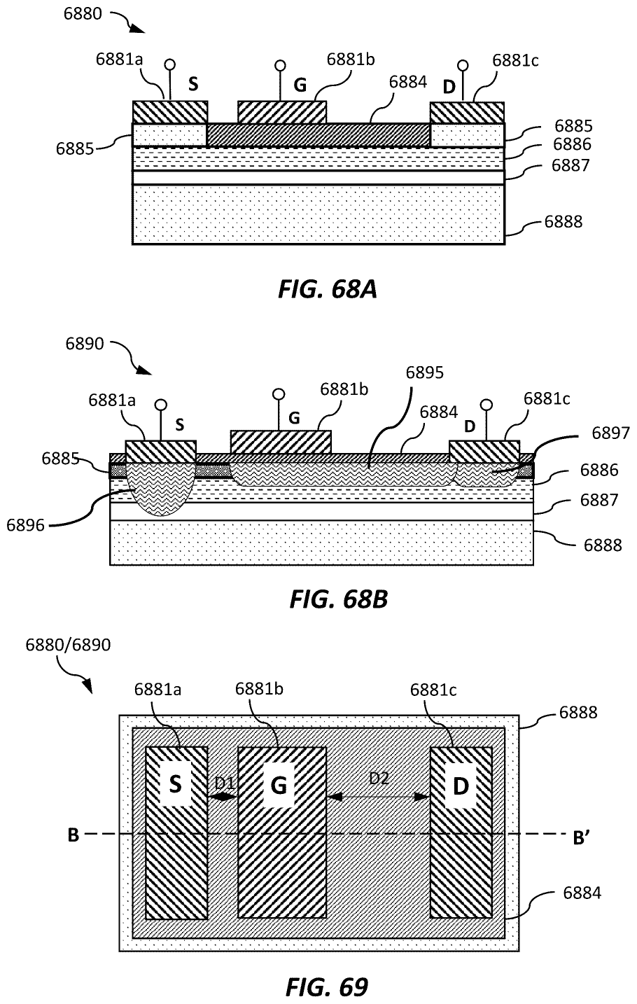

FIG. 68A shows a figurative sectional view of an example epitaxial oxide field effect transistor (FET) device 6880. In accordance with some aspects, the epitaxial oxide FET device 6880 includes a substrate 6888, an optional transition layer 6887 formed on the substrate 6888, an epitaxial oxide active region 6886 formed on the transition layer 6887 or on the substrate 6888, an optional intermediate layer 6885 formed on the active region 6886, an isolation region 6884 (i.e., a gate oxide) formed on the active region 6886, and electrical contacts and/or electrodes 6881a-c formed on or though the isolation region 6884. The electrical contact 6881a is a source contact (S) formed on the intermediate layer 6885 or on the active region 6886, the electrical contact 6881b is a gate contact (G) formed on the isolation region 6884, and the electrical contact 6881c is a drain contact (D) formed on the intermediate layer 6885 or on the active region 6886.

In accordance with some aspects, a region within the optional intermediate layer 6885 and the active region 6886 below the source contact 6881a is configured as a region of a first conductivity type (e.g., n-type or p-type), a region within the optional intermediate layer 6885 and the active region 6886 below the gate contact 6881b is configured as a region of a second and opposite conductivity type (e.g., p-type or n-type), and a region within the optional intermediate layer 6885 and the active region 6886 below the drain contact 6881c is configured as a region of the first conductivity type (e.g., n-type or p-type). Additionally, a doping concentration within the optional intermediate layer 6885 and the active region 6886 may vary laterally between the source contact 6881a and the drain contact 6881c to form channel and diffusion regions therein.

The MgₓGe_{y}O_{y} or Mgₐ(Siₓ(Ge_{y}Sn_{1-y})₁₋ₓ)O_{b} material layer may be used in two different ways. One function of the MgₓGe_{y}O_{y} or Mgₐ(Siₓ(Ge_{y}Sn_{1-y})₁₋ₓ)O_{b} layer is to be the active conduction channel region Semi1 with a wider bandgap material used to form the Gate layer. For example, the Gate layer may be itself epitaxially formed on active region 6886 (e.g., cubic gamma-Al₂O₃, MgO or MgAl₂O₄), or may be substantially amorphous (e.g., amorphous Al₂O₃). The composition of MgₓGe_{y}O_{y} or Mg, (Siₓ(Ge_{y}Sn_{1-y})₁₋ₓ)O_{b} may alternatively be used as the Gate layer, wherein for example, the active channel (e.g., active region 6886) is a smaller bandgap material. The metals forming S and D contacts are ideally ohmic and the gate metal can be selected to control the threshold voltage of the FET.

FIG. 68B shows a generalized sectional view of an example epitaxial oxide field effect transistor (FET) device 6890 of a similar configuration as the device 6880 illustrated in FIG. 68A. In FIG. 68B, a source region 6896 is implanted through the epitaxial oxide active region 6886 into the transition layer 6887 (and optionally the substrate 6888), whereas a drain region 6897 is implanted into the active region 6886 only. Also shown is an optional drift region 6895. The use of selective area ion-implantation to spatially alter the electrical conductivity of specific regions, such as the source region 6896 and drain region 6897 and the optional drift region 6895 is advantageous to provide improved lateral contact to a channel region of the active region 6886.

In accordance with some aspects, FIG. 69 shows a top view of the planar epitaxial oxide FET devices 6880/6890, depicting a distance D1 between the source-to-gate-electrical contacts 6881a and 6881b and a distance D2 between the gate-to-drain electrical contacts 6881b and 6881c. Section B-B′ indicates the cross-section shown in FIG. 68A. A distance relationship of D2 being greater than D1 can be utilized to control the breakdown voltage along a channel region in the active region 6886 between the gate and drain regions of the active region 6886.

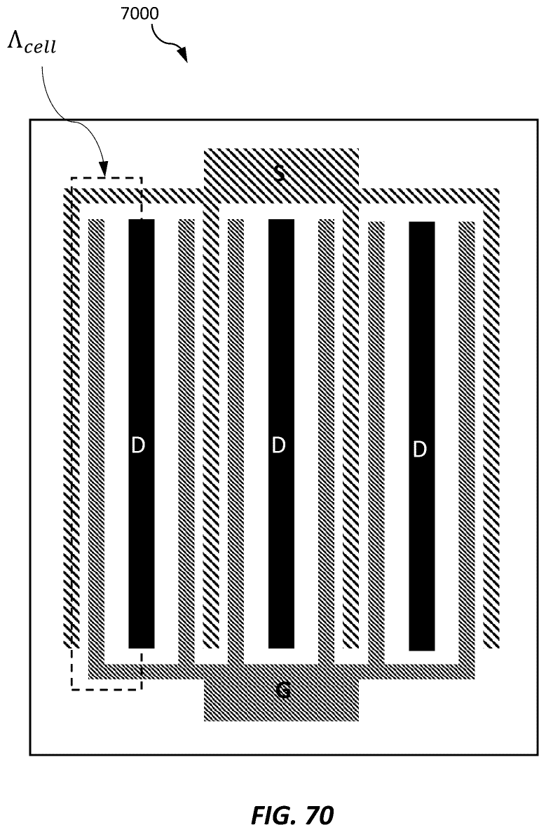

FIG. 70 shows a top view 7000 of the planar epitaxial oxide FET devices 6880/6890 comprising multiple interconnected unit cells Λ_{cell} 552 of the FET devices 6880/6890.

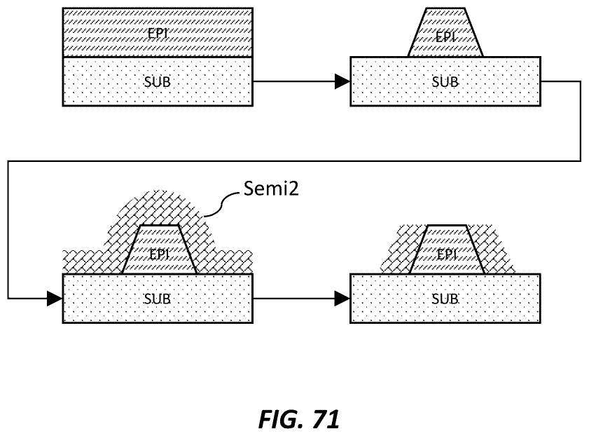

FIG. 71 shows a process flow diagram for forming a conduction device comprising a regrown conformal semiconductor layer region on an exposed etched mesa sidewall. Initially, a semiconductor device is formed having a substrate (SUB) and an epitaxially formed semiconductor layer region (EPI). This semiconductor layer region is then etched to leave a remaining mesa structured semiconductor layer region. An additional conformal semiconductor layer region (Semi2) is then grown on the mesa structure which may then be optionally planarized in a subsequent planarization step. For example, the conformal coating Semi2 can be another oxide deposited via atomic layer deposition. Semi2 can be used as a passivation region or may be used as an active region forming a FET.

It will be understood that the terms “comprise” and “include” and any of their derivatives (e.g., comprises, comprising, includes, including) as used in this specification are to be taken to be inclusive of features to which the term refers, and are not meant to exclude the presence of any additional features unless otherwise stated or implied

The reference to any prior art in this specification is not, and should not be taken as, an acknowledgement of any form of suggestion that such prior art forms part of the common general knowledge.

In some cases, a single embodiment may, for succinctness and/or to assist in understanding the scope of the disclosure, combine multiple features. It is to be understood that in such a case, these multiple features may be provided separately (in separate embodiments), or in any other suitable combination. Alternatively, where separate features are described in separate embodiments, these separate features may be combined into a single embodiment unless otherwise stated or implied. This also applies to the claims which can be recombined in any combination. That is, a claim may be amended to include a feature defined in any other claim. Furthermore, a phrase referring to “at least one of” a list of items refers to any combination of those items, including single members. As an example, “at least one of: a, b, or c” is intended to cover: a, b, c, a-b, a-c, b-c, and a-b-c.

Reference has been made in detail to aspects of the disclosed invention, one or more examples of which have been illustrated in the accompanying figures. Each example has been provided by way of explanation of the present technology, not as a limitation of the present technology. In fact, while the specification has been described in detail with respect to specific aspects of the invention, it will be appreciated that those skilled in the art, upon attaining an understanding of the foregoing, may readily conceive of alterations to, variations of, and equivalents to these aspects. For instance, features illustrated or described as part of one aspect may be used with another aspect to yield a still further aspect. Thus, it is intended that the present subject matter covers all such modifications and variations within the scope of the appended claims and their equivalents. These and other modifications and variations to the present invention may be practiced by those of ordinary skill in the art, without departing from the scope of the present invention, which is more particularly set forth in the appended claims. Furthermore, those of ordinary skill in the art will appreciate that the foregoing description is by way of example only and is not intended to limit the invention.

What is claimed is:

1. An epitaxial layer comprising single crystal Mgₐ(Siₓ(Ge_{y}Sn_{1-y})₁₋ₓ)O_{b}, wherein 1.5≤a≤2.5, 3≤b≤5, 0≤x≤1, and 0≤y≤1;
wherein the single crystal Mgₐ(Siₓ(Ge_{y}Sn_{1-y})₁₋ₓ)O_{b} has a crystal symmetry compatible with a substrate or an underlying layer on which the single crystal Mgₐ(Siₓ(Ge_{y}Sn_{y})₁₋ₓ)O_{b} is grown.

2. The epitaxial layer of claim 1, wherein a=2 and b=4.

3. The epitaxial layer of claim 1, wherein the single crystal Mgₐ(Siₓ(Ge_{y}Sn_{1-y})₁₋ₓ)O_{b} has an electronic bandgap between 3 eV and 8 eV.

4. The epitaxial layer of claim 1, wherein the single crystal Mgₐ(Siₓ(Ge_{y}Sn_{1-y})₁₋ₓ)O_{b} has a direct electronic bandgap.

5. The epitaxial layer of claim 1, wherein the single crystal Mgₐ(Siₓ(Ge_{y}Sn_{1-y})₁₋ₓ)O_{b} has a cubic crystal space group symmetry.

6. The epitaxial layer of claim 1, wherein the single crystal Mgₐ(Siₓ(Ge_{y}Sn_{1-y})₁₋ₓ)O_{b} is a ternary oxide material, wherein i) x=1, or ii) y=0 and x=0, or iii) y=1 and x=0.

7. The epitaxial layer of claim 1, wherein the single crystal Mgₐ(Siₓ(Ge_{y}Sn_{1-y})₁₋ₓ)O_{b} is a quaternary oxide material, wherein i) x=0 and 0<y<1, or ii) 0<x<1 and y=0 or 1.

8. The epitaxial layer of claim 1, wherein the single crystal Mgₐ(Siₓ(Ge_{y}Sn_{1-y})₁₋ₓ)O_{b} is a quinary oxide material, wherein 0<x<1 and 0<y<1.

9. The epitaxial layer of claim 1, wherein the single crystal Mgₐ(Siₓ(Ge_{y}Sn_{1-y})₁₋ₓ)O_{b} is doped.

10. The epitaxial layer of claim 9, wherein the single crystal Mgₐ(Siₓ(Ge_{y}Sn_{1-y})₁₋ₓ)O_{b} is a direct bandgap p-type material and comprises B, Ga, Al or Li+ in a Ge, Sn, or Si site of a corresponding undoped Mgₐ(Siₓ(Ge_{y}Sn_{1-y})₁₋ₓ)O_{b} crystal structure.

11. The epitaxial layer of claim 9, wherein the single crystal Mgₐ(Siₓ(Ge_{y}Sn_{1-y})₁₋ₓ)O_{b} is a direct bandgap p-type material and comprises Li+ in a Mg site of a corresponding undoped Mgₐ(Siₓ(Ge_{y}Sn_{1-y})₁₋ₓ)O_{b} crystal structure.

12. The epitaxial layer of claim 9, wherein the single crystal Mgₐ(Siₓ(Ge_{y}Sn_{1-y})₁₋ₓ)O_{b} is a direct bandgap p-type material and comprises N³⁺ in an O site of a corresponding undoped Mgₐ(Siₓ(Ge_{y}Sn_{1-y})₁₋ₓ)O_{b} crystal structure.

13. The epitaxial layer of claim 9, wherein the single crystal Mgₐ(Siₓ(Ge_{y}Sn_{1-y})₁₋ₓ)O_{b} is a direct bandgap p-type material and comprises intrinsic defects of oxygen vacancies or excess oxygen.

14. The epitaxial layer of claim 9, wherein the single crystal Mgₐ(Siₓ(Ge_{y}Sn_{1-y})₁₋ₓ)O_{b} is a direct bandgap n-type material and comprises P or As in a Ge, Sn, or Si site of a corresponding undoped Mgₐ(Siₓ(Ge_{y}Sn_{1-y})₁₋ₓ)O_{b} crystal structure.

15. The epitaxial layer of claim 9, wherein the single crystal Mgₐ(Siₓ(Ge_{y}Sn_{1-y})₁₋ₓ)O_{b} is a direct bandgap n-type material and comprises Ga, Al or Ni+ in a Mg site of a corresponding undoped Mgₐ(Siₓ(Ge_{y}Sn_{1-y})₁₋ₓ)O_{b} crystal structure.

16. The epitaxial layer of claim 1, wherein the single crystal Mgₐ(Siₓ(Ge_{y}Sn_{1-y})₁₋ₓ)O_{b} is a semi-insulating material comprising a group III metal in a group IV or group II site of a corresponding undoped Mgₐ(Siₓ(Ge_{y}Sn_{1-y})₁₋ₓ)O_{b} crystal structure.

17. A semiconductor structure comprising:
an epitaxial layer comprising single crystal Mgₐ(Siₓ(Ge_{y}Sn_{1-y})₁₋ₓ)O_{b} wherein 1.5≤a≤2.5, 3≤b≤5, 0≤x≤1, and 0≤y≤1; and
a substrate or an underlying layer on which the single crystal Mgₐ(Siₓ(Ge_{y}Sn_{1-y})₁₋ₓ)O_{b} is grown;
wherein the single crystal Mgₐ(Siₓ(Ge_{y}Sn_{1-y})₁₋ₓ)O_{b} has a crystal symmetry compatible with the substrate or the underlying layer.

18. The semiconductor structure of claim 17, wherein the substrate or the underlying layer comprises a substantially single crystal substrate material.

19. The semiconductor structure of claim 18, wherein the substrate is made of Si, AlLaO₃, MgF₂, MgO, MgGa₂O₄, MgAl₂O₄, LiF, β-Ga₂O₃, LiAlO₂, ZrO₂, LiNbO₃, LiTaO₃, Fe₂O₃, BN, LiGaO₂, TiO₂, AlN, SiC, BaF₂, BN, CdWO₄, SiC, or miscut SiC.

20. The semiconductor structure of claim 17, wherein the single crystal Mgₐ(Siₓ(Ge_{y}Sn_{1-y})₁₋ₓ)O_{b} is strained and is lattice mismatched to the substrate or the underlying layer.

21. The semiconductor structure of claim 20, wherein the single crystal Mgₐ(Siₓ(Ge_{y}Sn_{1-y})₁₋ₓ)O_{b} comprises a lattice mismatch of less than or equal to 10% with the substrate or the underlying layer.

22. An optoelectronic device comprising the semiconductor structure of claim 17, wherein the optoelectronic device comprises a light emitting diode or a photodetector.

23. The optoelectronic device of claim 22, wherein the optoelectronic device emits or absorbs light having a wavelength in a range from 150 nm to 280 nm.

24. An electronic device comprising the semiconductor structure of claim 17, wherein the semiconductor structure comprises a diode or a transistor.

25. The semiconductor structure of claim 17, wherein the epitaxial layer comprising the single crystal Mgₐ(Siₓ(Ge_{y}Sn_{1-y})₁₋ₓ)O_{b} is in an active region of the semiconductor structure.

26. The semiconductor structure of claim 17, wherein the epitaxial layer comprising the single crystal Mgₐ(Siₓ(Ge_{y}Sn_{1-y})₁₋ₓ)O_{b} is a doped layer having n-type or p-type conductivity.

27. The semiconductor structure of claim 17, further comprising a second epitaxial layer forming a heterostructure with the single crystal Mgₐ(Siₓ(Ge_{y}Sn_{1-y})₁₋ₓ)O_{b}.
